(19) United States
(12) Patent Application Publication
(10) Pub. No.: US 2025/0393208 A1
(43) Pub. Date: Dec. 25, 2025

(54) SEMICONDUCTOR MEMORY DEVICE

(71) Applicant: Kioxia Corporation, Tokyo (JP)

(72) Inventor: Yudai ISHIMURA, Yokkaichi (JP)

(73) Assignee: Kioxia Corporation, Tokyo (JP)

(21) Appl. No.: 18/974,334

(22) Filed: Dec. 9, 2024

(30) Foreign Application Priority Data
Jun. 19, 2024 (JP) 2024-098693

(51) Int. Cl. H10B 43/27; H10B 43/10

(52) U.S. Cl. CPC H10B 43/27; H10B 43/10

(57) ABSTRACT

According to one embodiment, a semiconductor memory device includes: a plurality of second and third interconnect layers provided apart from each other in a first direction, and the second interconnect layers including a plurality of first terrace portions provided not overlapping respective upper layers of the second interconnect layers in the first direction in a third area and a first bridge portion that extends in the second direction in a fourth area, and the third interconnect layers including a plurality of second terrace portions provided not overlapping respective upper layers of the third interconnect layers in the first direction in the fourth area, and a second bridge portion that extends in the second direction in the third area; and first and second contacts each electrically coupled to ones of the first and the second terrace portions, respectively.

### CROSS-REFERENCE TO RELATED APPLICATION

This application is based upon and claims the benefit of priority from Japanese Patent Application No. 2024-098693, filed Jun. 19, 2024, the entire contents of which are incorporated herein by reference.

### FIELD

Embodiments described herein relate generally to a semiconductor memory device.

### BACKGROUND

A NAND flash memory is known as a semiconductor memory device that can store data in a non-volatile manner. In the NAND flash memory, a three-dimensional memory structure may be adopted for increasing the level of integration and capacity.

### BRIEF DESCRIPTION OF DRAWINGS

FIG. 1 is a block diagram illustrating an example of a configuration of a memory system according to a first embodiment.

FIG. 2 is a circuit diagram illustrating an example of a circuit configuration of a memory cell array included in the semiconductor memory device according to the first embodiment.

FIG. 3 is a perspective view illustrating an example of an appearance of the semiconductor memory device according to the first embodiment.

FIG. 4 is a perspective view illustrating an outline of a bonding structure of the semiconductor memory device according to the first embodiment.

FIG. 5 is a plan view illustrating an example of a planar layout of the memory cell array included in the semiconductor memory device according to the first embodiment.

FIG. 6 is a plan view illustrating an example of a planar layout in a memory area of the memory cell array included in the semiconductor memory device according to the first embodiment.

FIG. 7 is a sectional view taken along line VII-VII in FIG. 6, illustrating an example of a sectional structure in the memory area of the memory cell array included in the semiconductor memory device according to the first embodiment.

FIG. 8 is an enlarged view of area VIII in FIG. 7, illustrating an example of a sectional structure of a memory pillar included in the semiconductor memory device according to the first embodiment.

FIG. 9 is an enlarged view of area IX in FIG. 7, illustrating an example of a sectional structure of a member that divides the memory cell array included in the semiconductor memory device according to the first embodiment.

FIG. 10 is a sectional view taken along line X′-X′ in FIG. 7, illustrating an example of a sectional structure of the memory pillar included in the semiconductor memory device according to the first embodiment.

FIG. 11 is a plan view illustrating an example of a planar layout of an upper stacked interconnect in a hookup area of the memory cell array included in the semiconductor memory device according to the first embodiment.

FIG. 12 is a plan view illustrating an example of a planar layout of a lower stacked interconnect in the hookup area of the memory cell array included in the semiconductor memory device according to the first embodiment.

FIG. 13 is a sectional view taken along line XIII-XIII in FIGS. 11 and 12 in the hookup area of the memory cell array included in the semiconductor memory device according to the first embodiment.

FIG. 14 is a sectional view taken along line XIV-XIV in FIGS. 11 and 12 in the hookup area of the memory cell array included in the semiconductor memory device according to the first embodiment.

FIG. 15 is a sectional view taken along line XV-XV in FIGS. 11 and 12 in the hookup area of the memory cell array included in the semiconductor memory device according to the first embodiment.

FIG. 16 is an enlarged view of area XVI in FIG. 13, illustrating an example of a sectional structure of a contact included in the semiconductor memory device according to the first embodiment.

FIG. 17 is a flowchart illustrating an example of a manufacturing process of the hookup area of the memory cell array included in the semiconductor memory device according to the first embodiment.

FIG. 18 is a sectional view illustrating an example of a sectional structure of the semiconductor memory device according to the first embodiment in the middle of manufacturing.

FIG. 19 is a sectional view illustrating an example of a sectional structure of the semiconductor memory device according to the first embodiment in the middle of manufacturing.

FIG. 20 is a sectional view illustrating an example of a sectional structure of the semiconductor memory device according to the first embodiment in the middle of manufacturing.

FIG. 21 is a sectional view illustrating an example of a sectional structure of the semiconductor memory device according to the first embodiment in the middle of manufacturing.

FIG. 22 is a sectional view illustrating an example of a sectional structure of the semiconductor memory device according to the first embodiment in the middle of manufacturing.

FIG. 23 is a sectional view illustrating an example of a sectional structure of the semiconductor memory device according to the first embodiment in the middle of manufacturing.

FIG. 24 is a sectional view illustrating an example of a sectional structure of the semiconductor memory device according to the first embodiment in the middle of manufacturing.

FIG. 25 is a sectional view illustrating an example of a sectional structure of the semiconductor memory device according to the first embodiment in the middle of manufacturing.

FIG. 26 is a sectional view illustrating an example of a sectional structure of the semiconductor memory device according to the first embodiment in the middle of manufacturing.

FIG. 27 is a sectional view illustrating an example of a sectional structure of the semiconductor memory device according to the first embodiment in the middle of manufacturing.

FIG. 28 is a sectional view illustrating an example of a sectional structure of the semiconductor memory device according to the first embodiment in the middle of manufacturing.

FIG. 29 is a sectional view illustrating an example of a sectional structure of the semiconductor memory device according to the first embodiment in the middle of manufacturing.

FIG. 30 is a sectional view illustrating an example of a sectional structure of the semiconductor memory device according to the first embodiment in the middle of manufacturing.

FIG. 31 is a sectional view illustrating an example of a sectional structure of the semiconductor memory device according to the first embodiment in the middle of manufacturing.

FIG. 32 is a sectional view illustrating an example of a sectional structure of the semiconductor memory device according to the first embodiment in the middle of manufacturing.

FIG. 33 is a sectional view illustrating an example of a sectional structure of the semiconductor memory device according to the first embodiment in the middle of manufacturing.

FIG. 34 is a sectional view illustrating an example of a sectional structure of the semiconductor memory device according to the first embodiment in the middle of manufacturing.

FIG. 35 is a sectional view in the hookup area of the memory cell array included in the semiconductor memory device according to a first modification of the first embodiment.

FIG. 36 is a sectional view in the hookup area of the memory cell array included in the semiconductor memory device according to a second modification of the first embodiment.

FIG. 37 is a plan view schematically illustrating an example of a planar layout in a hookup area of a memory cell array included in a semiconductor memory device according to a second embodiment.

FIG. 38 is a sectional view taken along line XXXVIII-XXXVIII in FIG. 37 in the hookup area of the memory cell array included in the semiconductor memory device according to the second embodiment.

FIG. 39 is a sectional view taken along line XXXIX-XXXIX in FIG. 37 in the hookup area of the memory cell array included in the semiconductor memory device according to the second embodiment.

FIG. 40 is a plan view schematically illustrating an example of a planar layout in a hookup area of a memory cell array included in a semiconductor memory device according to a third embodiment.

FIG. 41 is a sectional view taken along line XLI-XLI in FIG. 40 in the hookup area of the memory cell array included in the semiconductor memory device according to the third embodiment.

FIG. 42 is a sectional view taken along line XLII-XLII in FIG. 40 in the hookup area of the memory cell array included in the semiconductor memory device according to the third embodiment.

FIG. 43 is a plan view schematically illustrating an example of a planar layout in a hookup area of a memory cell array included in a semiconductor memory device according to a fourth embodiment.

FIG. 44 is a sectional view taken along line XLIV-XLIV in FIG. 43 in the hookup area of the memory cell array included in the semiconductor memory device according to the fourth embodiment.

FIG. 45 is a sectional view taken along line XLV-XLV in FIG. 43 in the hookup area of the memory cell array included in the semiconductor memory device according to the fourth embodiment.

FIG. 46 is a plan view schematically illustrating an example of a planar layout in a hookup area of a memory cell array included in a semiconductor memory device according to a fifth embodiment.

FIG. 47 is a plan view illustrating an example of a planar layout of a lower stacked interconnect in the hookup area of the memory cell array included in the semiconductor memory device according to the fifth embodiment.

FIG. 48 is a sectional view taken along line XLVIII-XLVIII in FIG. 46 in the hookup area of the memory cell array included in the semiconductor memory device according to the fifth embodiment.

FIG. 49 is a sectional view taken along line XLIX-XLIX in FIG. 46 in the hookup area of the memory cell array included in the semiconductor memory device according to the fifth embodiment.

FIG. 50 is a plan view schematically illustrating an example of a planar layout in a hookup area of a memory cell array included in a semiconductor memory device according to a sixth embodiment.

FIG. 51 is a plan view illustrating an example of a planar layout of a lower stacked interconnect in the hookup area of the memory cell array included in the semiconductor memory device according to the sixth embodiment.

FIG. 52 is a sectional view taken along line LII-LII in FIG. 50 in the hookup area of the memory cell array included in the semiconductor memory device according to the sixth embodiment.

FIG. 53 is a sectional view taken along line LIII-LIII in FIG. 50 in the hookup area of the memory cell array included in the semiconductor memory device according to the sixth embodiment.

### DETAILED DESCRIPTION

In general, according to one embodiment, a semiconductor memory device includes: a first interconnect layer; a plurality of second interconnect layers that are provided above the first interconnect layer and apart from each other in a first direction, the second interconnect layers straddling, as viewed in the first direction, a first area and a second area that are arranged in a second direction intersecting the first direction, wherein the first area includes a third area and a fourth area that are arranged in a third direction intersecting the first direction and the second direction, and the second interconnect layers including a plurality of first terrace portions that are provided not overlapping respective upper layers of the second interconnect layers in the first direction in the third area, and a first bridge portion that extends in the second direction in the fourth area; a plurality of third interconnect layers that are provided above the second interconnect layers and apart from each other in the first direction in the first area and the second area, the third interconnect layers including a plurality of second terrace portions that are provided not overlapping respective upper layers of the third interconnect layers in the first direction in the fourth area, and a second bridge portion that extends in the second direction in the third area; a first insulating member and a second insulating member that extend in the first direction and the second direction and sandwich the first area and the second area in the third direction; a first memory pillar that extends in the first direction in the second area, and in which a portion passing through the second interconnect layers and the third interconnect layers functions as a plurality of first memory cells; a first contact that extends in the first direction above one of the first terrace portions in the third area and is electrically coupled to the one of the first terrace portions; and a second contact that extends in the first direction above one of the second terrace portions in the fourth area and is electrically coupled to the one of the second terrace portions.

Hereinafter, embodiments will be described with reference to the drawings. The drawings are schematic, and dimensions and ratios of the drawings are not necessarily the same as actual ones. In the following description, constituent elements having substantially the same function and configuration are denoted by the same reference signs. In a case where elements having similar configurations are particularly distinguished from each other, different characters or numbers may be added to the end of the same reference sign.

In the following description, a first component being “coupled” to a different second component encompasses the first component being coupled to the second component indirectly through the intervention of an intermediate element that is conductive constantly or selectively, or directly without any intervention of such an intermediate element.

### 1. First Embodiment

### 1.1 Configurations

### 1.1.1 Memory System

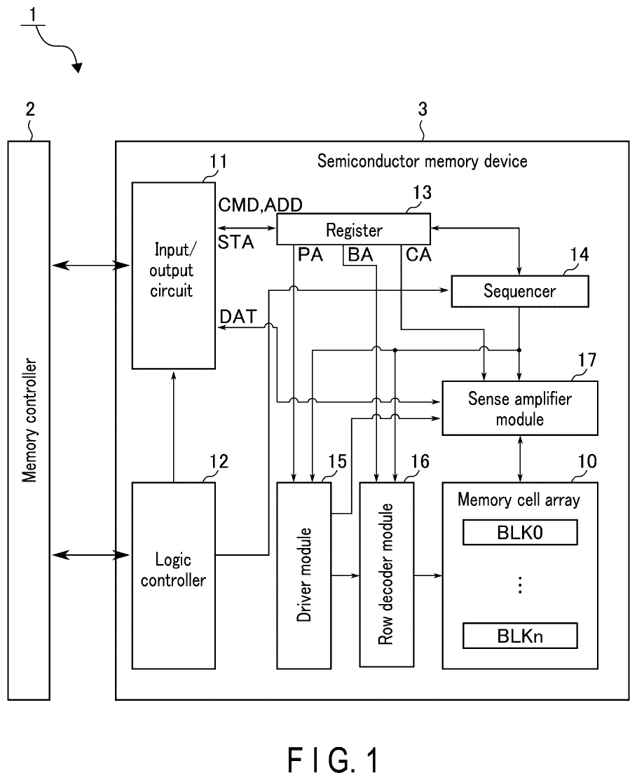

A semiconductor memory device according to a first embodiment will be described. FIG. 1 is a block diagram illustrating an example of a configuration of a memory system according to the first embodiment. A memory system 1 is a memory device configured to be coupled to an external host device (not illustrated). The memory system 1 is, for example, a memory card such as an SD™ card, a universal flash storage (UFS), or a solid state drive (SSD). The memory system 1 includes a memory controller 2 and a semiconductor memory device 3.

The memory controller 2 includes, for example, an integrated circuit such as a system on a chip (SoC). The memory controller 2 controls the semiconductor memory device 3 based on a request from an external host device. Specifically, the memory controller 2 writes data requested to be written by an external host device to the semiconductor memory device 3. The memory controller 2 reads, from the semiconductor memory device 3, data requested to be read by an external host device and outputs the data to the external host device.

The semiconductor memory device 3 is, for example, a NAND flash memory that can store data in a non-volatile manner.

Communication between the memory controller 2 and the semiconductor memory device 3 conforms to, for example, a single data rate (SDR) interface, a toggle double data rate (DDR) interface, or an open NAND flash interface (ONFI).

### 1.1.2 Semiconductor Memory Device

Subsequently, an internal configuration of the semiconductor memory device 3 according to the first embodiment will be described with reference to the block diagram provided in FIG. 1. The semiconductor memory device 3 includes, for example, a memory cell array 10, an input/output circuit 11, a logic controller 12, a register 13, a sequencer 14, a driver module 15, a row decoder module 16, and a sense amplifier module 17.

The memory cell array 10 is an aggregate of a set of memory cell transistors and constituent elements coupled to the memory cell transistors. The memory cell array 10 includes a plurality of blocks BLK0 to BLKn (n is an integer of 1 or more). The block BLK is an aggregate of a plurality of memory cell transistors that can store data in a non-volatile manner. The block BLK is used as, for example, an erase unit at the time of erasing data stored in the memory cell transistor. The memory cell array 10 includes a plurality of bit lines and a plurality of word lines. Each memory cell transistor is associated with, for example, a combination of one bit line and one word line. A detailed configuration of the memory cell array 10 will be described later.

The input/output circuit 11 is an interface circuit responsible for transmission and reception of input/output signals to and from the memory controller 2. The input/output signal includes, for example, data DAT, a command CMD, address information ADD, and status information STA. The input/output circuit 11 inputs and outputs the data DAT to and from the sense amplifier module 17 as well as to and from the memory controller 2. The input/output circuit 11 outputs each of the command CMD and the address information ADD transferred from the memory controller 2 to the register 13. The input/output circuit 11 outputs the status information STA transferred from the register 13 to the memory controller 2.

The logic controller 12 receives a control signal input from the memory controller 2. Based on the control signal, the logic controller 12 controls each of the input/output circuit 11 and the sequencer 14. For example, the logic controller 12 notifies the input/output circuit 11 that the input/output signal received by the input/output circuit 11 is the command CMD, the address information ADD, or the like. The logic controller 12 orders the input/output circuit 11 to input or output an input/output signal. The logic controller 12 controls the sequencer 14 and enables the semiconductor memory device 3. In addition, the logic controller 12 outputs, to the memory controller 2, a signal indicating whether the semiconductor memory device 3 is in a ready state or a busy state.

The register 13 temporarily stores the command CMD, the address information ADD, and the status information STA. The command CMD includes, for example, an order for causing the sequencer 14 to execute a read operation, a write operation, an erase operation, and the like. The address information ADD includes, for example, a block address BA, a page address PA, and a column address CA. For example, the block address BA, the page address PA, and the column address CA are used to select the block BLK, the word line, and the bit line, respectively. The status information STA is updated based on the control of the sequencer 14 and transferred to the input/output circuit 11.

The sequencer 14 controls the entire operation of the semiconductor memory device 3. For example, the sequencer 14 controls the driver module 15, the row decoder module 16, the sense amplifier module 17, and the like based on the command CMD stored in the register 13 and executes a read operation, a write operation, an erase operation, and the like.

The driver module 15 generates a plurality of voltages that have different magnitudes and are used in a read operation, a write operation, an erase operation, and the like. The driver module 15 supplies the generated voltage to the row decoder module 16, the sense amplifier module 17, and the like. In addition, the driver module 15 applies the generated voltage to, for example, the signal line corresponding to the word line selected based on the page address PA stored in the register 13.

The row decoder module 16 selects, for example, the corresponding one block BLK in the memory cell array 10 based on the block address BA stored in the register 13. The row decoder module 16 transfers, for example, the voltage of the signal line applied by the driver module 15 to the selected word line in the selected block BLK.

The sense amplifier module 17 includes a sense amplifier that can determine data based on a voltage of an associated bit line, a latch circuit that temporarily stores data, and the like. In the write operation, the sense amplifier module 17 applies a desired voltage to each bit line in accordance with write data DAT received from the input/output circuit 11. In addition, in the read operation, the sense amplifier module 17 determines the data stored in the memory cell transistor based on the magnitude of the voltage of the bit line. Thereafter, the sense amplifier module 17 transfers the determination result as read data DAT to the input/output circuit 11.

### 1.1.3 Circuit Configuration of Memory Cell Array

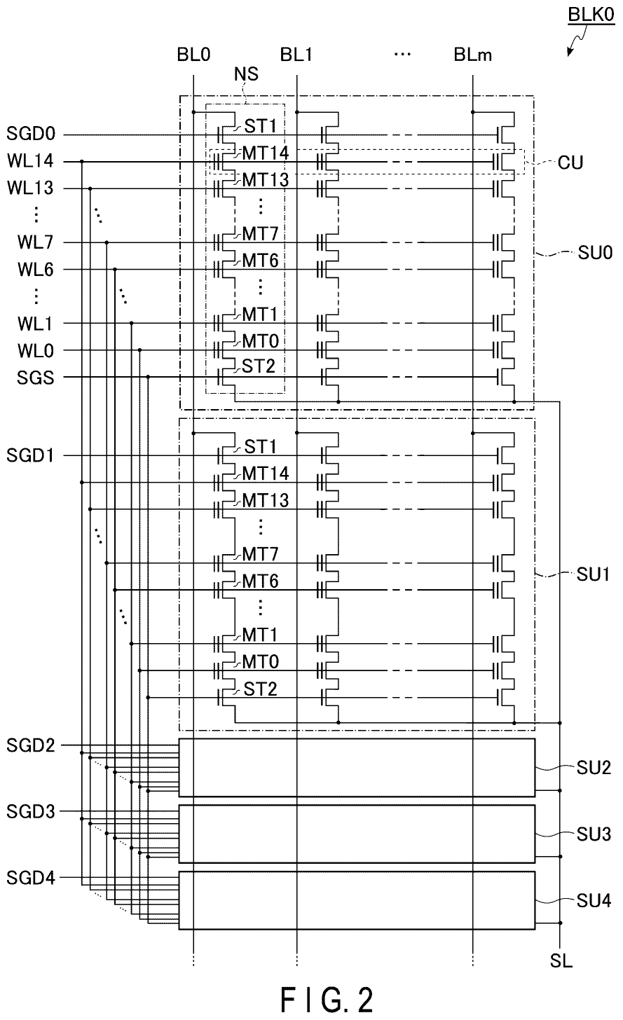

FIG. 2 is a circuit diagram illustrating an example of a circuit configuration of the memory cell array included in the semiconductor memory device according to the first embodiment. FIG. 2 illustrates a block BLK0. The block BLK0 includes, for example, five string units SU0 to SU4.

Each string unit SU includes a plurality of NAND strings NS respectively associated with the bit lines BL0 to BLm (m is an integer of 1 or more). Each NAND string NS includes, for example, 15 memory cell transistors MT0 to MT14 and select transistors ST1 and ST2. Each memory cell transistor MT includes a control gate and a charge storage film and stores data in a non-volatile manner based on the amount of charges in the charge storage film. Each of the select transistors ST1 and ST2 is used to select the string unit SU during various operations.

In each NAND string NS, the memory cell transistors MT0 to MT14 are coupled in series in this order. The drain of the select transistor ST1 is coupled to the associated bit line BL, and the source of the select transistor ST1 is coupled to the drain of the memory cell transistor MT14. The drain of the select transistor ST2 is coupled to the source of the memory cell transistor MT0, and the source of the select transistor ST2 is coupled to a source line SL.

The control gates of the memory cell transistors MT0 to MT14 in the same block BLK are coupled to word lines WL0 to WL14, respectively. Gates of the select transistors ST1 in the string units SU0 to SU4 are coupled to select gate lines SGD0 to SGD4, respectively. Gates of the select transistors ST2 in the same block BLK are coupled to a select gate line SGS.

Different column addresses CA are allocated to the bit lines BL0 to BLm. Each bit line BL is shared by the NAND string NS to which the same column address CA is allocated among the plurality of blocks BLK. Each of the word lines WL0 to WL14 is provided for each block BLK. The source line SL is shared among the plurality of blocks BLK, for example.

An aggregate of a plurality of the memory cell transistors MT coupled to the common word line WL in one string unit SU is referred to as, for example, a cell unit CU. For example, the memory capacity of the cell unit CU including the memory cell transistors MT each storing 1-bit data is defined as “one-page data”. The cell unit CU may have a memory capacity of two-page data or more in accordance with the number of bits of data stored in the memory cell transistor MT.

Note that the circuit configuration of the memory cell array 10 included in the semiconductor memory device 3 according to the first embodiment is not limited to the above description. For example, the number of the string units SU included in each block BLK can be designed to be any number. The number of the memory cell transistors MT and the select transistors ST1 and ST2 included in each NAND string NS can be designed to be any number.

### 1.1.4 Appearance of Semiconductor Memory Device

The semiconductor memory device 3 according to the first embodiment is formed by bonding two semiconductor circuit substrates each including a semiconductor circuit formed thereon and by separating the bonded semiconductor circuit substrates for each chip. That is, the semiconductor memory device 3 according to the first embodiment includes a structure formed by bonding semiconductor substrates W1 and W2 to each other. Each of the semiconductor substrates W1 and W2 is, for example, a silicon substrate. Hereinafter, a case where the semiconductor substrate W2 is removed in the manufacturing process of the semiconductor memory device 3 will be described. Note that a part of the semiconductor substrate W2 may remain after bonding, depending on the structure of the memory cell array 10.

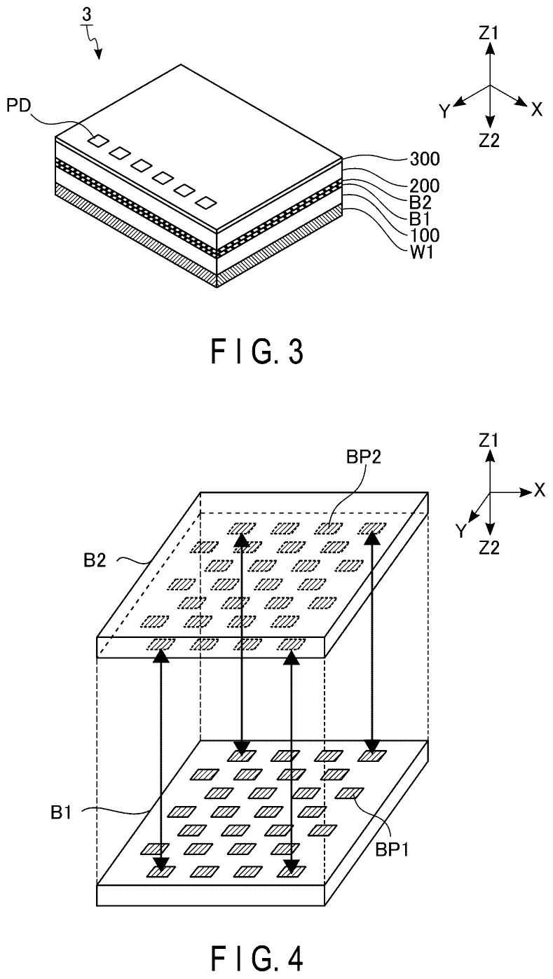

FIG. 3 is a perspective view illustrating an example of an appearance of the semiconductor memory device according to the first embodiment. In FIG. 3, hatching is added in order to enhance the visibility of the drawing, but the hatching is not necessarily related to the material or characteristics of a constituent element to which the hatching is added. As illustrated in FIG. 3, the semiconductor memory device 3 has, for example, a structure in which the semiconductor substrate W1, a control circuit layer 100, a joint layer B1, a joint layer B2, a memory layer 200, and an interconnect layer 300 are stacked in this order.

In the following description, a plane on which the semiconductor substrate W1 extends is referred to as an XY plane. Among the directions in which layers are stacked, a direction from the semiconductor substrate W1 toward the interconnect layer 300 is defined as a Z1 direction, and a direction from the interconnect layer 300 toward the semiconductor substrate W1 is defined as a Z2 direction. The Z1 direction and the Z2 direction are substantially perpendicular to the semiconductor substrate W1. Note that, in the case of not distinguishing the Z1 direction and the Z2 direction, each of the Z1 direction and the Z2 direction is simply referred to as a Z direction.

The control circuit layer 100 includes a control circuit formed using the semiconductor substrate W1. The semiconductor substrate W1 includes an impurity diffusion area or the like in accordance with the design of the control circuit. The control circuit layer 100 includes, for example, the input/output circuit 11, the logic controller 12, the register 13, the sequencer 14, the driver module 15, the row decoder module 16, and the sense amplifier module 17.

The joint layer B1 is formed using the semiconductor substrate W1. The joint layer B1 includes a plurality of joint pads electrically coupled to a control circuit provided in the control circuit layer 100 and forming a part of a semiconductor circuit.

The joint layer B2 is formed using the semiconductor substrate W2 (not illustrated). The joint layer B2 includes a plurality of joint pads electrically coupled to the memory cell array 10 provided in the memory layer 200 and forming a part of a semiconductor circuit.

The memory layer 200 includes the memory cell array 10 formed using the semiconductor substrate W2 (not illustrated).

The interconnect layer 300 is formed after the semiconductor substrates W1 and W2 are bonded together. The interconnect layer 300 includes an interconnect coupled to a semiconductor circuit provided in the memory layer 200 and a plurality of pads PD. The plurality of pads PD are exposed on the surface of the semiconductor memory device 3. The plurality of pads PD are used for coupling between the semiconductor memory device 3 and the memory controller 2 or the like.

FIG. 4 is a perspective view illustrating an outline of a bonding structure of the semiconductor memory device according to the first embodiment. The bonding of the semiconductor substrates W1 and W2 will be described with reference to FIG. 4.

As illustrated in FIG. 4, a plurality of joint pads BP1 included in the joint layer B1 and a plurality of joint pads BP2 included in the joint layer B2 are coupled to each other. As a result, the control circuit provided in the control circuit layer 100 and the memory cell array 10 provided in the memory layer 200 are electrically coupled to each other via the joint pads BP1 and BP2. A portion between the joint layers B1 and B2 corresponds to a boundary portion between a layer formed using the semiconductor substrate W1 and a layer formed using the semiconductor substrate W2 (not illustrated).

### 1.1.5 Configuration of Memory Cell Array

Hereinafter, an example of a structure of the memory cell array 10 included in the semiconductor memory device 3 according to the first embodiment will be described. In the following description, an X direction corresponds to the extending direction of the word line WL. A Y direction corresponds to the extending direction of the bit line BL. In the plan view, hatching is added as appropriate in order to enhance the visibility of the drawing. The hatching added to the plan view is not necessarily related to the material or characteristics of the constituent element to which hatching is added. In the sectional view, illustration of the configuration is omitted as appropriate in order to enhance the visibility of the drawing.

### 1.1.5.1 Overview

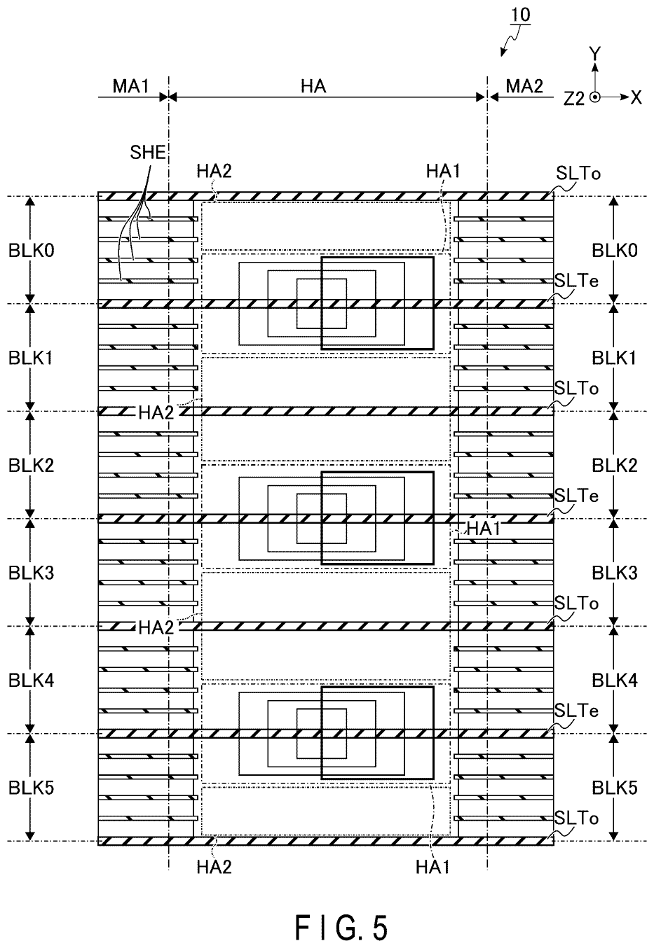

FIG. 5 is a plan view illustrating an example of a planar layout of the memory cell array included in the semiconductor memory device according to the first embodiment. FIG. 5 illustrates areas corresponding to six blocks BLK0 to BLK5. The sequence numbers at the ends for distinguishing the blocks BLK are assigned in ascending order from the upper side of this paper. In the memory cell array 10, for example, the layout illustrated in FIG. 5 is repeatedly disposed in the Y direction. As illustrated in FIG. 5, the memory cell array 10 includes a plurality of members SLT and a plurality of members SHE. The planar layout of the memory cell array 10 is divided into, for example, memory areas MA1 and MA2 and a hookup area HA in the X direction. The hookup area HA is provided between the memory area MA1 and the memory area MA2.

The memory areas MA1 and MA2 are areas that include a plurality of the NAND strings NS and are used for storing data. The hookup area HA is used for coupling between the row decoder module 16 and a stacked interconnect formed by stacking a plurality of interconnect layers (e.g., the word lines WL0 to WL14 and the select gate lines SGS and SGD) apart from each other in the Z direction.

Each of the plurality of members SLT extends along the X direction and is arranged in the Y direction. Each member SLT crosses the memory areas MA1 and MA2 in the X direction in the boundary area between the adjacent blocks BLK. In other words, each of the areas partitioned by the member SLT corresponds to one block BLK in the memory cell array 10. Each member SLT has, for example, a structure filled with an insulator and a plate-shaped contact. Each member SLT divides the stacked interconnect adjacent to each other with the member SLT interposed therebetween.

As illustrated in FIG. 5, in the present embodiment, among the plurality of members SLT arranged in the Y direction, the members SLT disposed in odd-numbered positions are referred to as “SLTo”, and the members SLT disposed in even-numbered positions are referred to as “SLTe”. In the memory cell array 10, a plurality of sets of the members SLTo and SLTe are arranged in the Y direction.

The plurality of members SHE are disposed in each of the memory areas MA1 and MA2. The plurality of members SHE corresponding to the memory area MA1 are each provided to cross the memory area MA1 in the X direction and are arranged in the Y direction. The plurality of members SHE corresponding to the memory area MA2 are each provided to cross the memory area MA2 in the X direction and are arranged in the Y direction. An end portion on the right side of this paper of each member SHE corresponding to the memory area MA1 and an end portion on the left side of this paper of each member SHE corresponding to the memory area MA2 are included in the hookup area HA. For example, in each of the memory areas MA1 and MA2, four members SHE are disposed between the members SLT adjacent in the Y direction. A combination of each of the areas partitioned by the members SLT and SHE in the memory area MA1 and each of the areas partitioned by the members SLT and SHE in the memory area MA2 corresponds to one string unit SU in the memory cell array 10. Each member SHE has, for example, a structure filled with an insulator. Each member SHE divides the adjacent select gate lines SGD with the member SHE interposed therebetween.

Note that the planar layout of the memory cell array 10 included in the semiconductor memory device 3 according to the first embodiment is not limited to the layout described above. For example, the number of the members SHE disposed between the adjacent members SLT can be designed to be any number. The number of the string units SU formed between the adjacent members SLT can be changed based on the number of the members SHE disposed between the adjacent members SLT.

The hookup area HA includes a plurality of hookup areas HA1 and HA2 alternately arranged in the Y direction. Each hookup area HA1 is provided for each two blocks BLK adjacent to each other in the Y direction with the member SLTe interposed therebetween. In other words, each hookup area HA1 is an area provided so as to be sandwiched between two members SLTo sandwiching the two adjacent blocks BLK in the hookup area HA. Each hookup area HA2 is provided for each two blocks BLK adjacent to each other in the Y direction with the member SLTo interposed therebetween. In other words, each hookup area HA2 is an area provided so as to be sandwiched between two members SLTe sandwiching the two adjacent blocks BLK in the hookup area HA.

### 1.1.5.2 Memory Area

### (Planar Layout)

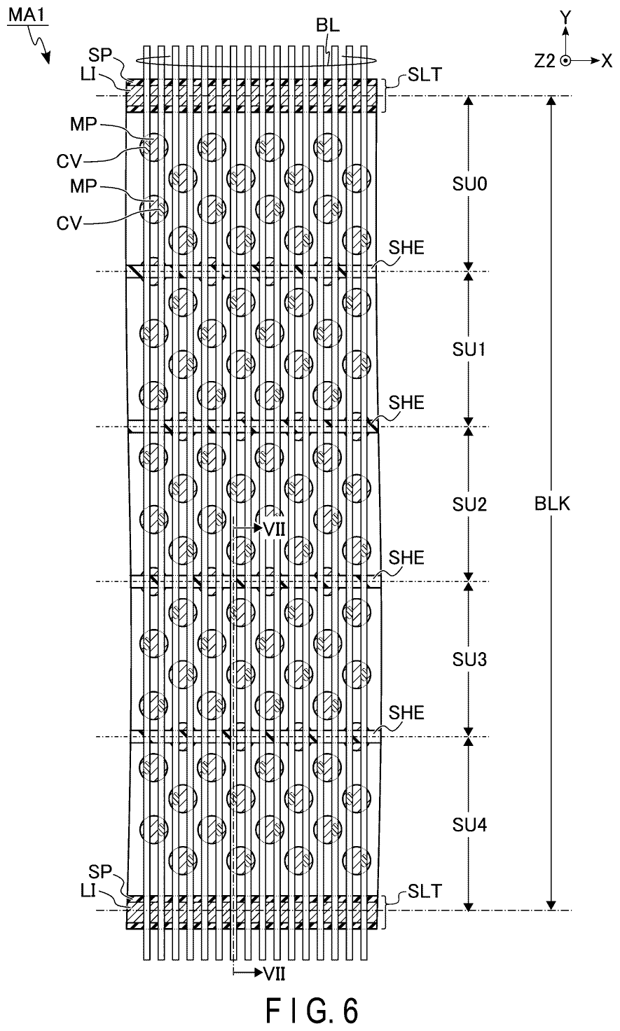

FIG. 6 is a plan view illustrating an example of a planar layout in the memory area of the memory cell array included in the semiconductor memory device according to the first embodiment. Note that FIG. 6 representatively illustrates a structure in one block BLK in the memory area MA1, but the structure of the memory area MA2 is similar to the structure of the memory area MA1. As illustrated in FIG. 6, in the memory areas MA1 and MA2, the memory cell array 10 includes a plurality of memory pillars MP, a plurality of contacts CV, and a plurality of the bit lines BL. Each member SLT includes a contact LI and a spacer SP.

Each memory pillar MP functions as, for example, one NAND string NS. The plurality of memory pillars MP is disposed in such a staggered manner as to have, for example, 24 rows in the Y direction in an area between two adjacent members SLT. In the example illustrated in FIG. 6, one member SHE overlaps each memory pillar MP of the fifth row, the tenth row, the 15th row, and the 20th row as counted from the upper side of this paper.

The plurality of bit lines BL each extend in the Y direction and are arranged in the X direction. Each bit line BL is disposed so as to overlap at least one memory pillar MP for each string unit SU. In the example illustrated in FIG. 6, two bit lines BL are disposed so as to overlap one memory pillar MP. In the case where the plurality of bit lines BL overlap the memory pillar MP, one bit line BL among the plurality of bit lines BL and the corresponding one memory pillar MP are electrically coupled via the contact CV. Note that, in the case where only one bit line BL overlaps the memory pillar MP, the bit line BL and the corresponding one memory pillar MP are electrically coupled via the contact CV.

For example, the contact CV between the memory pillar MP in contact with the member SHE and the corresponding bit line BL is omitted. In other words, the contact CV between the memory pillar MP in contact with the two different select gate lines SGD and the bit line BL is omitted. Neither the number nor arrangement of the memory pillars MP, the members SHE, or the like between the adjacent members SLT is limited to the configuration illustrated in FIG. 6 and these can be suitably changed. For example, the number of the bit lines BL overlapping each memory pillar MP can be designed to be any number.

The contact LI is a conductor extending in a XZ plane. The lower surface of the contact LI is in contact with the source line SL (not illustrated). The spacer SP is an insulator provided on a side surface of the contact LI. In other words, the spacer SP is provided in contact with the contact LI so as to sandwich the contact LI in the Y direction.

### (Sectional Structure)

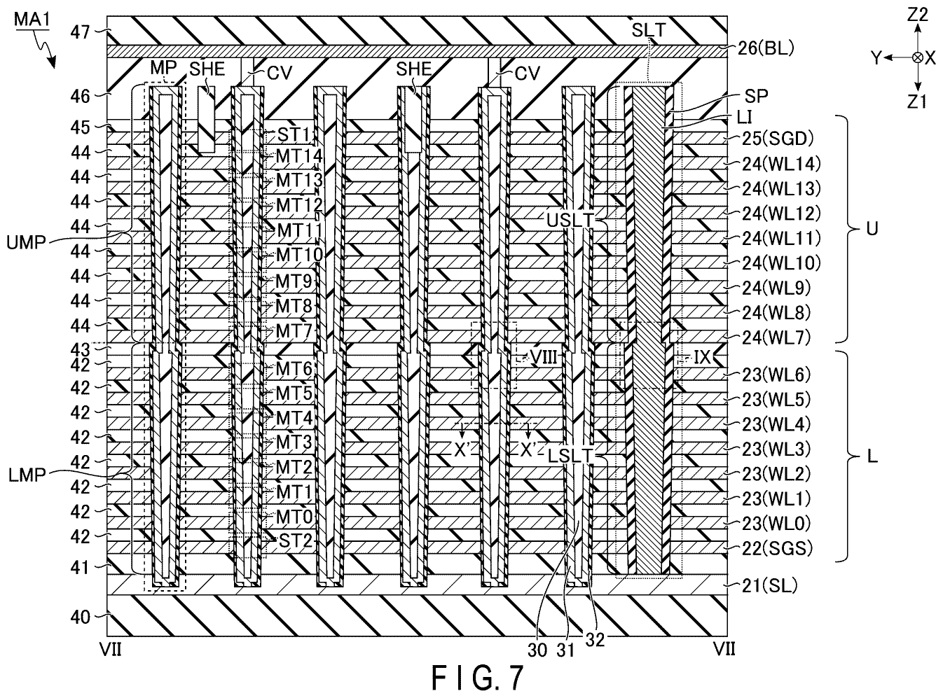

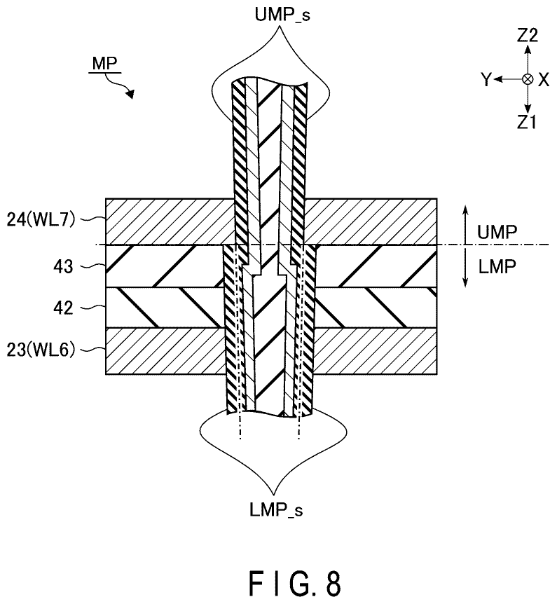

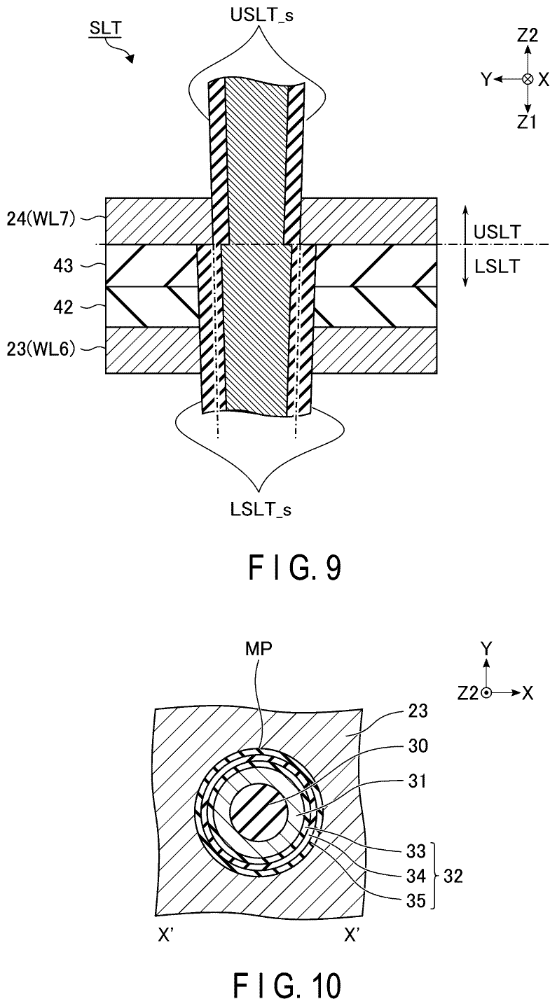

FIG. 7 is a sectional view taken along line VII-VII in FIG. 6, illustrating an example of a sectional structure in the memory area of the memory cell array included in the semiconductor memory device according to the first embodiment. As illustrated in FIG. 7, the memory cell array 10 further includes interconnect layers 21 to 26 and insulating layers 40 to 47. FIG. 8 is an enlarged view of area VIII in FIG. 7, illustrating an example of a sectional structure of the memory pillar included in the semiconductor memory device according to the first embodiment. FIG. 9 is an enlarged view of area IX in FIG. 7, illustrating an example of a sectional structure of a member that divides the memory cell array included in the semiconductor memory device according to the first embodiment. Note that, in FIGS. 8 and 9, some insulating layers are omitted for simplification of description. In the following description, the Z2 direction is defined as an upper side, and the Z1 direction is defined as a lower side.

The stacked interconnect included in the memory cell array 10 includes a lower stacked interconnect L and an upper stacked interconnect U. The lower stacked interconnect L includes the interconnect layer 22 corresponding to the select gate line SGS and a plurality of the interconnect layers 23 corresponding to the word lines WL0 to WL6. The upper stacked interconnect U includes the interconnect layers 24 corresponding to the word lines WL7 to WL14 and the interconnect layer 25 corresponding to the select gate line SGD.

The interconnect layer 21 is stacked above the semiconductor substrate W2 (not illustrated). The interconnect layer 21 is formed in, for example, a plate shape extending along the X direction on the XY plane. The interconnect layer 21 is used as the source line SL. The interconnect layer 21 contains, for example, phosphorus-doped silicon.

The insulating layer 41 and the interconnect layer 22 are stacked in this order above the interconnect layer 21. The interconnect layer 22 is formed in, for example, a plate shape extending along the X direction on the XY plane. The interconnect layer 22 is used as the select gate line SGS. The interconnect layer 22 contains, for example, tungsten or molybdenum.

The insulating layers 42 and the interconnect layers 23 are alternately stacked above the interconnect layer 22. The interconnect layer 23 is formed in, for example, a plate shape extending along the X direction on the XY plane. The interconnect layers 23 are used as the word lines WL0 to WL6 in order from the interconnect layer 22 side. The interconnect layer 23 contains, for example, tungsten or molybdenum.

The insulating layer 43 is stacked above the uppermost insulating layer 42. The interconnect layers 24, which are stacked above the insulating layer 43 in an alternating manner with the insulating layers 44, is formed in, for example, a plate shape extending along the X direction on the XY plane. The interconnect layers 24 are used as the word lines WL7 to WL14 in order from the insulating layer 43 side. The interconnect layer 24 contains, for example, tungsten or molybdenum.

The interconnect layer 25, the insulating layer 45, and the insulating layer 46 are stacked in this order above the uppermost insulating layer 44. The interconnect layer 25 is formed in, for example, a plate shape extending along the X direction on the XY plane. The interconnect layer 25 is used as the select gate line SGD. The interconnect layer 25 contains, for example, tungsten or molybdenum.

The interconnect layer 26 is stacked above the insulating layer 46. The interconnect layer 26 is formed in, for example, a line shape extending along the Y direction. The interconnect layer 26 is used as the bit line BL. In an area (not illustrated), the plurality of interconnect layers 26 are arranged along the X direction. The interconnect layer 26 contains, for example, copper.

The insulating layer 47 is stacked above the interconnect layer 26. The insulating layer 47 is a layer coupled to the joint layer B2 and includes a plurality of interconnects (not illustrated).

After the semiconductor substrate W2 (not illustrated) is removed, the insulating layer 40 is provided below the interconnect layer 21. The insulating layer 40 corresponds to the interconnect layer 300 and includes a plurality of interconnects (not illustrated).

Each memory pillar MP is provided extending along the Z direction. Each memory pillar MP includes an upper pillar UMP and a lower pillar LMP. The lower pillar LMP extends through the lower stacked interconnect L, that is, the interconnect layers 22 and 23, and the insulating layers 41 to 43. The upper pillar UMP extends through the upper stacked interconnect U, that is, the interconnect layers 24 and 25, and the insulating layers 44 and 45. The upper end of the lower pillar LMP and the lower end of the upper pillar UMP are in contact with each other at the boundary surface between the insulating layer 43 and the lowermost interconnect layer 24. For example, each of the lower pillar LMP and the upper pillar UMP has a larger sectional area (XY sectional area) along the XY plane from the lower side to the upper side. As illustrated in FIG. 8, the XY sectional area of the upper end of the lower pillar LMP is larger than the XY sectional area of the lower end of the upper pillar UMP. A side surface LMP_s of the lower pillar LMP and the extension of a side surface UMP_s of the upper pillar UMP (denoted by one-dot chain lines in FIG. 8) are displaced from each other and do not coincide with each other. Such a displacement between the side surface LMP_s of the lower pillar LMP and the extension of the side surface UMP_s of the upper pillar UMP may be generated not only in a YZ section illustrated in FIG. 8 but also in any section including the Z direction.

In addition, each memory pillar MP includes, for example, a core film 30, a semiconductor film 31, and a stacked film 32. The core film 30 is provided extending along the Z direction. For example, the upper end of the core film 30 is positioned in the insulating layer 46, and the lower end of the core film 30 is positioned in the interconnect layer 21. The core film 30 includes, for example, an insulator such as silicon oxide. The semiconductor film 31 covers the periphery of the core film 30, for example. At the lower end of the memory pillar MP, a part of the semiconductor film 31 is in contact with the interconnect layer 21. The semiconductor film 31 contains, for example, silicon. The stacked film 32 covers the side surface and the bottom surface of the semiconductor film 31 except for a portion where the semiconductor film 31 and the interconnect layer 21 are in contact with each other.

In the structure of the memory pillar MP illustrated in FIG. 7, a portion where the memory pillar MP and the interconnect layer 22 intersect each other functions as the select transistor ST2. Portions where the memory pillars MP and each of the interconnect layers 23 and 24 function as the memory cell transistors MT0 to MT14, respectively. A portion where the memory pillar MP and the interconnect layer 25 intersect each other functions as the select transistor ST1.

The columnar contact CV is provided on the upper surface of the semiconductor film 31 in the memory pillar MP. In the area illustrated in FIG. 7, two contacts CV respectively corresponding to two memory pillars MP among six memory pillars MP are displayed. To the memory pillar MP that does not overlap the member SHE and is not coupled to the contact CV in this area, another contact CV is coupled in an area (not illustrated).

One interconnect layer 26, that is, one bit line BL is in contact with the upper surface of each contact CV. One contact CV is coupled to one interconnect layer 26 in each of the spaces partitioned by the members SLT and SHE. That is, for example, one memory pillar MP in each area between the adjacent members SLT and SHE and one memory pillar MP in each area between the two adjacent members SHE are electrically coupled to each interconnect layer 26.

The member SLT is formed so as to extend along the XZ plane, for example. Each member SLT includes, for example, an upper member USLT and a lower member LSLT. The lower member LSLT extends through the lower stacked interconnect L, that is, the interconnect layers 22 and 23, and the insulating layers 41 to 43. The upper member USLT extends through the upper stacked interconnect U, that is, the interconnect layers 24 and 25, and the insulating layers 44 and 45. The upper end of the lower member LSLT and the lower end of the upper member USLT are in contact with each other at the boundary surface between the insulating layer 43 and the lowermost interconnect layer 24. For example, the width of each of the lower member LSLT and the upper member USLT in the Y direction increases from the lower side to the upper side. As illustrated in FIG. 9, the width in the Y direction of the upper end of the lower member LSLT is greater than the width in the Y direction of the lower end of the upper member USLT. A side surface LSLT s of the lower member LSLT and the extension of a side surface USLT_s of the upper member USLT (denoted by one-dot chain lines in FIG. 9) are displaced from each other and do not coincide with each other.

In the member SLT, the contact LI is provided so as to extend along the XZ plane, and the spacer SP is provided between the contact LI and the interconnect layers 22 to 25. The upper end of the contact LI is positioned, for example, in the insulating layer 46. The lower end of the contact LI is in contact with, for example, the interconnect layer 21. Note that the contact LI may be omitted depending on the structure of the memory cell array 10.

The member SHE is formed in, for example, a plate shape extending along the XZ plane and divides the interconnect layer 25. The upper end of the member SHE is positioned in the insulating layer 46. The lower end of the member SHE is positioned in the uppermost insulating layer 44. The member SHE includes, for example, an insulator such as silicon oxide. Note that the upper end of the member SHE and the upper end of the member SLT may be aligned or may not be aligned. In addition, the upper end of the member SHE and the upper end of the memory pillar MP may be aligned or may not be aligned.

FIG. 10 is a sectional view taken along line X′-X′ in FIG. 7, illustrating an example of a sectional structure of the memory pillar included in the semiconductor memory device according to the first embodiment. More specifically, FIG. 10 illustrates a sectional structure of the memory pillar MP in a layer being parallel to the surface of the semiconductor substrate W2 (not illustrated) and including the interconnect layer 23. As illustrated in FIG. 10, the stacked film 32 includes, for example, a tunnel insulating film 33, a charge storage film 34, and a block insulating film 35.

In the section including the interconnect layer 23, the core film 30 is provided, for example, at the central portion of the memory pillar MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The interconnect layer 23 surrounds the side surface of the block insulating film 35.

The semiconductor film 31 is used as a channel (current path) of the memory cell transistors MT0 to MT14 and the select transistors ST1 and ST2. Each of the tunnel insulating film 33 and the block insulating film 35 contains, for example, silicon oxide. The charge storage film 34 has a function of storing charges and contains, for example, silicon nitride. With this structure, each memory pillar MP can function as, for example, one NAND string NS.

### 1.1.5.3 Hookup Area

### (Planar Layout)

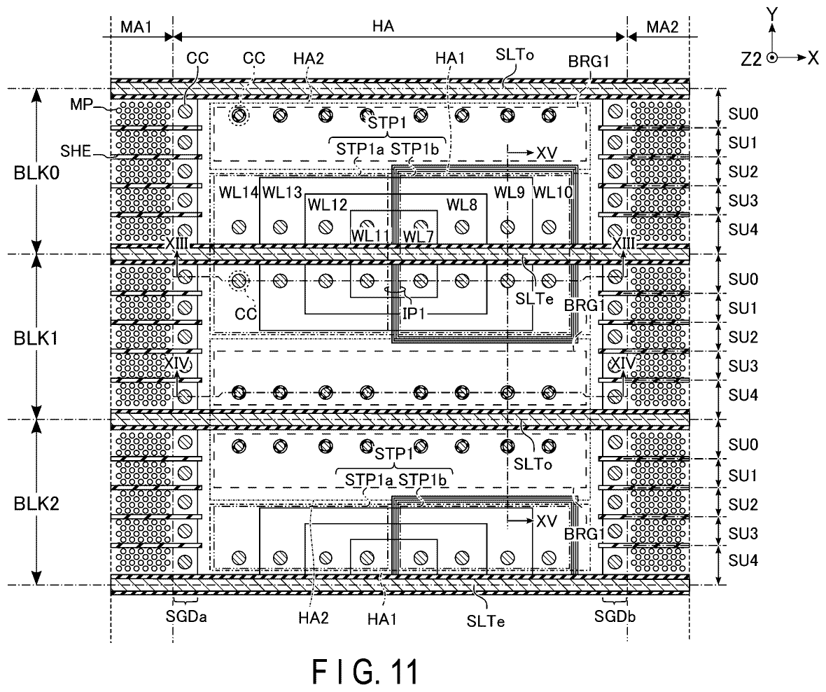

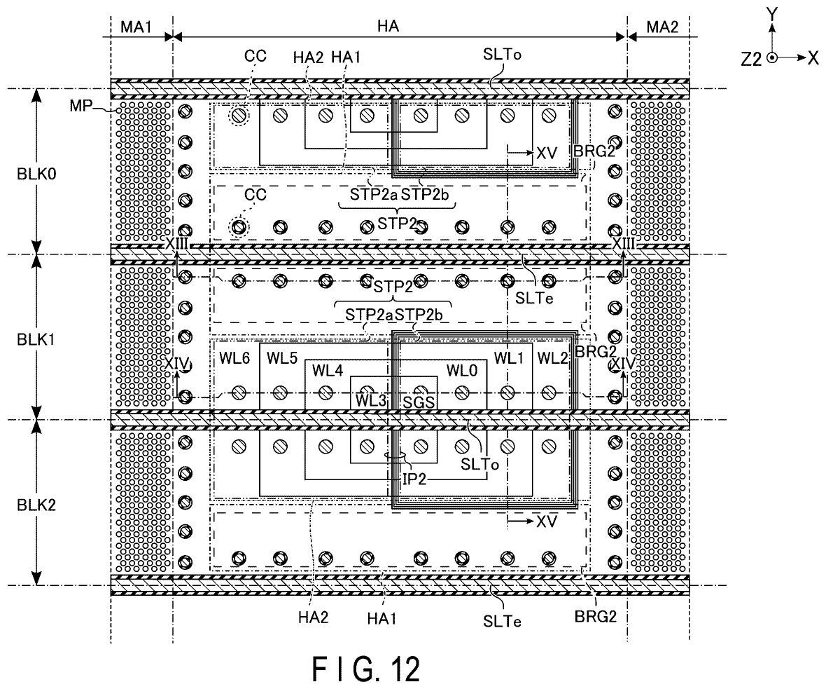

FIG. 11 is a plan view illustrating an example of a planar layout of an upper stacked interconnect in the hookup area of the memory cell array included in the semiconductor memory device according to the first embodiment. FIG. 12 is a plan view illustrating an example of a planar layout of a lower stacked interconnect in the hookup area of the memory cell array included in the semiconductor memory device according to the first embodiment. FIGS. 11 and 12 illustrate the hookup area HA and a part of the memory areas MA1 and MA2 near the hookup area HA. The areas illustrated in FIGS. 11 and 12 correspond to the blocks BLK0 to BLK2. Note that, in FIGS. 11 and 12, some insulating layers are omitted for simplification of description.

As illustrated in FIGS. 11 and 12, in the hookup area HA, the memory cell array 10 includes a plurality of contacts CC.

As illustrated in FIG. 11, the select gate line SGD includes a first portion SGDa coupled to the memory area MA1 and a second portion SGDb coupled to the memory area MA2. In addition, the select gate line SGD has five portions divided in the Y direction by the plurality of members SHE in each of the first portion SGDa and the second portion SGDb. Portions of the select gate line SGD divided in the Y direction by the plurality of members SHE are insulated from each other. That is, in one block BLK, the select gate line SGD is divided into ten pieces. One contact CC is provided for each of the ten divided select gate lines SGD. Note that the contacts CC provided in the first portion SGDa and the contacts CC provided in the second portion SGDb of the select gate line SGD corresponding to each other are electrically coupled to each other via an upper interconnect layer (not illustrated).

As illustrated in FIG. 11, in the hookup area HA1, each interconnect layer 24 included in the upper stacked interconnect U excluding the interconnect layer 25 corresponding to the select gate line SGD includes a terrace portion that does not overlap the upper interconnect layer 24 or 25 in the upper stacked interconnect U. As illustrated in FIG. 12, in the hookup area HA2, each of the interconnect layers 22 and 23 included in the lower stacked interconnect L includes a terrace portion that does not overlap the upper interconnect layers 23 in the lower stacked interconnect L. Note that the terrace portion of the lower stacked interconnect L may overlap the interconnect layer 24 included in the upper stacked interconnect U. Shapes of terrace portions of the upper stacked interconnect U and the lower stacked interconnect L in the hookup areas HA1 and HA2 are similar to steps, terraces, rimstone, and the like. Each of the contacts CC is coupled to the corresponding terrace portion of each of the interconnect layers 22 to 24.

As illustrated in FIG. 11, in each interconnect layer 24 included in the upper stacked interconnect U, one stepped area STP1 is provided for each two blocks BLK. The stepped area STP1 is provided so as to straddle the member SLTe in the Y direction. In the stepped area STP1, a first stadium-shaped stepped structure is formed. The first stadium-shaped stepped structure is a structure in which a terrace portion of an upper interconnect layer is formed so as to surround a terrace portion of a lower interconnect layer from four sides in plan view. In other words, the first stadium-shaped stepped structure has a structure recessed stepwise toward the central portion. The first stadium-shaped stepped structure is provided so as to straddle the member SLTe and has a symmetrical structure with respect to the member SLTe.

The plurality of interconnect layers 24 included in the upper stacked interconnect U include an inclined portion IP1 in the hookup area HA. The inclined portion IP1 is a level difference provided in a rectangular shape in a plan view and including end portions of a plurality of (four in the example illustrated in FIG. 11) interconnect layers 24 continuously stacked. A part of the inclined portion IP1 is provided so as to cross the stepped area STP1 in the Y direction. In the inclined portion IP1, the end portions of the plurality of interconnect layers 24 continuously stacked are inclined at substantially the same inclination angle in the oblique direction on the XZ plane and the YZ plane and form an inclined surface. The inclined portion IP1 is provided so as to surround a portion of the first stadium-shaped stepped structure on the memory area MA2 side with respect to a central portion along the X direction. The stepped area STP1 is divided into stepped areas STP1a and STP1b by the inclined portion IP1. The stepped areas STP1a and STP1b are provided side by side in the X direction.

The stepped area STP1a includes an area between the memory area MA1 and the inclined portion IP1 outside the inclined portion IP1 of the stepped area STP1. In the stepped area STP1a, terrace portions of the word lines WL11 to WL14 are provided. Specifically, the terrace portion of the word line WL11 is surrounded by the word line WL12. The terrace portion of the word line WL12 is surrounded by the word line WL13. The terrace portion of the word line WL13 is surrounded by the word line WL14. That is, in the stepped area STP1a, the first stadium-shaped stepped structure has a stepwise structure in three directions including: a direction ascending from the terrace portion of the word line WL11 toward the memory area MA1 side; and directions ascending from the terrace portion of the word line WL11 respectively toward sides of two hookup areas HA2 provided so as to sandwich, in the Y direction, the hookup area HA1 in which the first stadium-shaped stepped structure is provided.

The stepped area STP1b is an area including the inside of the inclined portion IP1 of the stepped area STP1. In the stepped area STP1b, terrace portions of the word lines WL7 to WL10 are provided. Specifically, the terrace portion of the word line WL7 is surrounded by the word line WL8. The terrace portion of the word line WL8 is surrounded by the word line WL9. The terrace portion of the word line WL9 is surrounded by the word line WL10. That is, in the stepped area STP1b, the first stadium-shaped stepped structure has a stepwise structure in three directions including: a direction ascending from the terrace portion of the word line WL7 toward the memory area MA2 side; and directions ascending from the terrace portion of the word line WL7 respectively toward sides of two hookup areas HA2 provided so as to sandwich, in the Y direction, the hookup area HA1 in which the first stadium-shaped stepped structure is provided.

The plurality of interconnect layers 24 included in the upper stacked interconnect U includes a bridge portion BRG1 in the hookup area HA2. In each of the plurality of interconnect layers 24 included in the upper stacked interconnect U, a portion provided in the memory area MA1 and a portion provided in the memory area MA2 are coupled via the bridge portion BRG1. That is, a portion provided in the memory area MA1 and a portion provided in the memory area MA2 of each interconnect layer 24 included in the upper stacked interconnect U have equal potentials.

Note that, in the example illustrated in FIG. 11, the stepped area STP1 is configured to lie within the hookup area HA1, but the present invention is not limited thereto. As long as each interconnect layer 24 included in the upper stacked interconnect U includes the terrace portion coupled to the corresponding contact CC in the hookup area HA1 and includes the bridge portion BRG1 in the hookup area HA2, a part of the stepped area STP1 may be provided in the hookup area HA2.

As illustrated in FIG. 12, in each of the interconnect layers 22 and 23 included in the lower stacked interconnect L, one stepped area STP2 is provided for each two blocks BLK. The stepped area STP2 is provided so as to straddle the member SLTo in the Y direction. In the stepped area STP2, a second stadium-shaped stepped structure is formed. The second stadium-shaped stepped structure is a structure in which a terrace portion of an upper interconnect layer is formed so as to surround a terrace portion of a lower interconnect layer from four sides in plan view. In other words, the second stadium-shaped stepped structure has a structure recessed stepwise toward the central portion. The second stadium-shaped stepped structure is provided so as to straddle the member SLTo and has a symmetrical structure with respect to the member SLTo.

The plurality of interconnect layers 22 and 23 included in the lower stacked interconnect L include an inclined portion IP2 in the hookup area HA. The inclined portion IP2 is a level difference provided in a rectangular shape in a plan view and including end portions of a plurality of (four in the example illustrated in FIG. 12) interconnect layers 22 and 23 continuously stacked. A part of the inclined portion IP2 is provided to cross the stepped area STP2 in the Y direction. In the inclined portion IP2, the end portions of the plurality of interconnect layers 22 and 23 continuously stacked are inclined at substantially the same inclination angle in the oblique direction on the XZ plane and the YZ plane and form an inclined surface. The inclined portion IP2 is provided so as to surround a portion of the second stadium-shaped stepped structure on the memory area MA2 side with respect to a central portion along the X direction. The stepped area STP2 is divided into stepped areas STP2a and STP2b by the inclined portion IP2. The stepped areas STP2a and STP2b are provided side by side in the X direction.

The stepped area STP2a is an area including a portion between the memory area MA1 and the inclined portion IP2 outside the inclined portion IP2 of the stepped area STP2. In the stepped area STP2a, terrace portions of the word lines WL3 to WL6 are provided. Specifically, the terrace portion of the word line WL3 is surrounded by the word line WL4. The terrace portion of the word line WL4 is surrounded by the word line WL5. The terrace portion of the word line WL5 is surrounded by the word line WL6. That is, in the stepped area STP2a, the second stadium-shaped stepped structure has a stepwise structure in three directions including: a direction ascending from the terrace portion of the word line WL3 toward the memory area MA1 side; and directions ascending from the terrace portion of the word line WL3 respectively toward sides of two hookup areas HA1 provided so as to sandwich, in the Y direction, the hookup area HA2 in which the second stadium-shaped stepped structure is provided.

The stepped area STP2b is an area including the inside of the inclined portion IP2 of the stepped area STP2. In the stepped area STP2b, terrace portions of the select gate line SGS and the word lines WL0 to WL2 are provided. Specifically, the terrace portion of the select gate line SGS is surrounded by the word line WL0. The terrace portion of the word line WL0 is surrounded by the word line WL1. The terrace portion of the word line WL1 is surrounded by the word line WL2. That is, in the stepped area STP2b, the second stadium-shaped stepped structure has a stepwise structure in three directions including: a direction ascending from the terrace portion of the select gate line SGS toward the memory area MA2 side; and directions ascending from the terrace portion of the select gate line SGS respectively toward sides of two hookup areas HA1 provided so as to sandwich, in the Y direction, the hookup area HA2 in which the second stadium-shaped stepped structure is provided.

The plurality of interconnect layers 22 and 23 included in the lower stacked interconnect L includes a bridge portion BRG2 in the hookup area HA1. In each of the plurality of interconnect layers 22 and 23 included in the lower stacked interconnect L, a portion provided in the memory area MA1 and a portion provided in the memory area MA2 are coupled via the bridge portion BRG2. That is, a portion provided in the memory area MA1 and a portion provided in the memory area MA2 of each of the interconnect layers 22 and 23 included in the lower stacked interconnect L have equal potentials.

Note that, in the example illustrated in FIG. 12, the stepped area STP2 is configured to lie within the hookup area HA2, but the present invention is not limited thereto. As long as each of the interconnect layers 22 and 23 included in the lower stacked interconnect L includes the terrace portion coupled to the corresponding contact CC in the hookup area HA2 and includes the bridge portion BRG2 in the hookup area HA1, a part of the stepped area STP2 may be provided in the hookup area HA1.

The plurality of contacts CC are provided corresponding to the select gate lines SGS and SGD and the word lines WL0 to WL14, respectively. As illustrated in FIGS. 11 and 12, the plurality of contacts CC corresponding to the select gate lines SGD are provided side by side in the Y direction for each line of the contacts CC corresponding to respective one of the first portion SGDa and the second portion SGDb. Among the interconnect layers 24 and 25 included in the upper stacked interconnect U, the plurality of contacts CC corresponding to the interconnect layers 24 excluding the interconnect layer 25 corresponding to the select gate line SGD are provided side by side in the X direction in the hookup area HA1. For example, the contacts CC provided in the hookup area HA1 correspond to the word lines WL14, WL13, WL12, WL11, WL7, WL8, WL9, and WL10 in this order from the left side of the page. The plurality of contacts CC corresponding to the interconnect layers 22 and 23 included in the lower stacked interconnect L are provided side by side in the X direction in the hookup area HA2. For example, the contacts CC provided in the hookup area HA2 correspond to the word lines WL6, WL5, WL4, and WL3, the select gate line SGS, and the word lines WL0, WL1, and WL2 in this order from the left side of the page.

As illustrated in FIGS. 11 and 12, in the memory cell array 10 according to the first embodiment, the contacts CC are provided so as to be arranged in two columns in the Y direction in one block BLK. This structure is referred to as a “two-lane contact structure”.

### (Sectional Structure)

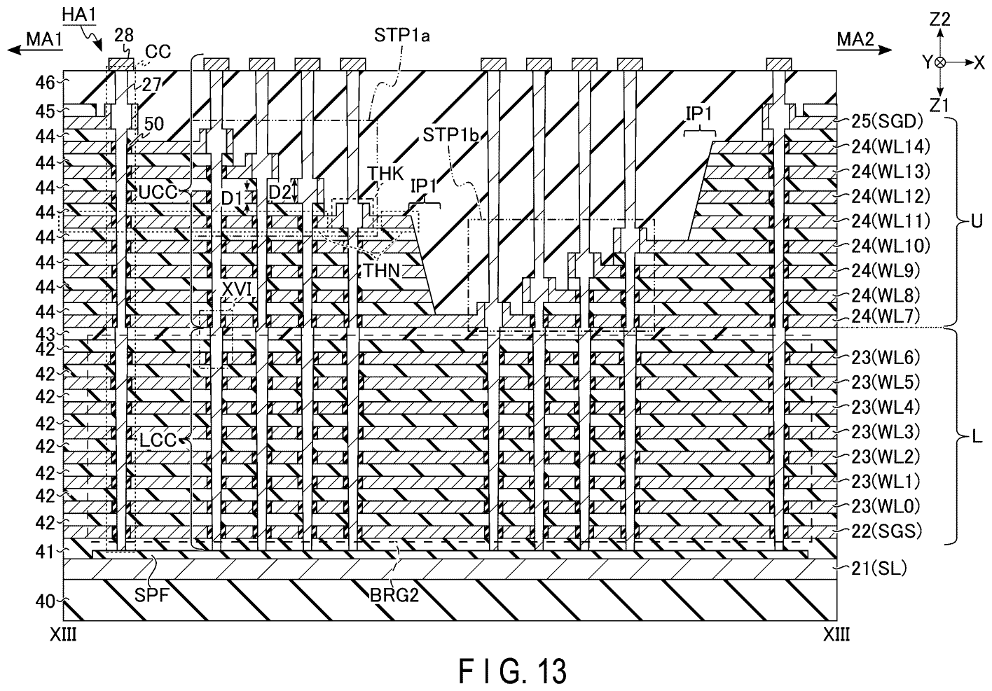

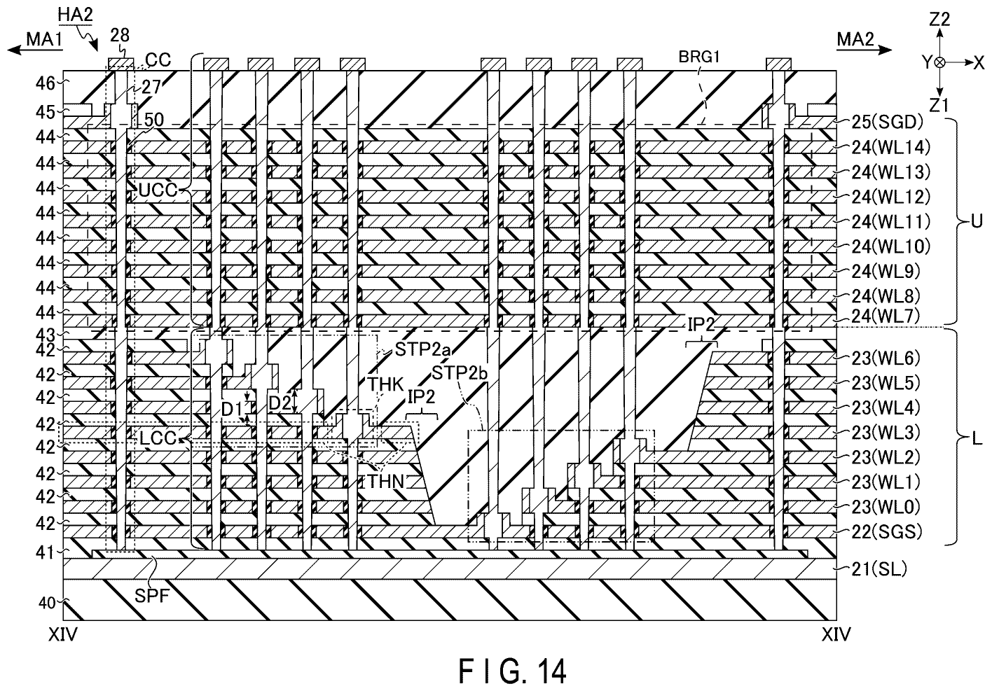

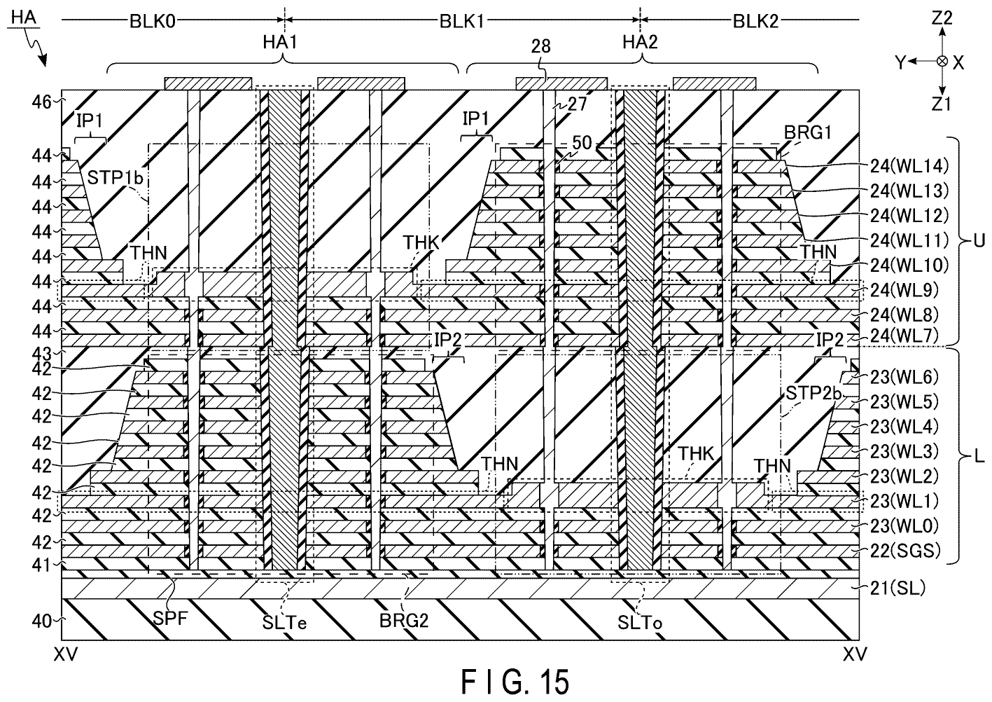

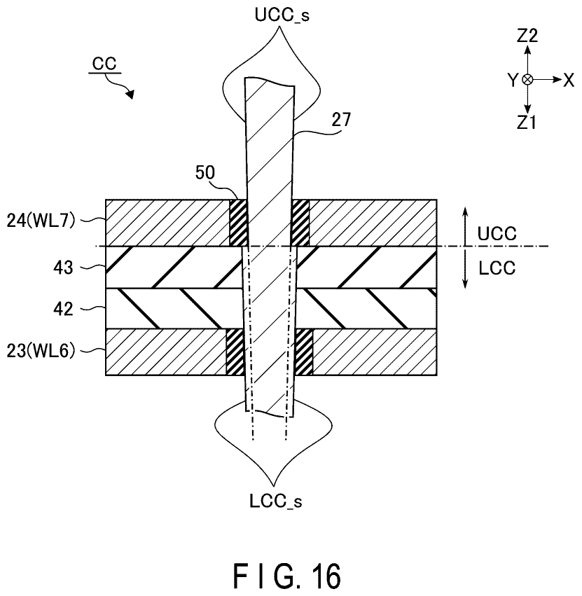

FIG. 13 is a sectional view taken along line XIII-XIII in FIGS. 11 and 12 in the hookup area of the memory cell array included in the semiconductor memory device according to the first embodiment. FIG. 14 is a sectional view taken along line XIV-XIV in FIGS. 11 and 12 in the hookup area of the memory cell array included in the semiconductor memory device according to the first embodiment. FIGS. 13 and 14 illustrate XZ sections of the hookup area HA and the contact CC in the block BLK1. FIGS. 13 and 14 correspond to the XZ sections of the hookup areas HA1 and HA2, respectively. FIG. 15 is a sectional view taken along line XV-XV in FIGS. 11 and 12 in the hookup area of the memory cell array included in the semiconductor memory device according to the first embodiment. FIG. 15 illustrates YZ sections of a part of the hookup area HA, the contact CC, and the member SLT in the blocks BLK0 to BLK2. FIG. 16 is an enlarged view of area XVI in FIG. 13, illustrating an example of a sectional structure of a contact included in the semiconductor memory device according to the first embodiment. Note that, in FIG. 16, some insulating layers are omitted for simplification of description. In the following description, in the case where any of the stepped area STP1a, STP1b, STP2a, or STP2b is not specified, it is referred to as a “stepped area STP”.

As illustrated in FIG. 13, in the hookup area HA1, the upper stacked interconnect U includes the stepped areas STP1a and STP1b. The upper stacked interconnect U has a structure descending from the memory area MA1 toward the memory area MA2, which is a part of the first stadium-shaped stepped structure, in the stepped area STP1a. The upper stacked interconnect U has a structure ascending from the memory area MA1 toward the memory area MA2, which is a part of the first stadium-shaped stepped structure, in the stepped area STP1b.

In the hookup area HA1, the lower stacked interconnect L includes the bridge portion BRG2. In the lower stacked interconnect L in the bridge portion BRG2, each of the interconnect layers 22 and 23 extends in the X direction and couples a portion provided in the memory area MA1 and a portion provided in the memory area MA2 of the interconnect layer 22 or 23.

As illustrated in FIG. 14, in the hookup area HA2, the lower stacked interconnect L includes the stepped areas STP2a and STP2b. The lower stacked interconnect L has a structure descending from the memory area MA1 toward the memory area MA2, which is a part of the second stadium-shaped stepped structure, in the stepped area STP2a. The lower stacked interconnect L has a structure ascending from the memory area MA1 toward the memory area MA2, which is a part of the second stadium-shaped stepped structure, in the stepped area STP2b.

In the hookup area HA2, the upper stacked interconnect U includes the bridge portion BRG1. In the upper stacked interconnect U in the bridge portion BRG1, each interconnect layer 24 extends in the X direction and couples a portion provided in the memory area MA1 and a portion provided in the memory area MA2 of the interconnect layer 24.

As illustrated in FIGS. 13 and 14, each of the interconnect layers 22 to 25 includes a thin film portion THN and a thick film portion THK. Each thin film portion THN extends in the X direction and has, for example, a first thickness D1 in the Z direction. The thick film portion THK is provided at each terrace portion in each stepped area STP. Each thick film portion THK has, for example, a second thickness D2 greater than the first thickness D1 in the Z direction. For example, the second thickness D2 in the Z direction of the thick film portion THK is substantially equal to the thickness obtained by adding the first thickness D1 and the thickness in the Z direction of the insulating layer provided one layer above the respective one of these interconnect layers 22 to 25. Note that the thick film portion THK may have a thickness equal to or smaller than the first thickness D1 in the Z direction depending on the configuration of the contact CC to be described later.

As illustrated in FIG. 13, in the stepped areas STP1a and STP1b, the plurality of thick film portions THK provided in the respective interconnect layers 24 included in the upper stacked interconnect U are provided side by side in the X direction. As illustrated in FIG. 14, in the stepped areas STP2a and STP2b, the plurality of thick film portions THK provided in the respective interconnect layers 22 and 23 included in the lower stacked interconnect L are provided side by side in the X direction. Each thick film portion THK is spaced apart in the X direction from the side surface of the thick film portion THK of the corresponding one of the interconnect layers 23 to 25 provided one layer above the respective one of these interconnect layers 22 to 24. That is, the plurality of thick film portions THK provided in one stepped area STP are provided apart from each other in the X direction. In addition, each thick film portion THK is spaced apart from the inclined portions IP1 and IP2 in the X direction.

As illustrated in FIG. 15, the stepped area STP1b and the stepped area STP2b are provided side by side in the Y direction at positions different from each other in the Z direction. Near the member SLT, the bridge portion BRG2 of the lower stacked interconnect L is provided below the stepped area STP1b. The bridge portion BRG1 of the upper stacked interconnect U is provided above the stepped area STP2b. Note that the stepped area STP1b and the stepped area STP2b may overlap in part each other in the Z direction. Although not illustrated, the stepped area STP1a and the stepped area STP2a are arranged in the Y direction and provided at positions different from each other in the Z direction. Near the member SLT, the bridge portion BRG2 of the lower stacked interconnect L is provided below the stepped area STP1a. The bridge portion BRG1 of the upper stacked interconnect U is provided above the stepped area STP2a. Note that the stepped area STP1a and the stepped area STP2a may overlap in part each other in the Z direction. That is, near the member SLT, in a case where the stepped area STP is provided and a stepwise structure is formed in one of the upper stacked interconnect U or the lower stacked interconnect L at the positions overlapping each other in the Z direction, the bridge portion BRG1 or BRG2 is provided and a structure in which the interconnect layers and the insulating layers are stacked is formed in the other of the upper stacked interconnect U or the lower stacked interconnect L. As illustrated in FIG. 15, the inclined portions IP1 and IP2 are provided outside the stepped area STP in the Y direction. For example, the inclined portions IP1 and IP2 may be provided at the positions overlapping each other in the Z direction. The inclined portion IP1 may be provided above the stepped area STP2b. The inclined portion IP2 may be provided below the stepped area STP1b.

As illustrated in FIG. 15, each thick film portion THK of the interconnect layers 22 to 24 is provided over two blocks BLK so as to straddle the member SLT in the Y direction. In other words, each thick film portion THK is in contact with any of the plurality of members SLT in the Y direction. For example, in the interconnect layers 24 and 25 included in the upper stacked interconnect U, the thick film portion THK of each interconnect layer 24 excluding the interconnect layer 25 corresponding to the select gate line SGD is provided so as to straddle the member SLTe in the Y direction. The thick film portion THK of each of the interconnect layers 22 and 23 included in the lower stacked interconnect L is provided so as to straddle the member SLTo in the Y direction. Although not illustrated, the thick film portion THK of the interconnect layer 25 corresponding to the select gate line SGD is provided, for example, so as to straddle all the members SLT in the Y direction except for the members SLT provided at both ends among the members SLT arranged in the Y direction. In other words, the thick film portion THK of the interconnect layer 25 in each block BLK is in contact with the member SLTo at one end portion in the Y direction and in contact with the member SLTe at the other end portion in the Y direction. Each thick film portion THK of the interconnect layers 22 to 24 is separated in the X direction from the side surface of each of the interconnect layers 23 to 25 provided one layer above the respective one of these interconnect layers 22 to 24.

As illustrated in FIGS. 13 to 15, in the hookup area HA, the memory cell array 10 further includes interconnect layers 28 and a stopper film SPF.

The plurality of contacts CC are provided extending in the Z direction. Each contact CC extends through (passes through), in the Z direction, the corresponding interconnect layer and other layers above the stopper film SPF provided at the position where the contact CC is disposed in plan view. The upper surface of each contact CC is in contact with the interconnect layer 28. The lower surface of each contact CC is in contact with the stopper film SPF. The contact CC provided extending through the stacked interconnects in the Z direction in this manner is referred to as a “through contact”.

Each contact CC includes an upper contact UCC and a lower contact LCC. The lower contact LCC extends through the lower stacked interconnect L, that is, at least a part of the interconnect layers 22 and 23 and at least a part of the insulating layers 41 to 43. The upper contact UCC extends through the upper stacked interconnect U, that is, at least a part of the interconnect layers 24 and 25 and at least a part of the insulating layers 44 and 45. The upper end of the lower contact LCC and the lower end of the upper contact UCC are in contact with each other at the boundary surface between the insulating layer 43 and the lowermost interconnect layer 24. For example, each of the lower contact LCC and the upper contact UCC has a larger sectional area (XY sectional area) along the XY plane from the lower side toward the upper side. As illustrated in FIG. 16, the XY sectional area of the upper end of the lower contact LCC is larger than the XY sectional area of the lower end of the upper contact UCC. A side surface LCC s of the lower contact LCC and the extension of a side surface UCC s of the upper contact UCC (denoted by one-dot chain lines in FIG. 16) are displaced from each other and do not coincide with each other. Such a displacement between the side surface LCC s of the lower contact LCC and the extension of the side surface UCC s of the upper contact UCC may be generated not only in the YZ section illustrated in FIG. 16 but also in any section including the Z direction.

Each of the plurality of contacts CC includes a conductor 27 and a plurality of insulators 50. The conductor 27 functions as a conductive portion of the contact CC. The conductor 27 has a shape extending in the Z direction and extends through at least a part of the plurality of interconnect layers 22 to 25 and at least a part of the insulating layer 41 to 45 in the Z direction. In a portion extending through the thick film portion THK, the conductor 27 is coupled to any one of the interconnect layers 22, 23, 24, or 25 (corresponding interconnect layer) in which the thick film portion THK is provided. The upper end of the conductor 27 is in contact with the interconnect layer 28, and the lower end of the conductor 27 is in contact with the stopper film SPF. The conductor 27 couples, as the conductive portion of the contact CC, one of the interconnect layers 22, 23, 24, or 25 corresponding to the contact CC and the interconnect layer 28. The conductor 27 contains, for example, tungsten. The plurality of insulators 50 are provided so as to surround the side surface of the conductor 27 in a portion where the conductor 27 extends through the thin film portion THN in the interconnect layers 22, 23, 24, and 25. The plurality of insulators 50 insulate the conductor 27 and the thin film portion THN through which the conductor 27 extends. That is, each contact CC is coupled to the interconnect layer 22, 23, 24, or 25 of which the thick film portion THK is passed by the contact CC among the interconnect layers 22, 23, 24, and 25 and is insulated from the interconnect layer 22, 23, 24, or 25 of which the thin film portion THN is passed by the contact CC. Note that the configuration of the contact CC is not limited to the above configuration as long as the contact CC is coupled to the corresponding interconnect layer and is insulated from other interconnect layers.

A plurality of the interconnect layers 28 are provided on the plurality of contacts CC, respectively. Each contact CC is electrically coupled to the row decoder module 16 via the interconnect layer 28.

As illustrated in FIGS. 13 to 15, in the hookup area HA, the stopper film SPF is provided above the interconnect layer 21. The stopper film SPF has an insulating property. At the time of forming holes corresponding to the plurality of contacts CC in the manufacturing process of the hookup area HA, the stopper film SPF functions as an etching stopper layer for ensuring that the lower surface of the hole does not reach the interconnect layer 21. Note that the stopper film SPF is not provided in the memory area MA1 or MA2.

### 1.2 Manufacturing Method

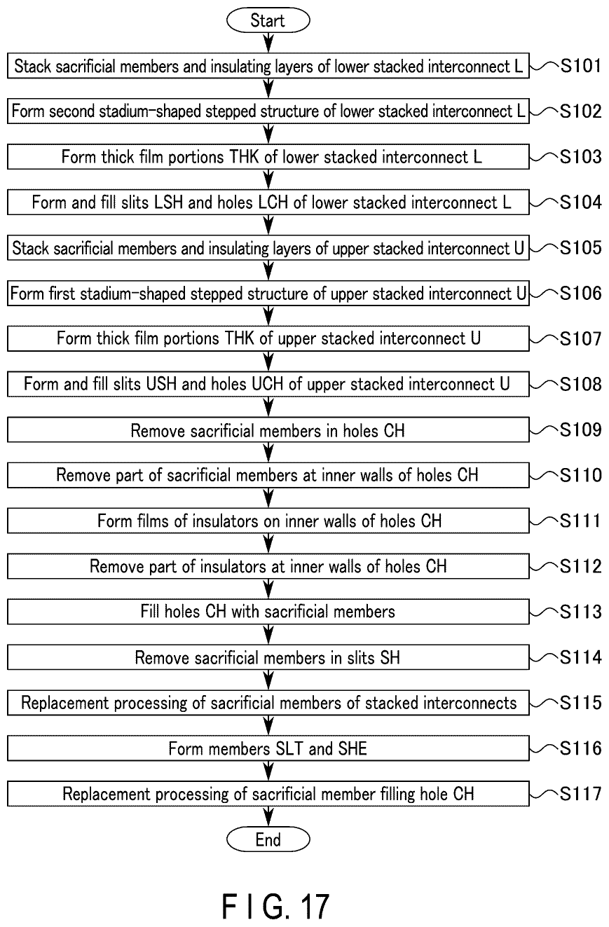

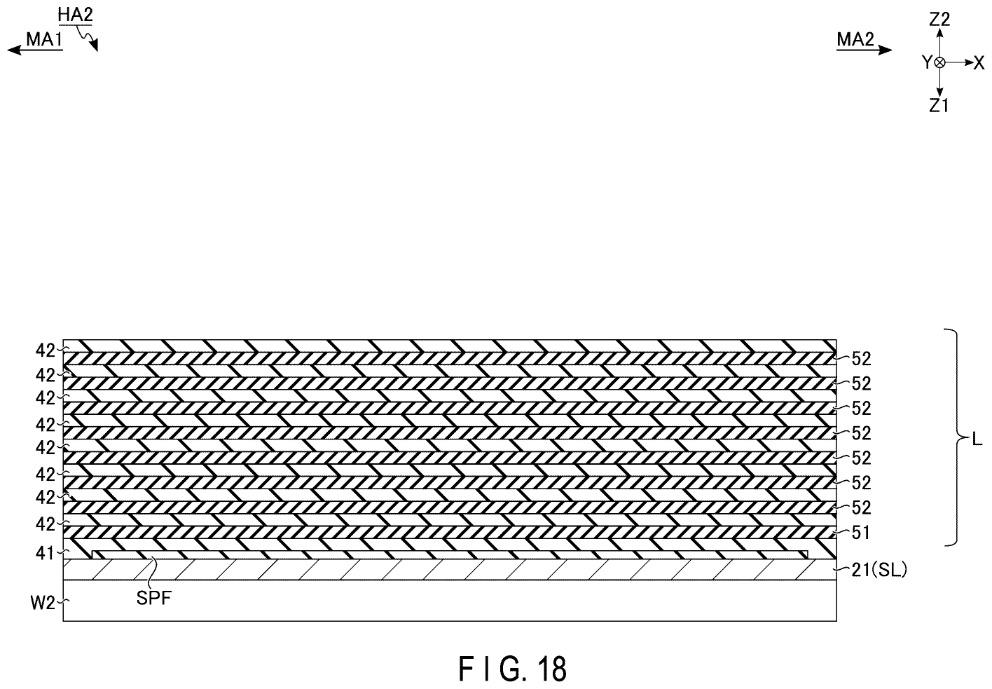

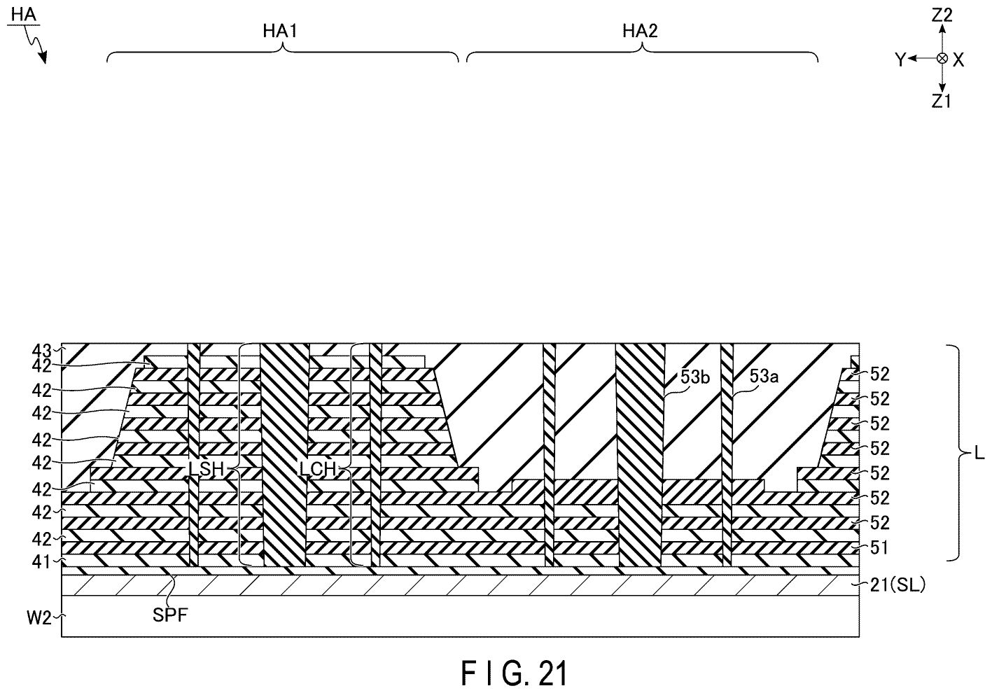

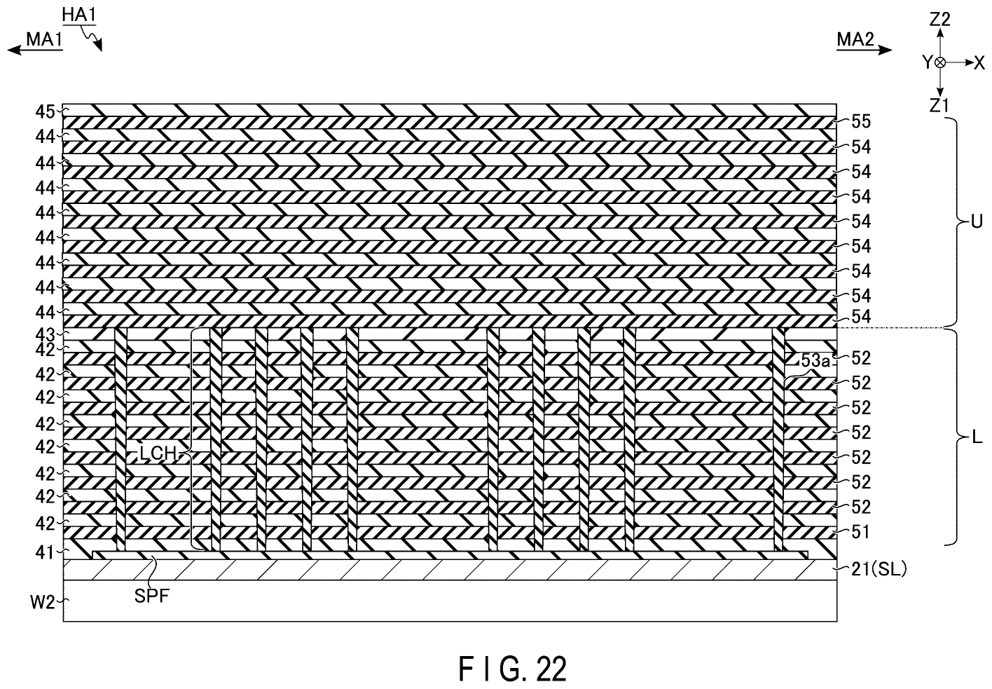

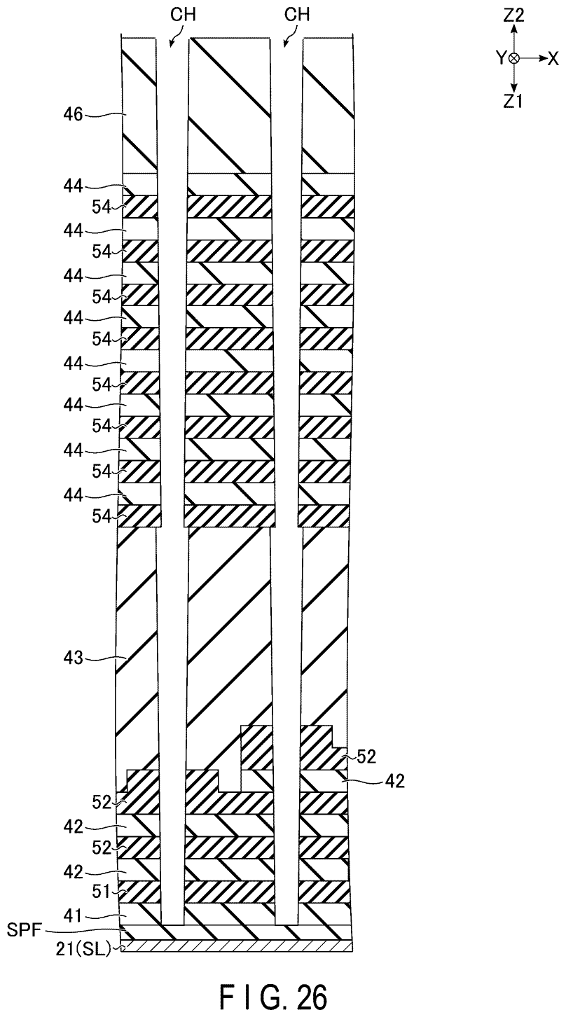

FIG. 17 is a flowchart illustrating an example of a manufacturing process of the hookup area of the memory cell array included in the semiconductor memory device according to the first embodiment. Each of FIGS. 18 to 34 is a sectional view illustrating an example of a sectional structure of the semiconductor memory device according to the first embodiment in the middle of manufacturing. FIGS. 18 to 20 correspond to the section illustrated in FIG. 14. FIGS. 21, 25, and 30 to 34 correspond to the section illustrated in FIG. 15. FIGS. 22 to 24 correspond to the section illustrated in FIG. 13. FIGS. 26 to 29 correspond to the XZ section of the area including the contact CC.

As illustrated in FIG. 17, in the manufacturing process of the hookup area HA, the processing of S101 to S117 is sequentially performed. Hereinafter, an example of a manufacturing process of the hookup area HA will be described with reference to FIGS. 18 to 34 as appropriate. Note that the hookup area HA is manufactured simultaneously with the memory areas MA1 and MA2. In the following description, manufacturing processes of the memory areas MA1 and MA2 will also be described in part.

In the present embodiment, the following case is described as an example: a method of forming structures corresponding to the interconnect layers 22, 23, 24, and 25 by using sacrificial members 51, 52, 54, and 55, respectively, and then forming the interconnect layers 22, 23, 24, and 25 by replacing the sacrificial members 51, 52, 54, and 55 with the conductive material (hereinafter, referred to as “replacement”) is adopted as a method of forming the plurality of interconnect layers 22, 23, 24, and 25 corresponding to the respective select gate lines SGS and SGD and the word lines WL0 to WL14.

First, the processing of S101 and S102 is sequentially performed, and the second stadium-shaped stepped structure is formed in the area corresponding to the lower stacked interconnect L.

Specifically, as illustrated in FIG. 18, first, the interconnect layer 21 is stacked on the semiconductor substrate W2. Next, the stopper film SPF is stacked on the interconnect layer 21. Note that the stopper film SPF is stacked only in an area corresponding to the hookup area HA, and portions stacked in the memory areas MA1 and MA2 are removed. Thereafter, the insulating layer 41 and the sacrificial member 51 are stacked in this order on the interconnect layer 21 and the stopper film SPF. On the sacrificial member 51, eight insulating layers 42 and seven layers of the sacrificial members 52 are alternately stacked one by one (S101). The uppermost layer is the insulating layer 42. The thickness of each of the sacrificial members 51 and 52 in the Z direction is equal to the first thickness D1. The insulating layers 41 and 42 contain, for example, silicon oxide (SiO). The sacrificial members 51 and 52 contain, for example, silicon nitride (SiN).

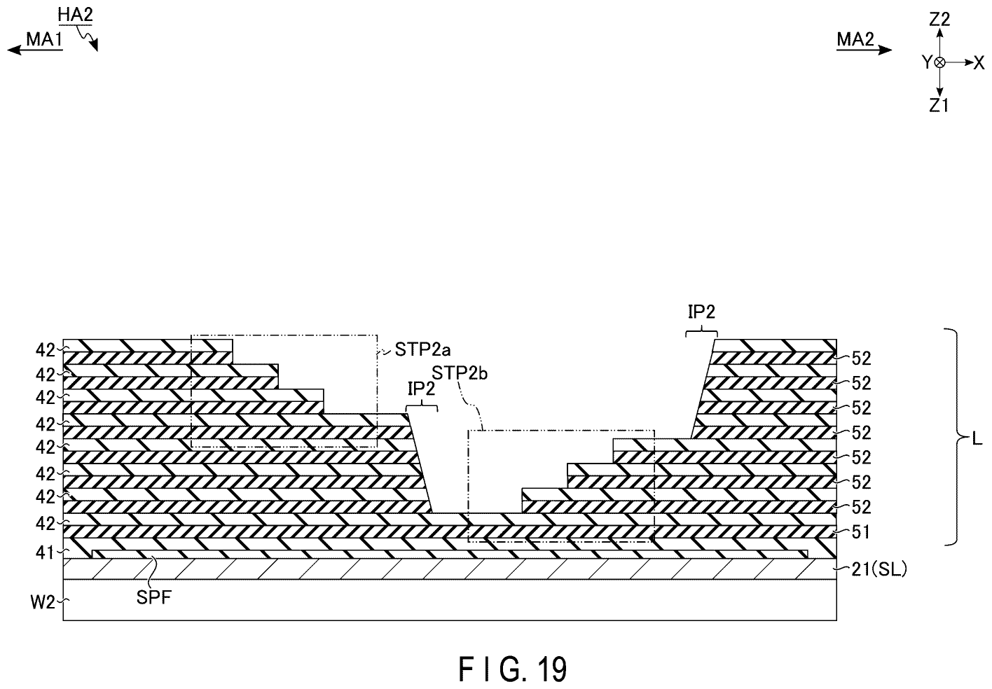

Thereafter, as illustrated in FIG. 19, the second stadium-shaped stepped structure is formed mainly in the area centered on the hookup area HA2 (S102). The second stadium-shaped stepped structure is formed by the following two steps of processing.

First, in an area corresponding to the stepped area STP2, four insulating layers 42 and four layers of the sacrificial members 52 from the upper layer are processed in a step shape in which a set of one insulating layer 42 and one layer of the sacrificial member 52 is set as one stage. Specifically, first, a mask in which a portion corresponding to the lowest stage of each of the stepped areas STP2a and STP2b is open is formed by photolithography or the like. Then, the insulating layer 42 and the sacrificial member 52 corresponding to one stage are removed by anisotropic etching using the mask. Next, a portion of the mask corresponding to the second lowest stage of each of the stepped areas STP2a and STP2b, is removed. Thereafter, the insulating layer 42 and the sacrificial member 52 corresponding to one stage are removed by anisotropic etching using the mask. As described above, by repeating the reduction in size of the masked area and the anisotropic etching, the insulating layer 42 and the sacrificial member 52 are processed in a step shape. Such processing is called “slimming”.

Secondly, multistage processing is performed on a portion corresponding to the inclined portion IP2, and the stepped structure formed in the stepped area STP2b is processed so as to correspond to the interconnect layer below the stepped structure formed in the stepped area STP2a. The multistage processing is the processing of removing a plurality of sets of insulating layers 42 and sacrificial members 52 in the process area at a time. Specifically, first, a mask in which an area corresponding to the inclined portion IP2 is open is formed by photography or the like. Then, for example, a set of the insulating layers 42 and the sacrificial members 52 corresponding to four stages are removed by anisotropic etching using the mask. This process forms a structure in which the four insulating layers 42 from the lower layer and the sacrificial member 51 and three layers of the sacrificial members 52 from the lower layer are processed in a step shape with a set of one insulating layer 42 and one layer of the sacrificial member 51 or 52 as one stage. In addition, the inclined portion IP2 is formed at the time of removing a plurality of stages by multistage processing.

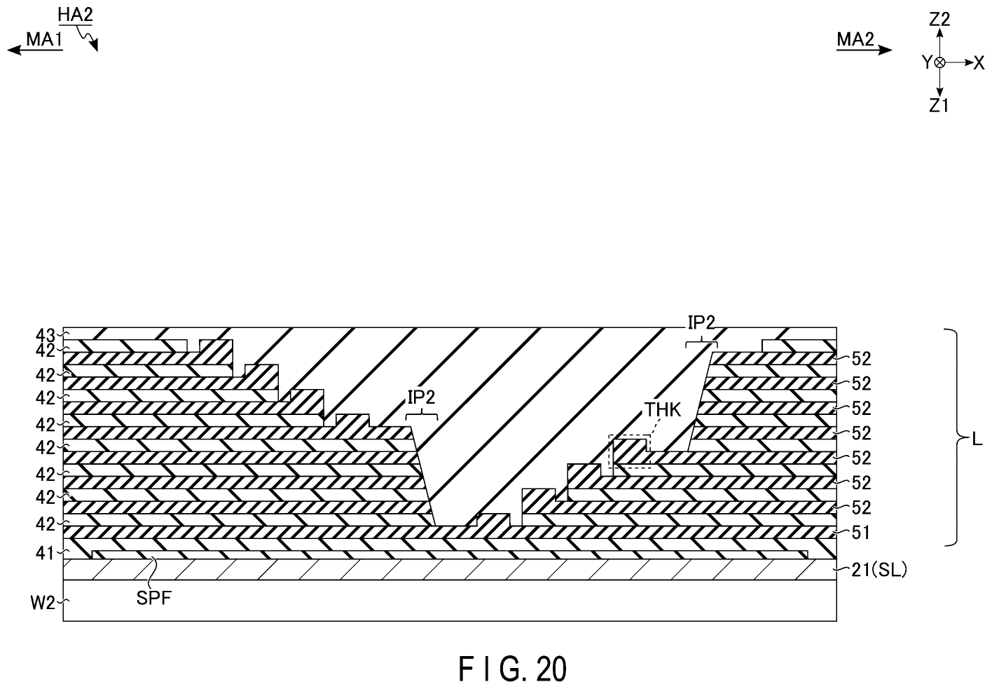

Next, the processing of S103 is performed, and structures corresponding to the thick film portions THK of the interconnect layers 22 and 23 are formed in the hookup area HA2. Thereafter, as illustrated in FIG. 20, the insulating layer 43 is stacked so as to fill the second stadium-shaped stepped structure.

Specifically, in the hookup area HA2, the insulating layer 42 exposed on the upper surface of the second stadium-shaped stepped structure is removed. Then, a sacrificial material is formed on the sacrificial members 51 and 52, and the films of the sacrificial members 51 and 52 in the stepped portion are thickened. The sacrificial material is the same material as the sacrificial members 51 and 52 and contains, for example, SiN. Thereafter, the sacrificial material formed on the uppermost insulating layer 42 is removed. In addition, in the sacrificial material obtained by thickening the films of the stepped portions of the sacrificial members 51 and 52, a portion in contact with the side surface portion of the sacrificial member 52 provided one layer above the sacrificial member 51 or 52 with the insulating layer 42 interposed therebetween and the inclined portion IP2 and a portion provided near the inclined portion IP2 are removed. In this way, portions of the sacrificial members 51 and 52 where the films thereof are thickened and that correspond to the thick film portion THK are formed. The thickness in the Z direction of the sacrificial members 51 and 52 corresponding to the thick film portion THK is equal to the second thickness D2.

The second stadium-shaped stepped structure is then filled with the insulating layer 43. The insulating layer 43 contains, for example, tetra ethoxy silane (TEOS). For example, the surface of the insulating layer 43 is planarized by chemical mechanical polishing (CMP).

Next, the processing of S104 is performed, and a plurality of slits LSH and a plurality of holes LCH corresponding to the lower members LSLT and the lower contacts LCC are formed. Thereafter, as illustrated in FIG. 21, the plurality of slits LSH and the plurality of holes LCH are filled with a sacrificial member 53.

Specifically, first, a mask in which an area corresponding to each lower member LSLT and each lower contact LCC is open is formed by photolithography or the like. Then, a plurality of slits LSH corresponding to the respective lower members LSLT and the plurality of holes LCH corresponding to the respective lower contacts LCC are formed by anisotropic etching using the mask. Each slit LSH and each hole LCH extend through each of the insulating layers 41, 42, and 43 and the sacrificial members 51 and 52. A part of the stopper film SPF is exposed at the bottom portion of each slit LSH and each hole LCH.

Thereafter, the plurality of slits LSH and the plurality of holes LCH are filled with the sacrificial member 53. The sacrificial member 53 contains, for example, amorphous silicon. Hereinafter, the sacrificial member 53 provided so as to fill the plurality of holes LCH is defined as a sacrificial member 53a. The sacrificial member 53 provided so as to fill the plurality of slits LSH is defined as a sacrificial member 53b.

Note that, in the same step as S104, in the memory areas MA1 and MA2, for example, a plurality of holes corresponding to the lower pillars LMP are formed. This hole forming processing is similar to the processing of forming the holes LCH. Thereafter, a plurality of holes corresponding to the lower pillars LMP are filled with the sacrificial member.

Subsequently, the processing of S105 and S106 is sequentially performed, and the first stadium-shaped stepped structure is formed in the area corresponding to the upper stacked interconnect U.

Specifically, as illustrated in FIG. 22, eight layers of the sacrificial members 54 and eight insulating layers 44 are alternately stacked one by one on the insulating layer 43. The uppermost layer is the insulating layer 44. The sacrificial member 55 and the insulating layer 45 are stacked in this order on the uppermost insulating layer 44 (S105). The thickness of each of the sacrificial members 54 and 55 in the Z direction is equal to the first thickness D1. The insulating layers 44 and 45 contain, for example, SiO. The sacrificial members 54 and 55 contain, for example, SiN.

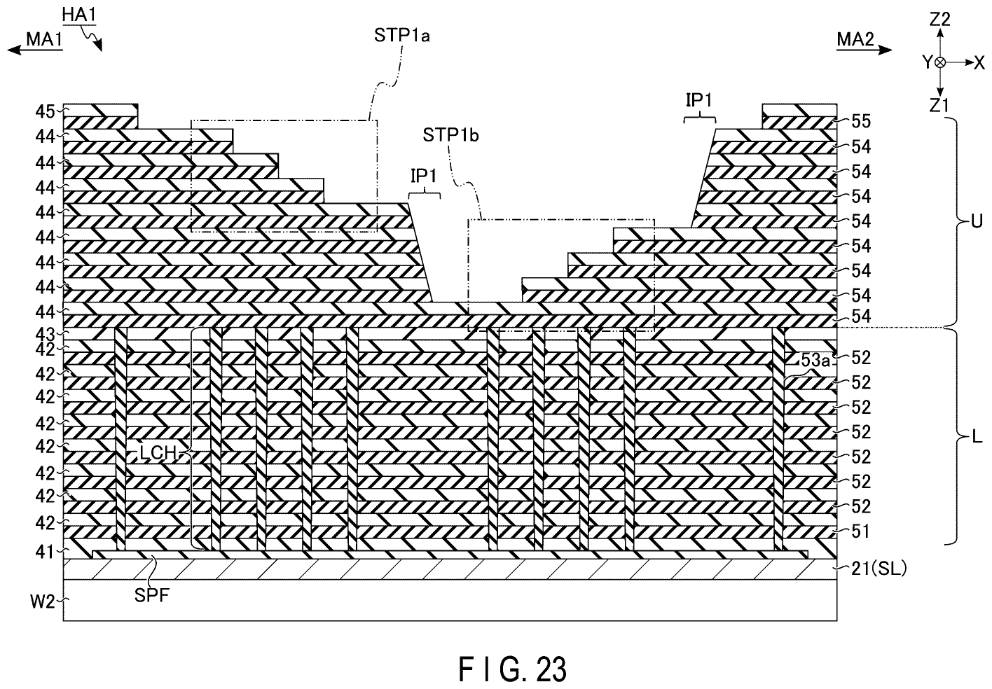

Thereafter, as illustrated in FIG. 23, the first stadium-shaped stepped structure is formed mainly in the area centered on the hookup area HA1 (S106). The first stadium-shaped stepped structure is formed by the following three steps of processing.

First, in the area corresponding to the stepped area STP1, the insulating layer 45, the three insulating layers 44 from the upper layer, the sacrificial member 55 and the three layers of the sacrificial members 54 from the upper layer are processed in a step shape in which a set of the insulating layer 45 and the sacrificial member 55 or a set of the one insulating layer 44 and the one layer of the sacrificial member 54 is set as one stage by slimming.

Secondly, multistage processing is performed on a portion corresponding to the inclined portion IP1, and the stepped structure formed in the stepped area STP1b is processed so as to correspond to the interconnect layer below the stepped structure formed in the stepped area STP1a. By the multistage processing, for example, a set of the insulating layer 45 and the sacrificial member 55 and a set of the insulating layers 44 and the sacrificial members 54 corresponding to three stages are removed. The inclined portion IP1 is formed at the time of removing a plurality of stages by multistage processing.

Thirdly, in the area where the hookup areas HA1 and HA2 are arranged in the Y direction, for example, a set of the insulating layer 45 and the sacrificial member 55 or a set of one insulating layer 44 and one layer of the sacrificial member 54 corresponding to one stage is removed by anisotropic etching. By this processing, the insulating layer 45 and the sacrificial member 55 are divided into a portion in contact with the memory area MA1 and a portion in contact with the memory area MA2.

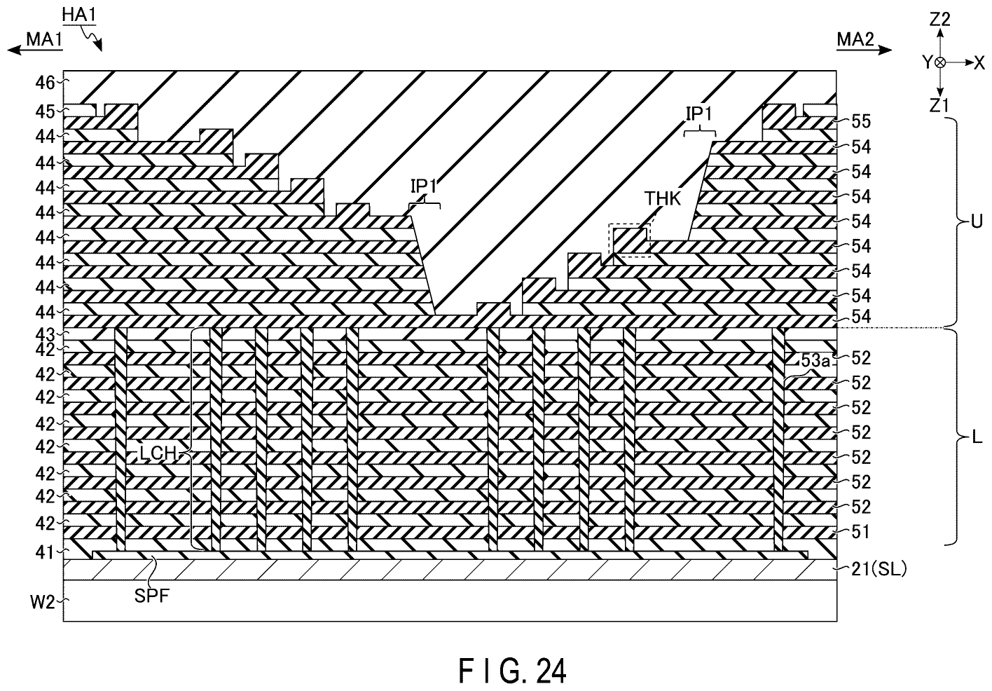

Next, the processing of S107 is performed, and structures corresponding to the thick film portions THK of the interconnect layers 24 and 25 are formed in the hookup area HA1. Thereafter, as illustrated in FIG. 24, the insulating layer 46 is stacked so as to fill the first stadium-shaped stepped structure.

Specifically, in the hookup area HA1, a part of the insulating layer 44 exposed on the upper surface of the first stadium-shaped stepped structure and the insulating layer 45 provided at the terrace portion of the select gate line SGD are removed. Then, a sacrificial material is formed on the sacrificial members 54 and 55, and the films of the sacrificial members 54 and 55 in the stepped portion are thickened. The sacrificial material is the same material as the sacrificial members 54 and 55 and contains, for example, SiN. Thereafter, the sacrificial member formed on the insulating layer 45 is removed. In addition, in the sacrificial material obtained by thickening the films of the stepped portions of the sacrificial members 54 and 55, a portion in contact with the side surface portion of the sacrificial member 54 or 55 provided one layer above the sacrificial member 54 with the insulating layer 44 interposed therebetween and the inclined portion IP1 and a portion provided near the inclined portion IP1 are removed. In this way, portions of the sacrificial members 54 and 55 where the films thereof are thickened and that correspond to the thick film portion THK are formed. The thickness in the Z direction of the sacrificial members 54 and 55 corresponding to the thick film portion THK is equal to the second thickness D2.

The first stadium-shaped stepped structure is then filled with the insulating layer 46. The insulating layer 46 contains, for example, TEOS. For example, the surface of the insulating layer 46 is planarized by CMP.

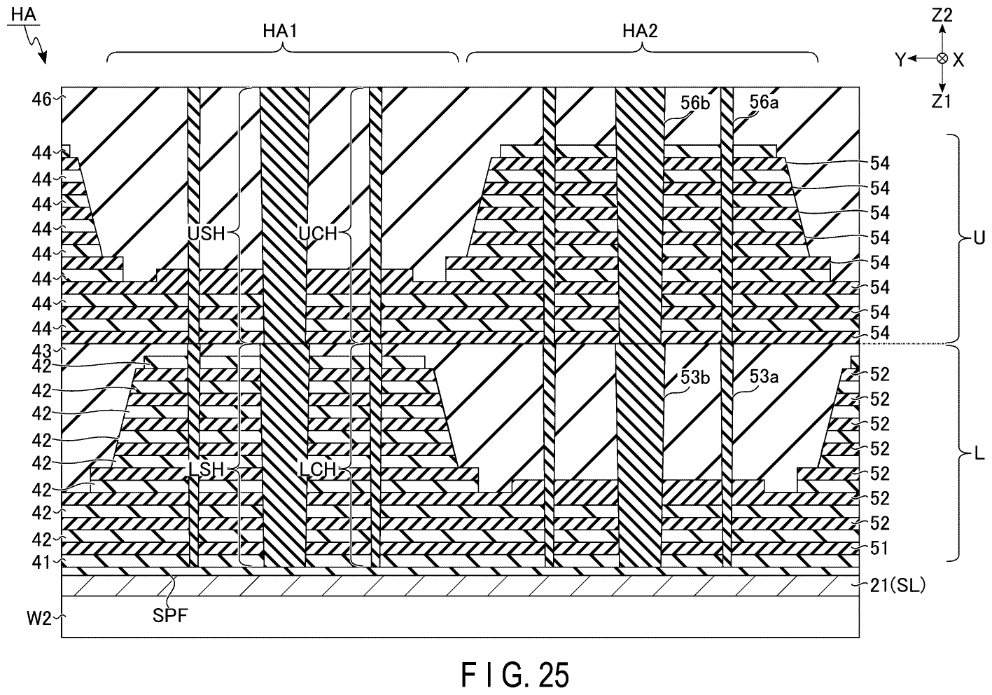

Next, the processing of S108 is performed, and a plurality of slits USH and a plurality of holes UCH corresponding to the upper members USLT and the upper contacts UCC are formed. Thereafter, as illustrated in FIG. 25, the plurality of slits USH and the plurality of holes UCH are filled with a sacrificial member 56.

Specifically, first, a mask in which an area corresponding to each upper member USLT and each upper contact UCC is open is formed by photolithography or the like. The mask is formed so that the opened area is substantially the same area as an area corresponding to each lower member LSLT and each lower contact LCC. Then, the plurality of slits USH corresponding to the respective upper members USLT and the plurality of holes UCH corresponding to the respective upper contacts UCC are formed by anisotropic etching using the mask. Each slit USH and each hole UCH extend through each of the insulating layers 44, 45, and 46 and the sacrificial members 54 and 55. A part of the upper surface of the sacrificial member 53b is exposed at the bottom portion of each slit USH. A part of the upper surface of the sacrificial member 53a is exposed at the bottom portion of each hole UCH.

Thereafter, the plurality of slits USH and the plurality of holes UCH are filled with the sacrificial member 56. The sacrificial member 56 contains, for example, amorphous silicon. Hereinafter, the sacrificial member 56 provided so as to fill the plurality of holes UCH is defined as a sacrificial member 56a. The sacrificial member 56 provided so as to fill the plurality of slits USH is defined as a sacrificial member 56b. The sacrificial member 56a is in contact with the sacrificial member 53a at the bottom portion. The sacrificial member 56b is in contact with the sacrificial member 53b at the bottom portion.

Note that, in the same step as S108, in the memory areas MA1 and MA2, a plurality of holes corresponding to the upper pillars UMP are formed. This hole forming processing is similar to the processing of forming the holes UCH. Thereafter, a plurality of holes corresponding to the upper pillars UMP are filled with the sacrificial member.

Next, the processing of S109 to S113 is sequentially performed, and a configuration corresponding to the contact CC is formed.

Specifically, first, as illustrated in FIG. 26, the sacrificial members 53a and 56a filling the holes LCH and UCH are removed (S109). In this way, the hole LCH and the hole UCH are coupled, and the hole CH is formed.

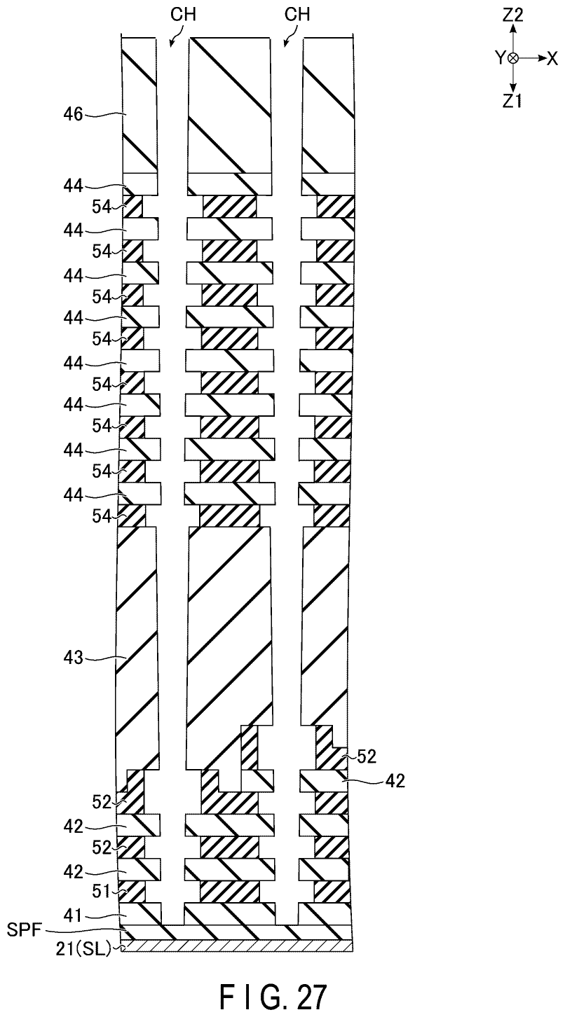

Next, as illustrated in FIG. 27, the peripheral portions of the sacrificial members 51, 52, 54, and 55 exposed to the side surfaces of the holes CH are removed by wet etching through the holes CH (S110). In this way, a plurality of grooves in which the sacrificial members 51, 52, 54, and 55 are recessed in the radial direction along the XY plane direction with respect to the insulating layers 41, 42, 44, and 45 are formed on the side surface of each hole CH.

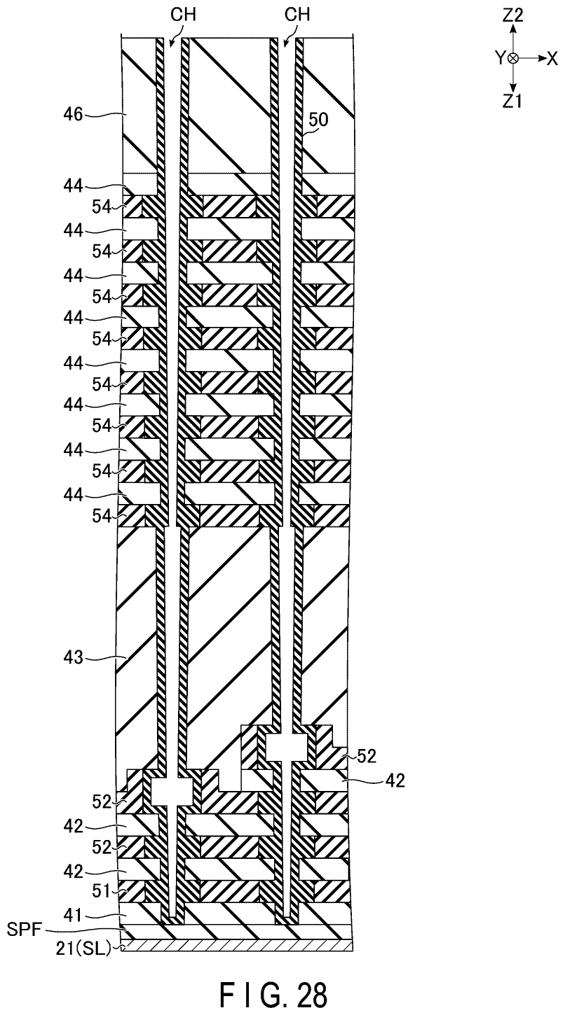

Thereafter, as illustrated in FIG. 28, the film of the insulator 50 is formed on the inner wall of each hole CH (S111). For portions where the film of the sacrificial member 51, 52, 54, or 55 is not thickened, the film of the insulator 50 is formed so as to fill all of the plurality of grooves formed in S110. On the other hand, in a portion where the film of any of the sacrificial members 51, 52, 54, or 55 is thickened, the film of the insulator 50 is formed so as to cover the surface of the groove while leaving a portion recessed at the central portion. The insulator 50 contains, for example, SiO.

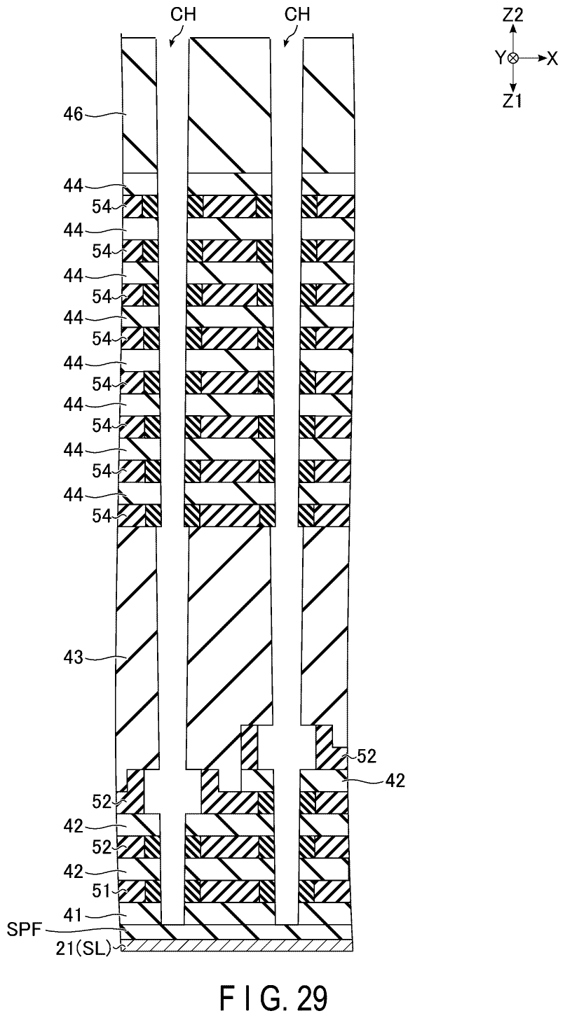

Thereafter, as illustrated in FIG. 29, a part of the insulator 50 provided on the inner wall of each hole CH is removed by wet etching or the like (S112). At this time, in a portion where the film of the sacrificial member 51, 52, 54, or 55 is not thickened, the insulator 50 filling the groove is not completely removed, and none of the sacrificial members 51, 52, 54, and 55 is exposed to the side surface portion of each hole CH. On the other hand, in a portion where the film of any of the sacrificial members 51, 52, 54, or 55 is thickened, the insulator 50 provided so as to cover the surface of the groove is removed, and these sacrificial members 51, 52, 54, or 55 are exposed on the side surface portion of each hole CH.

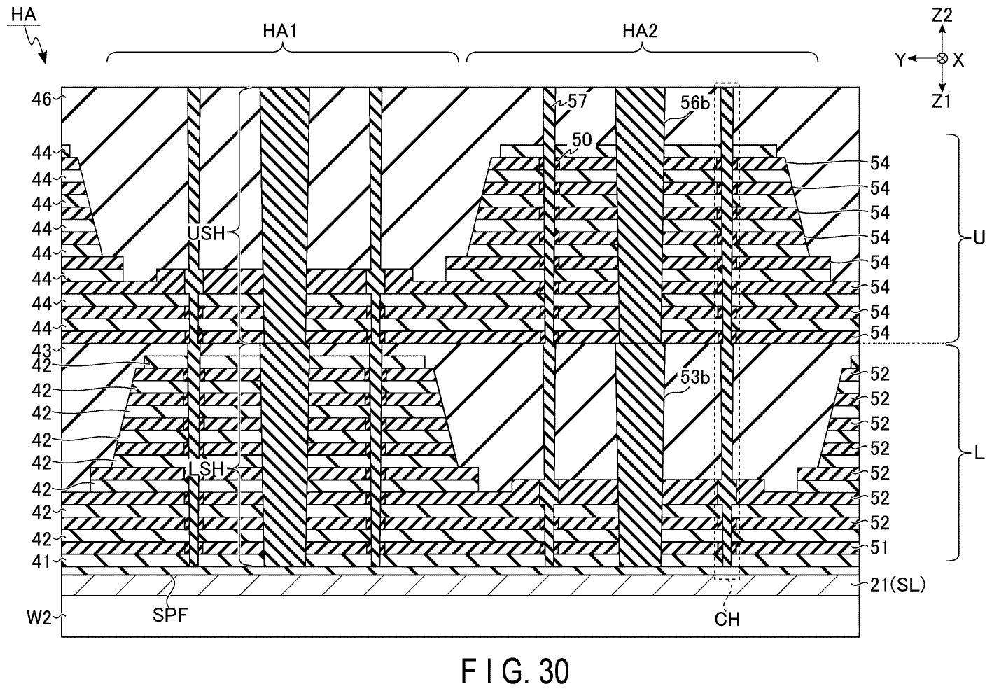

Thereafter, as illustrated in FIG. 30, each hole CH is filled with a sacrificial member 57 (S113). Each filling sacrificial member 57 is horizontally in contact with the sacrificial member 51, 52, 54, or 55 in a groove formed at a portion where the film of any of the sacrificial member 51, 52, 54, or 55 is thickened. In addition, each sacrificial member 57 is in contact with the stopper film SPF on the lower surface. The sacrificial member 57 contains, for example, amorphous silicon.

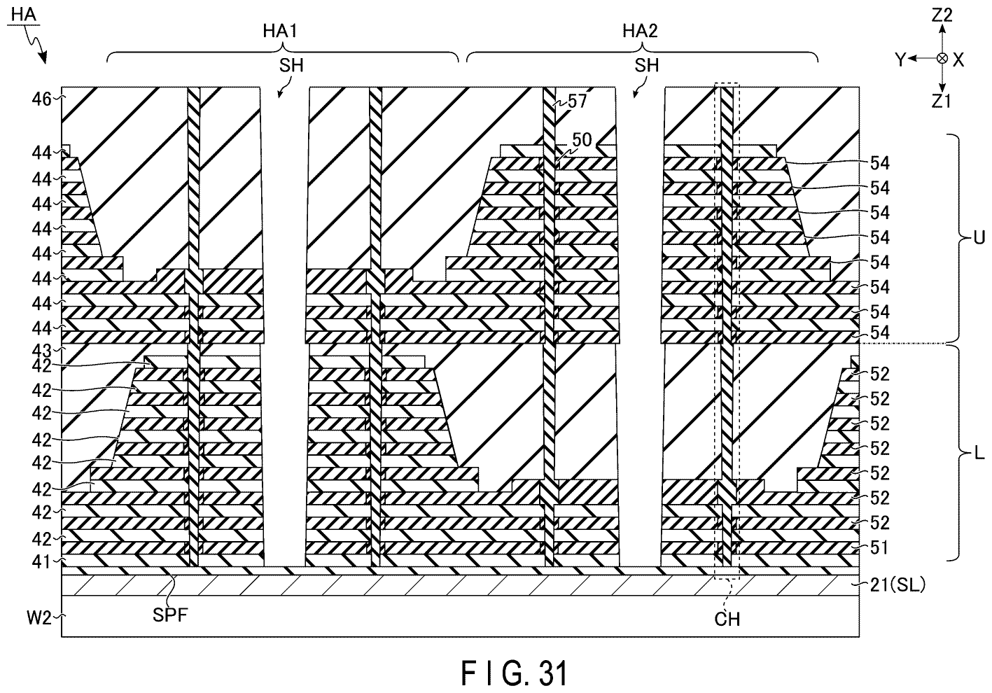

Next, as illustrated in FIG. 31, the sacrificial members 53b and 56b filling the slits LSH and USH are removed (S114). In this way, the slit LSH and the slit USH are coupled, and the slit SH is formed.

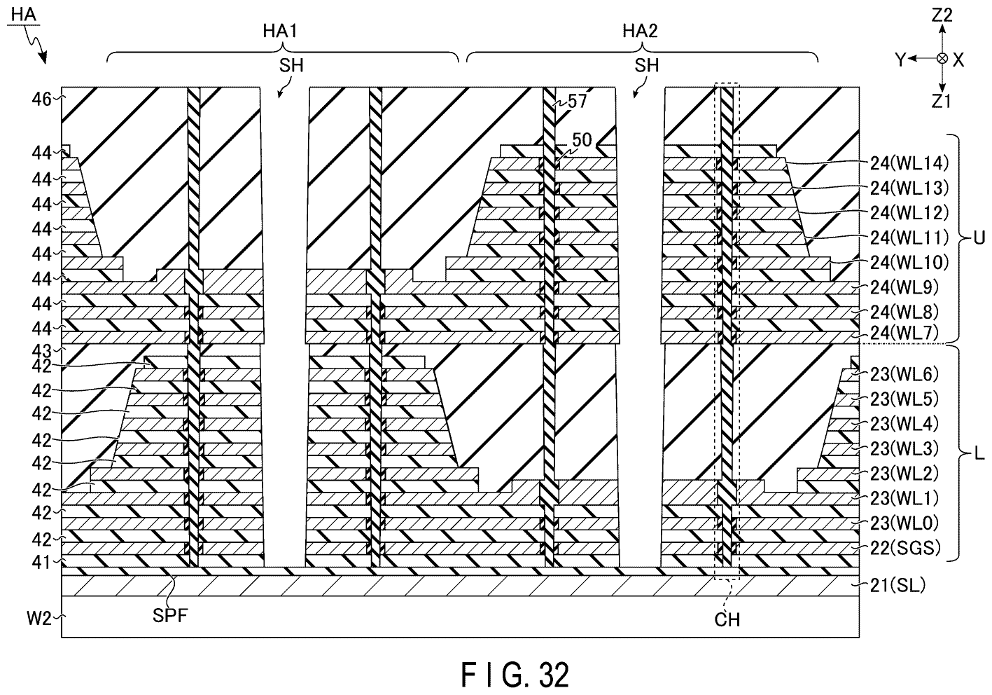

Next, as illustrated in FIG. 32, a stacked interconnect structure is formed by replacement (S115).

Specifically, first, the sacrificial members 51, 52, 54, and 55 are removed through the slits SH by wet etching. At this time, the three-dimensional structure of the structural body from which the sacrificial members 51, 52, 54, and 55 are removed is supported by the plurality of memory pillars MP (not illustrated) and a plurality of support pillars (not illustrated) that are disposed as appropriate in the hookup area HA. Then, the space from which the sacrificial members 51, 52, 54, and 55 were removed is filled with the conductor through the slit SH. For the formation of the conductor in this step, for example, chemical vapor deposition (CVD) is used. Thereafter, the conductor formed inside the slit SH is removed by etch-back processing, and the interconnect layer adjacent in the Z direction and the conductor are separated. In this way, the interconnect layer 22 functioning as the select gate line SGS, the plurality of interconnect layers 23 functioning as the word lines WL0 to WL6, the plurality of interconnect layers 24 functioning as the word lines WL7 to WL14, and the interconnect layer 25 functioning as the select gate line SGD are formed. Note that the interconnect layers 22, 23, 24, and 25 formed in this step may contain a barrier metal. In this case, in the formation of the conductor after removing the sacrificial members 51, 52, 54, and 55, for example, titanium nitride is deposited as a barrier metal, and then tungsten is formed. In addition, the interconnect layers 22, 23, 24, and 25 may include an insulating film. In this case, in the formation of the conductor after removing the sacrificial members 51, 52, 54, and 55, for example, metal oxide film of aluminum oxide or the like is formed as an insulating film, and then a barrier metal and tungsten are formed.

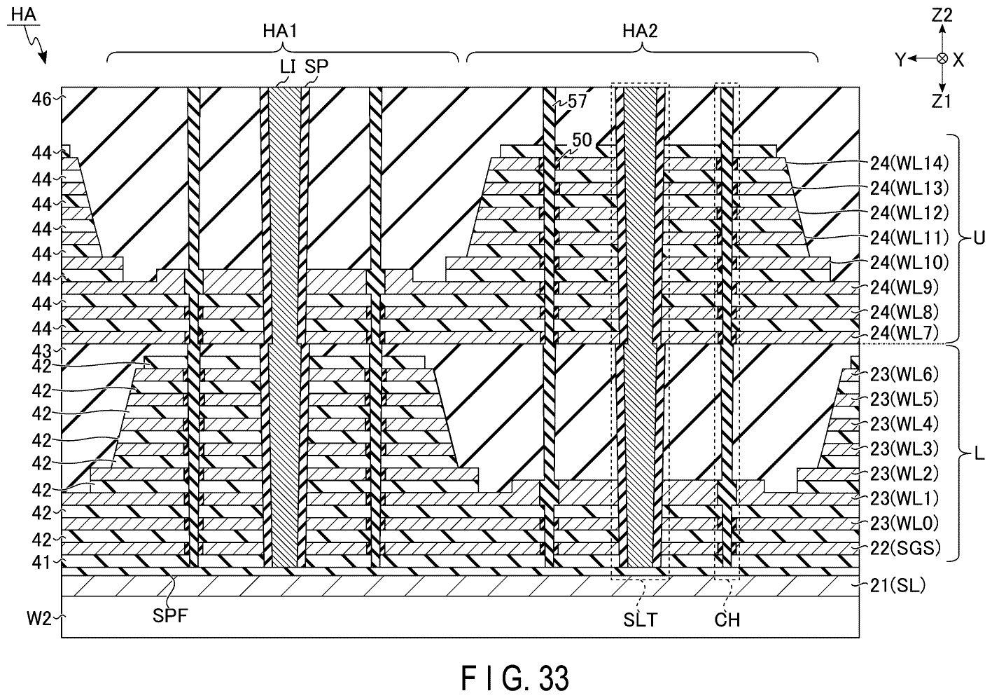

Next, as illustrated in FIG. 33, the member SLT is formed in each slit SH. Although not illustrated, the member SHE is formed from the memory area MA1 to the first portion SGDa of the select gate line SGD and from the memory area MA2 to the second portion SGDb of the select gate line SGD (S116).

Specifically, first, an insulating portion (spacer SP) is formed so as to cover the side surface and the bottom surface of the slit SH. Then, a part of the spacer SP provided at the bottom portion of the slit SH is removed, and a part of the interconnect layer 21 is exposed at the bottom portion of the slit SH. Then, a conductor (contact LI) is formed in the slit SH, and the conductor formed outside the slit SH is removed by, for example, CMP. Thereafter, a plurality of grooves are formed in an area corresponding to the member SHE between the members SLT adjacent in the Y direction so that the plurality of grooves are parallel to the member SLT. Then, the inside of each groove is filled with an insulating film, and thus the member SHE dividing the interconnect layer 25 in the Y direction is formed.

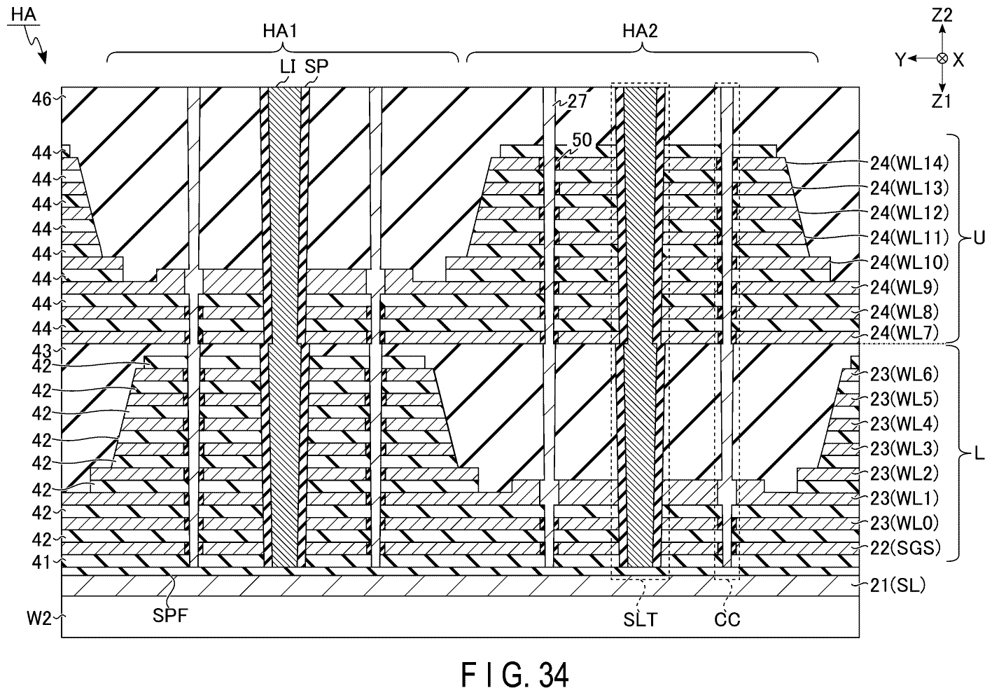

Finally, as illustrated in FIG. 34, replacement processing of the sacrificial member 57 filling the hole CH is performed, and the contact CC is formed (S117).

Specifically, first, the sacrificial member 57 filling each hole CH is removed by wet etching. At this time, in a case where each of the interconnect layers 22, 23, 24, and 25 includes an insulating film, the insulating film in contact with the sacrificial member 57 is also simultaneously removed. Then, the hole CH is filled with the plurality of conductors 27. Each conductor 27 is horizontally in contact with the interconnect layers 22, 23, 24, and 25 in the groove formed at each terrace portion in these interconnect layers 22, 23, 24, and 25. In addition, each conductor 27 is in contact with the stopper film SPF on the lower surface. Finally, the conductor formed on the upper surface of the stacked structure is removed by, for example, CMP, so that the surfaces corresponding to the upper ends of the plurality of contacts CC are exposed.

The structure of the hookup area HA in the memory cell array 10 is formed by the manufacturing process described above. Note that the manufacturing process described above is merely an example, and the present invention is not limited thereto. For example, other processing may be inserted between the manufacturing processes, or some steps may be omitted or integrated with each other. In addition, each manufacturing process may be interchanged within the possible range.

### 1.3 Effects According to First Embodiment

The effect that can improve the yield of the semiconductor memory device by applying the first embodiment will be described in detail below.

In the manufacturing process of the memory cell array, two slits SH extending in the X direction are disposed side by side in the Y direction so as to sandwich one block BLK. In such an arrangement, a stress in the Y direction is applied to each slit SH in the replacement processing of the interconnect layers 22 to 25. The magnitude of the stress in the Y direction applied to each slit SH depends on the material of the structure at or near each slit SH. For example, the stress of a portion where the interconnect layer and the insulating layer are alternately stacked (metal portion) and the stress of a portion filled mainly with the insulating layer (filled portion) are different from each other. The stress effect applied to each slit SH is evaluated as a ratio of the area of the metal portion at or near each slit SH to the area of the filled portion in a certain YZ section (metal portion area/filled portion area). In one block BLK, in a case where the stress applied to the two slits SH in contact with the one block BLK is different in each slit SH, the stress in the Y direction is biased, and thus, the stacked interconnect may have an incline in the Y direction. If the stacked interconnect has an incline, the slit SH is blocked, and the contact LI may not be able to be formed. In addition, the hole UCH formed in the upper stacked interconnect U and the hole LCH formed in the lower stacked interconnect L may be displaced in position from each other and may cause a coupling failure of the contact CC. For these reasons, the yield of the semiconductor memory device may decrease.

On the other hand, it is considered that the stress in the Y direction applied to the slits SH corresponding to the members SLTo and SLTe provided so as to sandwich the block BLK1 illustrated in the central portion of FIG. 15 in the Y direction, in the memory cell array 10 in the semiconductor memory device 3 according to the first embodiment. The breakdown of a portion where the slit SH corresponding to the member SLTo is in contact with the block BLK1 and the vicinity of such a portion is as follows: most of the lower stacked interconnect L is a filled portion, and the upper stacked interconnect U is a metal portion. The breakdown of a portion where the slit SH corresponding to the member SLTe is in contact with the block BLK1 and the vicinity of such a portion is as follows: the lower stacked interconnect L is a metal portion, and most of the upper stacked interconnect U is a filled portion. Therefore, in terms of the whole stacked interconnect, the configurations at or near the two slits SH in contact with the block BLK1 can be considered to be similar except that the upper stacked interconnect U and the lower stacked interconnect L are reversed. Here, considering the value of (metal portion area/filled portion area) at or near each slit SH, the value at or near the slit SH corresponding to the member SLTo and the value at or near the slit SH corresponding to the member SLTe take substantially the same value. That is, it can be said that the stresses applied from the block BLK1 to two slits SH provided so as to sandwich the block BLK1 in the Y direction are substantially equal. Therefore, the incline of the stacked interconnect due to the bias of a stress can be reduced.

Further, in the memory cell array 10 of the semiconductor memory device 3 according to the first embodiment, all the thick film portions THK of the respective interconnect layers 22, 23, 24, and 25 are in contact with the member SLT. For this reason, at the time of replacement of the sacrificial member in step S115, the conductive material (e.g., tungsten) used for replacement flows so as to fill the whole thick film portion THK, and thus generation of voids in the thick film portion THK can be reduced. Therefore, at the time of degassing the semiconductor memory device 3, defects due to formation of a void can be reduced.

In the memory cell array 10 of the semiconductor memory device 3 according to the first embodiment, a through contact is used as the contact CC that couples each of the interconnect layers 22, 23, 24, and 25 and the interconnect layer 28. This can reduce a defect in which the contact does not reach the intended interconnect layer and is not conducted, or a defect in which the contact reaches the interconnect layer below the intended interconnect layer and the two interconnect layers are short-circuited.

As described above, according to the first embodiment, the yield of the semiconductor memory device 3 can be improved from a plurality of viewpoints.

In addition, the memory cell array 10 in the semiconductor memory device 3 according to the first embodiment includes a two-lane contact structure in which coupling portions of the interconnect layers 22, 23, and 24 with the contacts CC are provided in two columns in the Y direction for each one block BLK. This structure can suppress an increase in the length of the memory cell array 10 in one direction (e.g., the X direction) due to the arrangement of the coupling portions of the interconnect layers 22, 23, and 24 with the contacts CC in the direction, and can reduce (suppress the expansion of) the chip area of the semiconductor memory device 3.

Here, in the case of an arrangement in which two or more columns of coupling portions with the contacts CC are provided in the Y direction in one stadium-shaped stepped structure, the width in the Y direction of a portion that couples the memory areas MA1 and MA2 of each interconnect layer 22, 23, and 24 is reduced, and the current characteristics may be deteriorated. In addition, in the case of using the through contact, it is desired to increase the width of the coupling portion with the contact. For this reason, for example, it is conceivable to make the angle of the inclined portion formed in multistage processing steep, but formation of the inclined portion having a steep angle is difficult.

On the other hand, in the memory cell array 10 of the semiconductor memory device 3 according to the first embodiment, a portion of the interconnect layers 22 and 23 below the first stadium-shaped stepped structure provided in the hookup area HA1 corresponds to the bridge portion BRG2 that couples the memory areas MA1 and MA2 in the lower stacked interconnect L. A portion of the interconnect layer 24 above the second stadium-shaped stepped structure provided in the hookup area HA2 corresponds to the bridge portion BRG1 that couples the memory areas MA1 and MA2 in the upper stacked interconnect U. Therefore, the width in the Y direction of a portion that couples the memory areas MA1 and MA2 can be made equal to the width in the Y direction of the coupling portion with the contact CC. Therefore, deterioration of current characteristics can be reduced. In addition, the inclined portion IP1 of the upper stacked interconnect U and the inclined portion IP2 of the lower stacked interconnect L may overlap each other in the Z direction. Therefore, a sufficient width in the Y direction can be secured, and the angles of the inclined portions IP1 and IP2 can be reduced.

### 1.4 Modifications

The semiconductor memory device 3 according to the first embodiment described above can be variously modified. Hereinafter, differences from the first embodiment will be described as to a first modification and a second modification of the first embodiment.

### 1.4.1 First Modification

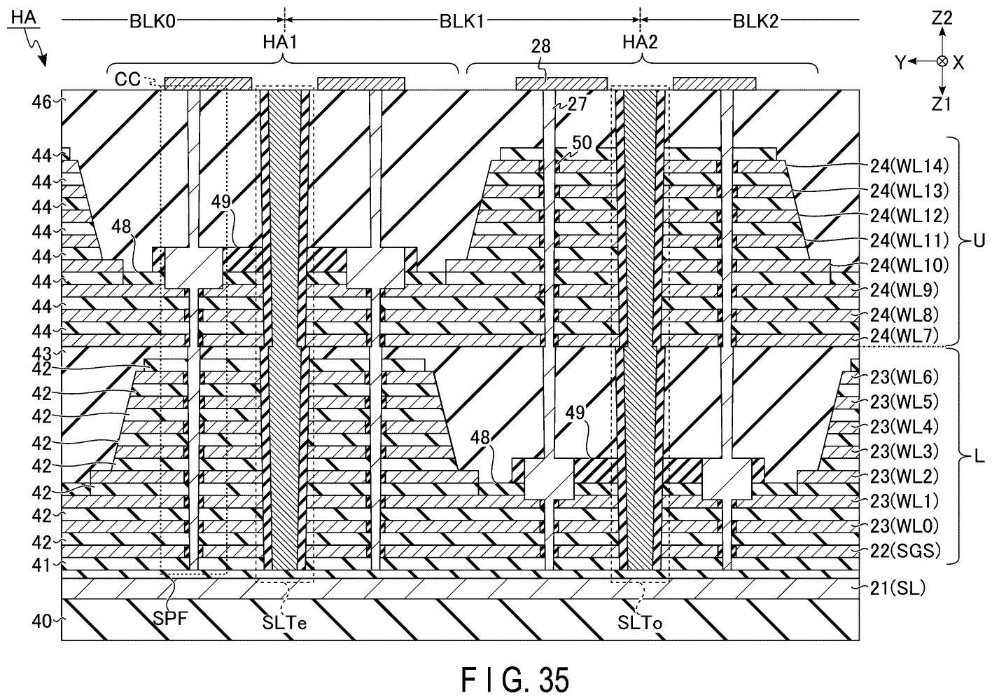

FIG. 35 is a sectional view in the hookup area of the memory cell array included in the semiconductor memory device according to a first modification of the first embodiment. The section illustrated in FIG. 35 corresponds to the section illustrated in FIG. 15 in the first embodiment.

As illustrated in FIG. 35, the memory cell array 10 included in the semiconductor memory device 3 according to the first modification of the first embodiment further includes insulating layers 48 and 49. The insulating layers 48 and 49 contain, for example, SiO. In addition, each of the interconnect layers 22, 23, 24, and 25 of the memory cell array 10 does not include a thick film portion.

Compared to the first embodiment, the first modification of the first embodiment is different in the shape of the contact CC and the structure of the coupling portion with the interconnect layers 22, 23, 24, and 25 to which the contacts CC correspond. Specifically, in the contact CC according to the first embodiment, the conductor 27 is coupled to the corresponding interconnect layer in the XY plane direction in the thick film portion THK of the interconnect layer 22, 23, 24, and 25. On the other hand, in the contact CC according to the first modification, the conductor 27 is coupled to the corresponding interconnect layer in the Z direction on the upper surface of the interconnect layer 22, 23, 24, and 25.

In the manufacturing process of the memory cell array 10 according to the first modification of the first embodiment, steps S103 and S107 in the first embodiment are omitted, and instead, a step in which the insulating layer 48 and the thick film sacrificial member are stacked in this order is inserted. The thick film sacrificial member contains, for example, SiN. The thick film sacrificial member stacked at this time is larger than the first thickness D1 and is, for example, equal to the second thickness D2. After step S112, a process of removing a part of the thick film sacrificial member through the hole CH is inserted. In step S113, a portion where a part of the thick film sacrificial member was removed is filled with the sacrificial member 57. In step S115, all the thick film sacrificial members are removed through the slit SH. In step S116, at the same time as the formation of the spacer SP of the member SLT, the insulating layer 49 is formed at the portion from which the thick film sacrificial member was removed. In step S117, a part of the insulating layer 48 is removed until the upper surface of the corresponding interconnect layer is exposed.

### 1.4.2 Second Modification

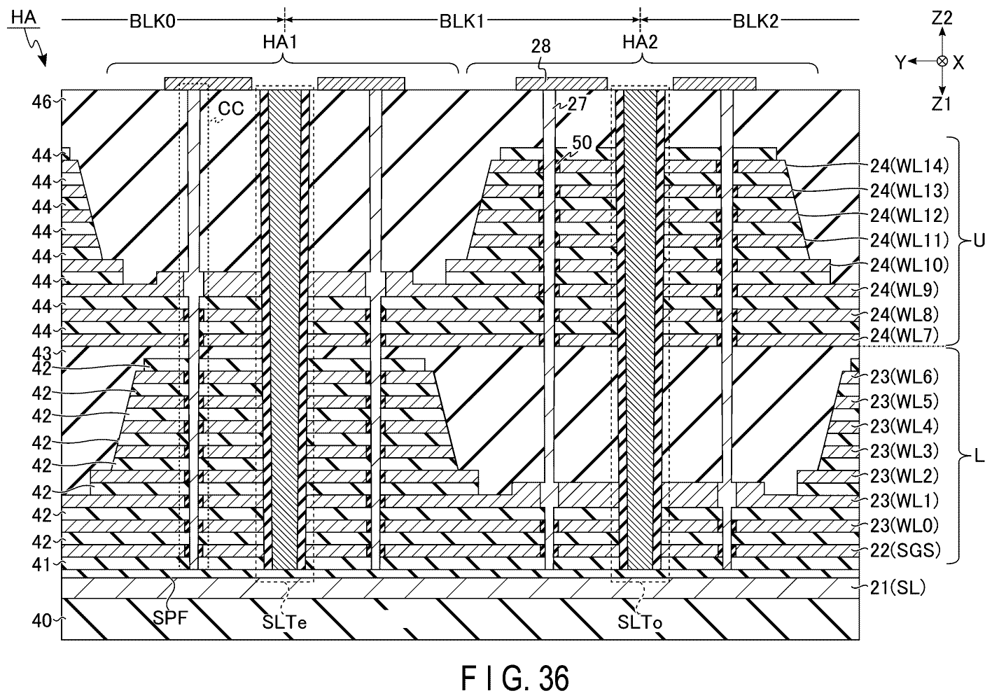

FIG. 36 is a sectional view in the hookup area of the memory cell array included in the semiconductor memory device according to a second modification of the first embodiment. The section illustrated in FIG. 36 corresponds to the section illustrated in FIG. 15 in the first embodiment.

As illustrated in FIG. 36, in the memory cell array 10 included in the semiconductor memory device 3 according to the second modification of the first embodiment, the member SLT is not divided into an upper member and a lower member and is formed at a time. Similarly, the contact CC is not divided into the upper contact and the lower contact but is formed at a time. Although not illustrated, the memory pillar MP may similarly be formed at a time without being divided into the upper pillar and the lower pillar.

In the manufacturing process of the memory cell array 10 according to the second modification of the first embodiment, step S104 in the first embodiment is omitted, and the slit SH and the hole CH extending through both the upper stacked interconnect U and the lower stacked interconnect L are formed in step S108. Thereafter, the member SLT is formed so as to fill the slit SH, and the contact CC is formed so as to fill the hole CH.

Note that, as another variation of the second modification, any one or two of the member SLT, the contact CC, and/or the memory pillar MP may be formed at a time without being divided into an upper portion and a lower portion.

### 2. Second Embodiment

Next, a semiconductor memory device according to a second embodiment will be described. A semiconductor memory device 3 according to the second embodiment is different from the semiconductor memory device 3 according to the first embodiment in that a memory cell array 10 of the semiconductor memory device 3 according to the second embodiment includes four stacked structures and a stepped structure is formed in each stacked structure. In the following description, description about configurations and manufacturing methods equivalent to those of the first embodiment will be omitted, and configurations different from those of the first embodiment will be mainly described.

### 2.1 Structure of Memory Cell Array

### 2.1.1 Planar Layout

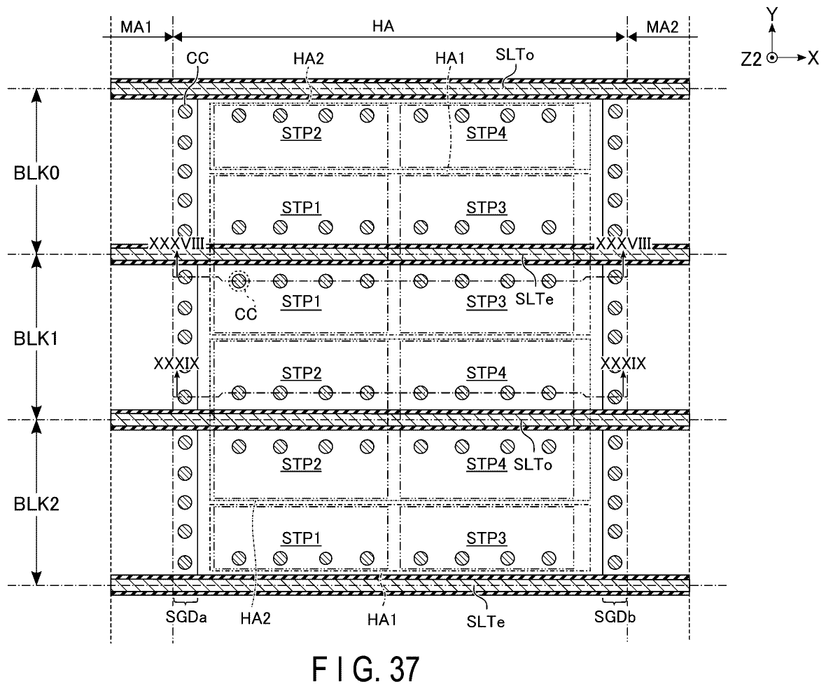

FIG. 37 is a plan view schematically illustrating an example of a planar layout in a hookup area of a memory cell array included in a semiconductor memory device according to the second embodiment. FIG. 37 illustrates areas corresponding to three blocks BLK0 to BLK2. Note that FIG. 37 omits the stepped structure and illustrates a stepped area where the stepped structure is provided in plan view. In FIG. 37, only the positions of a plurality of contacts CC are illustrated, and the structures thereof are omitted.

As illustrated in FIG. 37, the memory cell array 10 includes stepped areas STP1, STP2, STP3, and STP4 in the hookup area HA. The stepped areas STP1 and STP3 are provided so as to straddle a member SLTe in the Y direction and are arranged in the X direction. The stepped areas STP2 and STP4 are provided so as to straddle a member SLTo in the Y direction and are arranged in the X direction. The stepped areas STP1 and STP2 are provided side by side in the Y direction. The stepped areas STP3 and STP4 are provided side by side in the Y direction. In the stepped areas STP1 to STP4, for example, first to fourth stadium-shaped stepped structures are respectively provided. The terrace portions of the first and third stadium-shaped stepped structures are provided in a hookup area HA1. The terrace portions of the second and fourth stadium-shaped stepped structures are provided in a hookup area HA2. The plurality of contacts CC are provided corresponding to the respective terrace portions of the first to fourth stadium-shaped stepped structures.

### 2.1.2 Sectional Structure

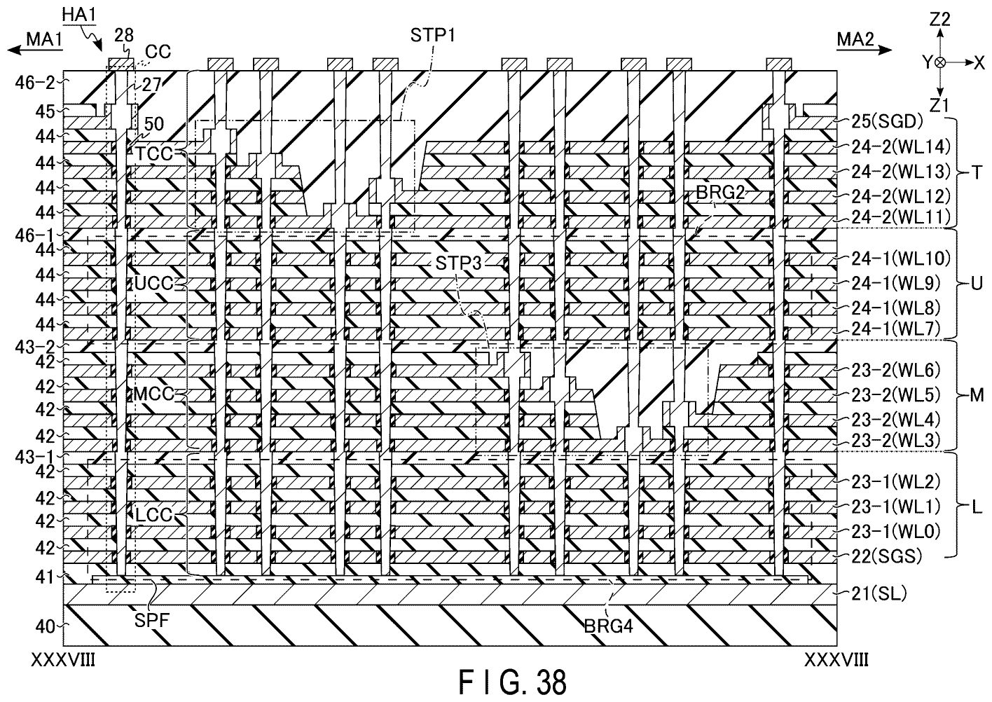

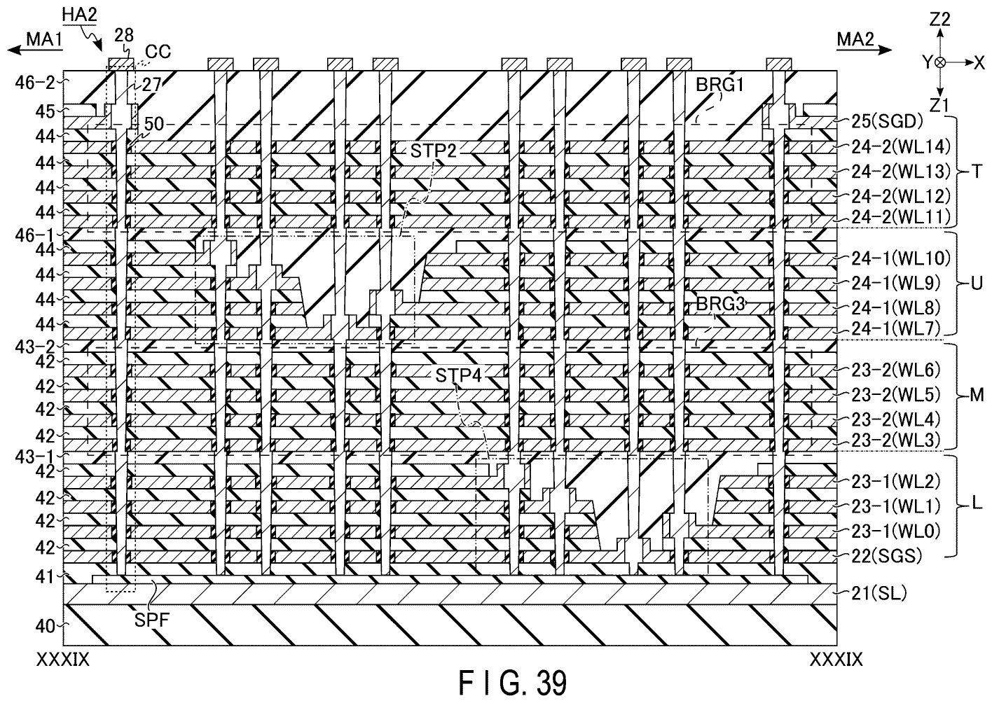

FIG. 38 is a sectional view taken along line XXXVIII-XXXVIII in FIG. 37 in the hookup area of the memory cell array included in the semiconductor memory device according to the second embodiment. FIG. 39 is a sectional view taken along line XXXIX-XXXIX in FIG. 37 in the hookup area of the memory cell array included in the semiconductor memory device according to the second embodiment. FIGS. 38 and 39 illustrate XZ sections of the hookup area HA and the contact CC in the block BLK1. FIGS. 38 and 39 correspond to the XZ sections of the hookup areas HA1 and HA2, respectively.

As illustrated in FIGS. 38 and 39, the memory cell array 10 includes a lower stacked interconnect L, a middle stacked interconnect M, an upper stacked interconnect U, and a top stacked interconnect T. The lower stacked interconnect L and the middle stacked interconnect M correspond to the lower stacked interconnect L in the first embodiment. The lower stacked interconnect L includes an interconnect layer 22 corresponding to a select gate line SGS and a plurality of interconnect layers 23-1 corresponding to word lines WL0 to WL2. The middle stacked interconnect M includes a plurality of interconnect layers 23-2 corresponding to word lines WL3 to WL6. The upper stacked interconnect U and the top stacked interconnect T correspond to the upper stacked interconnect U in the first embodiment. The upper stacked interconnect U includes a plurality of interconnect layers 24-1 corresponding to word lines WL7 to WL10. The top stacked interconnect T includes a plurality of interconnect layer 24-2 corresponding to word lines WL11 to WL14 and an interconnect layer 25 corresponding to a select gate line SGD.

As illustrated in FIG. 38, in the hookup area HA1, the stepped area STP1 is provided in the top stacked interconnect T, and the stepped area STP3 is provided in the middle stacked interconnect M. The top stacked interconnect T includes a first stadium-shaped stepped structure in the stepped area STP1. The middle stacked interconnect M includes a third stadium-shaped stepped structure in the stepped area STP3. The first stadium-shaped stepped structure and the third stadium-shaped stepped structure are provided at positions not overlapping each other in the Z direction.

In the hookup area HA1, the upper stacked interconnect U and the lower stacked interconnect L include bridge portions BRG2 and BRG4, respectively. The bridge portions BRG2 and BRG4 extend in the X direction and couple a portion provided in a memory area MA1 and a portion provided in a memory area MA2 of each of the interconnect layers 22, 23-1, and 24-1 included in the upper stacked interconnect U and the lower stacked interconnect L.

As illustrated in FIG. 39, in the hookup area HA2, the stepped area STP2 is provided in the upper stacked interconnect U, and the stepped area STP4 is provided in the lower stacked interconnect L. The upper stacked interconnect U includes a second stadium-shaped stepped structure in the stepped area STP2. The lower stacked interconnect L includes a fourth stadium-shaped stepped structure in the stepped area STP4. The second stadium-shaped stepped structure and the fourth stadium-shaped stepped structure are provided at positions not overlapping each other in the Z direction.

In the hookup area HA2, the top stacked interconnect T and the middle stacked interconnect M include bridge portions BRG1 and BRG3, respectively. The bridge portions BRG1 and BRG3 extend in the X direction and couple a portion provided in the memory area MA1 and a portion provided in the memory area MA2 of each of the interconnect layers 23-2 and 24-2 included in the top stacked interconnect T and the middle stacked interconnect M.

The memory cell array 10 includes insulating layers 43-1, 43-2, 46-1, and 46-2. The insulating layer 43-1 is provided so as to fill the fourth stadium-shaped stepped structure between the lower stacked interconnect L and the middle stacked interconnect M. The insulating layer 43-2 is provided so as to fill the third stadium-shaped stepped structure between the middle stacked interconnect M and the upper stacked interconnect U. The insulating layer 46-1 is provided so as to fill the second stadium-shaped stepped structure between the upper stacked interconnect U and the top stacked interconnect T. The insulating layer 46-2 is provided so as to fill the first stadium-shaped stepped structure above the top stacked interconnect T.

The plurality of contacts CC are provided extending in the Z direction. Each contact CC is a through contact that extends through (passes through), in the Z direction, the corresponding interconnect layer and other layers above the stopper film SPF provided at the position where the contact CC is disposed in plan view.

Each contact CC includes a top contact TCC, an upper contact UCC, a middle contact MCC, and a lower contact LCC. The lower contact LCC extends through the lower stacked interconnect L, that is, at least a part of the interconnect layers 22 and 23-1, at least a part of the insulating layers 41 and 42, and the insulating layer 43-1. The middle contact MCC extends through the middle stacked interconnect M, that is, at least a part of the interconnect layers 23-2, at least a part of the insulating layers 42, and the insulating layer 43-2. The upper contact UCC extends through the upper stacked interconnect U, that is, at least a part of the interconnect layers 24-1, at least a part of the insulating layers 44, and the insulating layer 46-1. The top contact TCC extends through the top stacked interconnect T, that is, at least a part of the interconnect layers 24-2 and 25, at least a part of the insulating layers 44 and 45, and the insulating layer 46-2. The upper end of the lower contact LCC and the lower end of the middle contact MCC are in contact with each other at the boundary surface between the insulating layer 43-1 and the lowermost interconnect layer 23-2. The upper end of the middle contact MCC and the lower end of the upper contact UCC are in contact with each other at the boundary surface between the insulating layer 43-2 and the lowermost interconnect layer 24-1. The upper end of the upper contact UCC and the lower end of the top contact TCC are in contact with each other at the boundary surface between the insulating layer 46-1 and the lowermost interconnect layer 24-2.

Although not illustrated, a member SLT and a memory pillar MP may also have individual structures for each stacked interconnect. The structures of the members SLT and the memory pillars MP for each stacked interconnect are coupled continuously in the Z direction.

### 2.2 Effects

According to the second embodiment, similarly to the first embodiment, the yield of the semiconductor memory device 3 can be improved. In addition, according to the second embodiment, since a plurality of stepped structures can be disposed side by side in the X direction, the chip area of the semiconductor memory device 3 can be reduced (expansion thereof can be suppressed).

### 2.3 Modifications

The semiconductor memory device 3 according to the second embodiment described above can be variously modified. For example, modifications corresponding to the first modification and the second modification in the first embodiment may be applied to the semiconductor memory device 3 according to the second embodiment.

### 3. Third Embodiment

Next, a semiconductor memory device according to a third embodiment will be described. A semiconductor memory device 3 according to the third embodiment is different from the semiconductor memory device 3 according to the second embodiment at a position where a stepped structure of each stacked structure is formed. In the following description, description about configurations equivalent to those of the second embodiment will be omitted, and configurations different from those of the second embodiment will be mainly described.

### 3.1 Structure of Memory Cell Array

### 3.1.1 Planar Layout

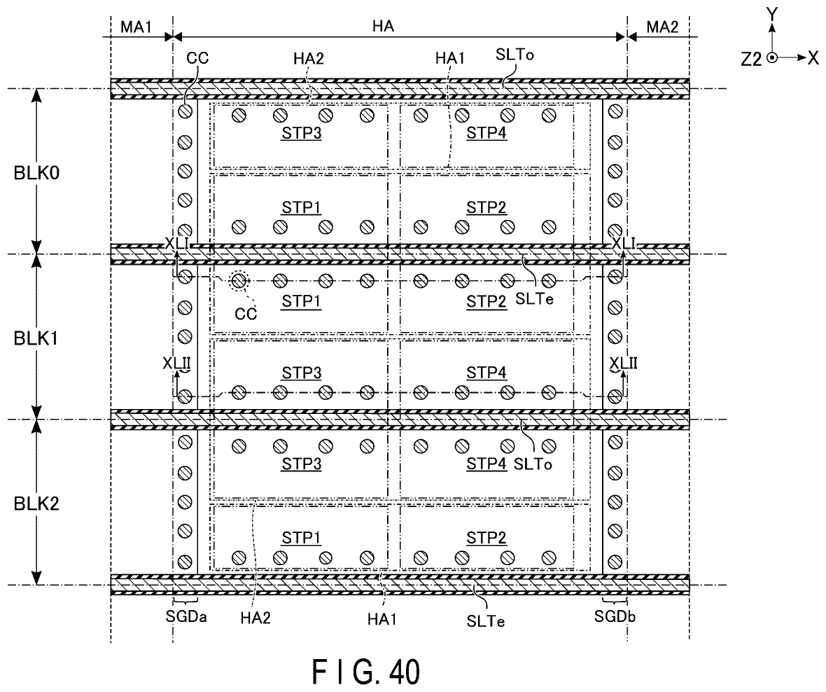

FIG. 40 is a plan view schematically illustrating an example of a planar layout in a hookup area of a memory cell array included in a semiconductor memory device according to the third embodiment. FIG. 40 illustrates areas corresponding to three blocks BLK0 to BLK2. Note that FIG. 40 omits the stepped structure and illustrates a stepped area where the stepped structure is provided in plan view. In FIG. 40, only the positions of a plurality of contacts CC are illustrated, and the structures thereof are omitted.

As illustrated in FIG. 40, a memory cell array 10 includes stepped areas STP1, STP2, STP3, and STP4 in the hookup area HA. The stepped areas STP1 and STP2 are provided so as to straddle a member SLTe in the Y direction and are arranged in the X direction. The stepped areas STP3 and STP4 are provided so as to straddle a member SLTo in the Y direction and are arranged in the X direction. The stepped areas STP1 and STP3 are provided side by side in the Y direction. The stepped areas STP2 and STP4 are provided side by side in the Y direction. In the stepped areas STP1 to STP4, for example, first to fourth stadium-shaped stepped structures are respectively provided. The terrace portions of the first and second stadium-shaped stepped structures are provided in a hookup area HA1. The terrace portions of the third and fourth stadium-shaped stepped structures are provided in a hookup area HA2. The plurality of contacts CC are provided corresponding to the respective terrace portions of the first to fourth stadium-shaped stepped structures.

### 3.1.2 Sectional Structure

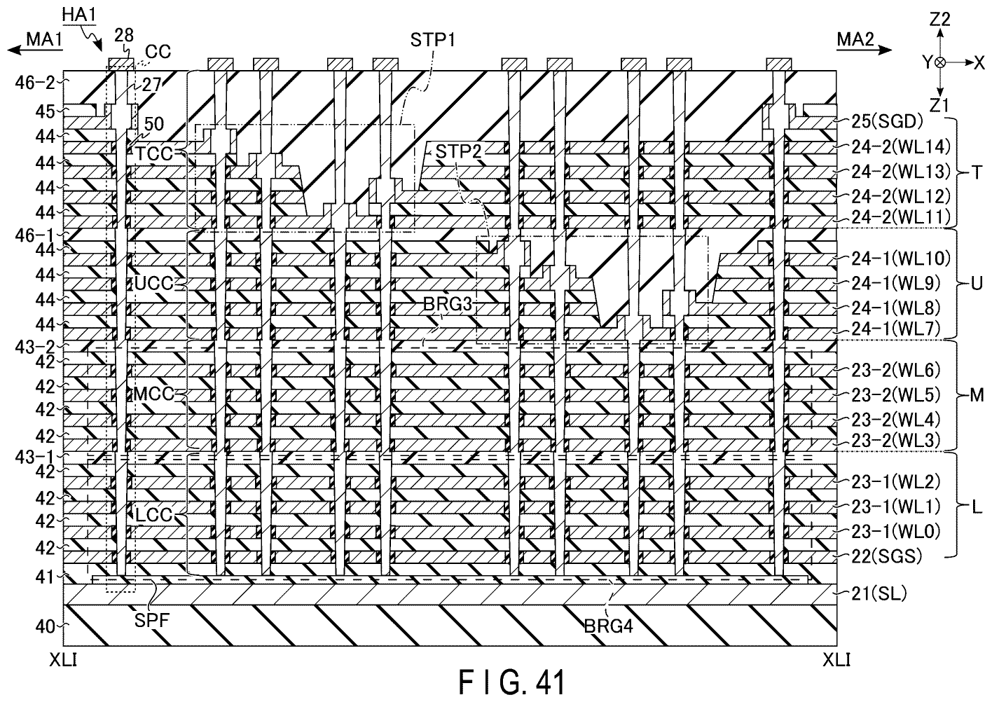

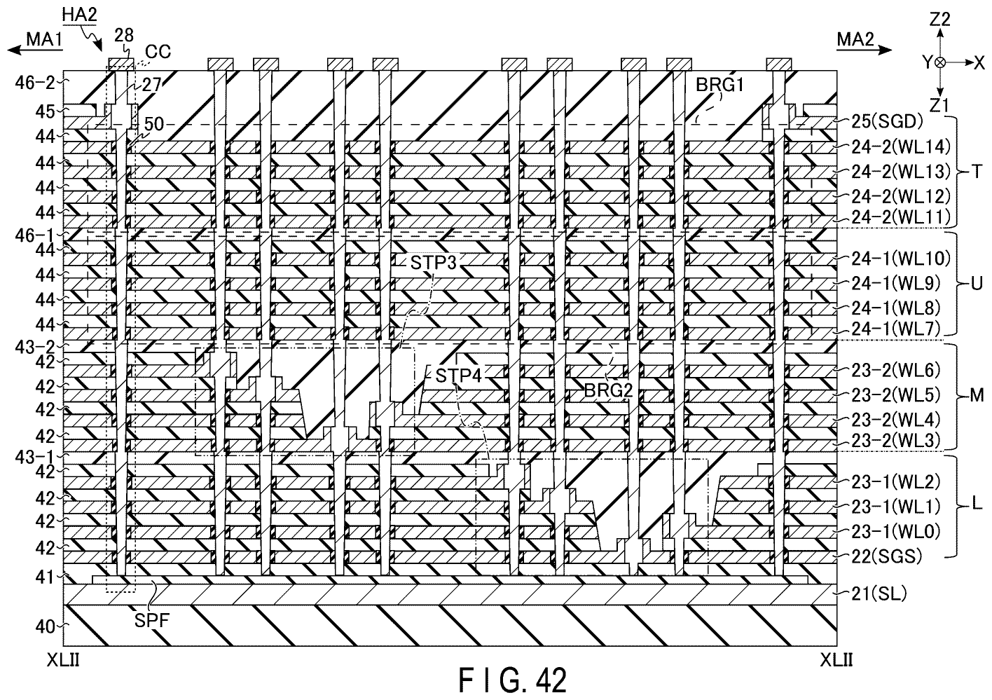

FIG. 41 is a sectional view taken along line XLI-XLI in FIG. 40 in the hookup area of the memory cell array included in the semiconductor memory device according to the third embodiment. FIG. 42 is a sectional view taken along line XLII-XLII in FIG. 40 in the hookup area of the memory cell array included in the semiconductor memory device according to the third embodiment. FIGS. 41 and 42 illustrate XZ sections of the hookup area HA and the contact CC in the block BLK1. FIGS. 41 and 42 correspond to the XZ sections of the hookup areas HA1 and HA2, respectively.

As illustrated in FIG. 41, in the hookup area HA1, the stepped area STP1 is provided in a top stacked interconnect T, and the stepped area STP2 is provided in an upper stacked interconnect U. The top stacked interconnect T includes a first stadium-shaped stepped structure in the stepped area STP1. The upper stacked interconnect U includes a second stadium-shaped stepped structure in the stepped area STP2. The first stadium-shaped stepped structure and the second stadium-shaped stepped structure are provided at positions not overlapping each other in the Z direction.

In the hookup area HA1, a middle stacked interconnect M and a lower stacked interconnect L include bridge portions BRG3 and BRG4, respectively. The bridge portions BRG3 and BRG4 extend in the X direction and couple a portion provided in a memory area MA1 and a portion provided in a memory area MA2 of each of interconnect layers 22, 23-1, and 23-2 included in the middle stacked interconnect M and the lower stacked interconnect L.

As illustrated in FIG. 42, in the hookup area HA2, the stepped area STP3 is provided in the middle stacked interconnect M, and the stepped area STP4 is provided in the lower stacked interconnect L. The middle stacked interconnect M includes a third stadium-shaped stepped structure in the stepped area STP3. The lower stacked interconnect L includes a fourth stadium-shaped stepped structure in the stepped area STP4. The third stadium-shaped stepped structure and the fourth stadium-shaped stepped structure are provided at positions not overlapping each other in the Z direction.

In the hookup area HA2, the top stacked interconnect T and the upper stacked interconnect U include bridge portions BRG1 and BRG2, respectively. The bridge portions BRG1 and BRG2 extend in the X direction and couple a portion provided in the memory area MA1 and a portion provided in the memory area MA2 of each of interconnect layers 24-1 and 24-2 included in the top stacked interconnect T and the upper stacked interconnect U.

### 3.2 Effects

According to the third embodiment, similarly to the first embodiment, the yield of the semiconductor memory device 3 can be improved. In addition, similarly to the second embodiment, the chip area of the semiconductor memory device 3 can be reduced (expansion thereof can be suppressed).

### 3.3 Modifications

The semiconductor memory device 3 according to the third embodiment described above can be variously modified. For example, modifications corresponding to the first modification and the second modification in the first embodiment may be applied to the semiconductor memory device 3 according to the third embodiment.

### 4. Fourth Embodiment

Next, a semiconductor memory device according to a fourth embodiment will be described. A semiconductor memory device 3 according to the fourth embodiment is different from the semiconductor memory device 3 according to the second embodiment at a position where a stepped structure of each stacked structure is formed. In the following description, description about configurations equivalent to those of the second embodiment will be omitted, and configurations different from those of the second embodiment will be mainly described.

### 4.1 Structure of Memory Cell Array

### 4.1.1 Planar Layout

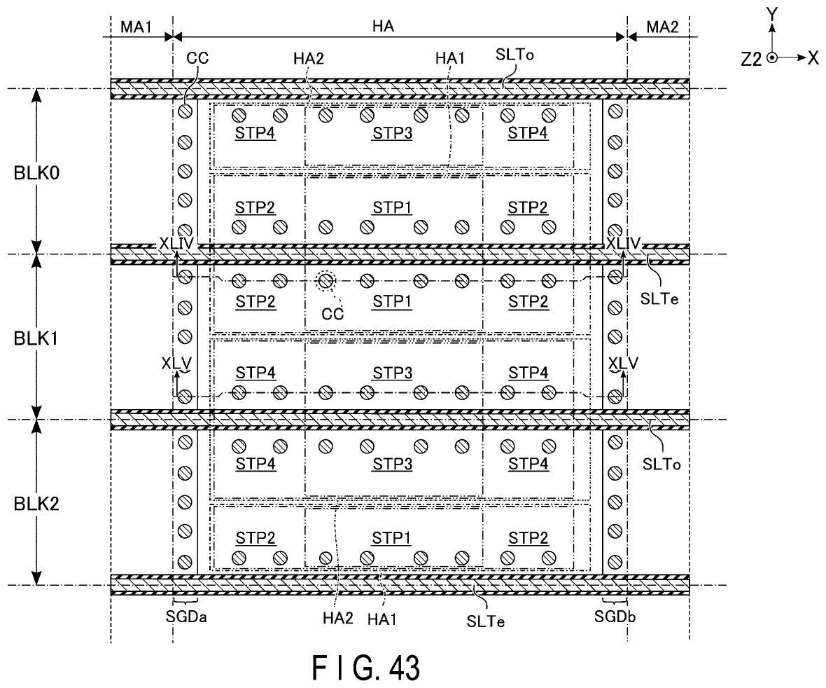

FIG. 43 is a plan view schematically illustrating an example of a planar layout in a hookup area of a memory cell array included in a semiconductor memory device according to the fourth embodiment. FIG. 43 illustrates areas corresponding to three blocks BLK0 to BLK2. Note that FIG. 43 omits the stepped structure and illustrates a stepped area where the stepped structure is provided in plan view. In FIG. 43, only the positions of a plurality of contacts CC are illustrated, and the structures thereof are omitted.

As illustrated in FIG. 43, the memory cell array 10 includes stepped areas STP1, STP2, STP3, and STP4 in a hookup area HA. The stepped areas STP1 and STP2 are provided so as to straddle a member SLTe in the Y direction and overlap each other in the Z direction. The stepped areas STP3 and STP4 are provided so as to straddle a member SLTo in the Y direction and overlap each other in the Z direction. The stepped areas STP1 and STP3 are provided side by side in the Y direction. The stepped areas STP2 and STP4 are provided side by side in the Y direction. In the stepped areas STP1 to STP4, for example, first to fourth stadium-shaped stepped structures are respectively provided. The terrace portions of the first and second stadium-shaped stepped structures are provided in a hookup area HA1. The terrace portions of the third and fourth stadium-shaped stepped structures are provided in a hookup area HA2. The plurality of contacts CC are provided corresponding to the respective terrace portions of the first to fourth stadium-shaped stepped structures.

### 4.1.2 Sectional Structure

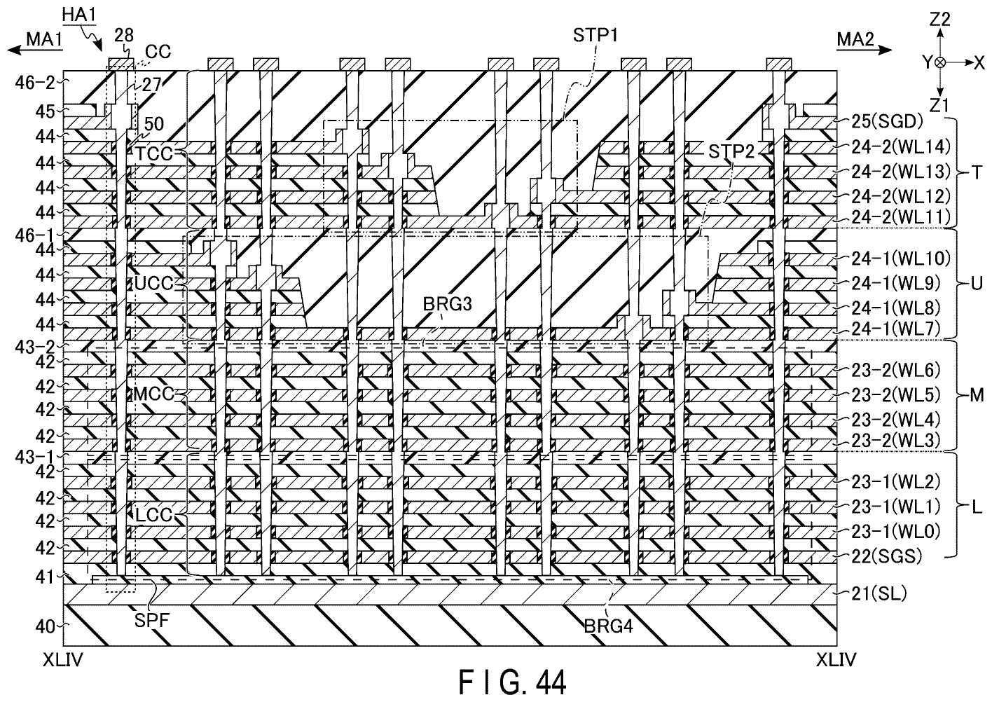

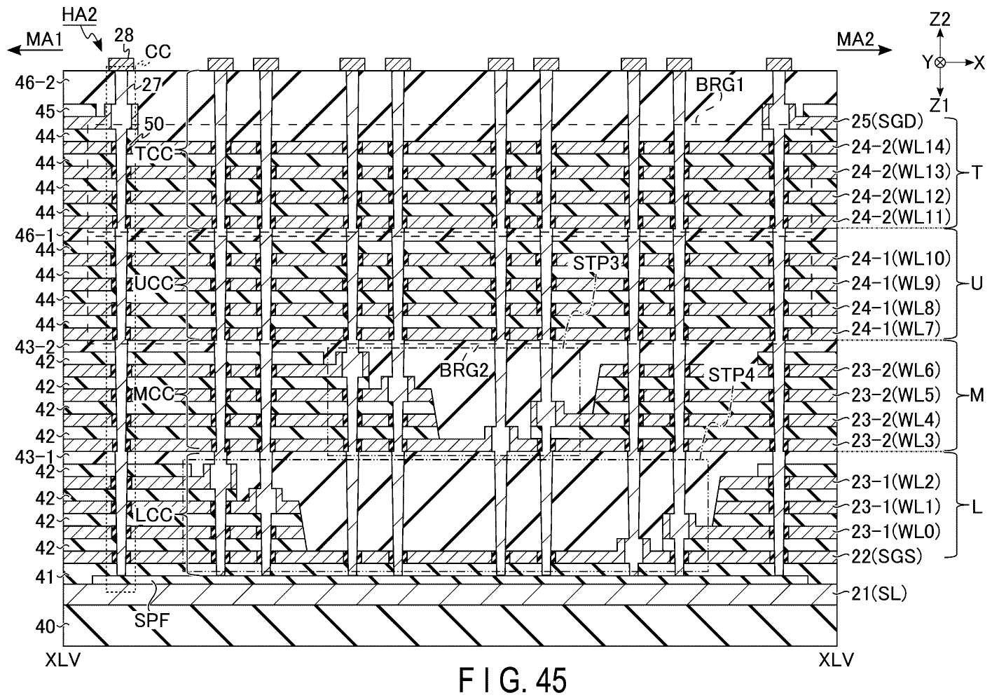

FIG. 44 is a sectional view taken along line XLIV-XLIV in FIG. 43 in the hookup area of the memory cell array included in the semiconductor memory device according to the fourth embodiment. FIG. 45 is a sectional view taken along line XLV-XLV in FIG. 43 in the hookup area of the memory cell array included in the semiconductor memory device according to the fourth embodiment. FIGS. 44 and 45 illustrate XZ sections of the hookup area HA and the contact CC in the block BLK1. FIGS. 44 and 45 correspond to the XZ sections of the hookup areas HA1 and HA2, respectively.

As illustrated in FIG. 44, in the hookup area HA1, a stepped area STP1 is provided in a top stacked interconnect T, and a stepped area STP2 is provided in an upper stacked interconnect U. The top stacked interconnect T includes a first stadium-shaped stepped structure in the stepped area STP1. The upper stacked interconnect U includes a second stadium-shaped stepped structure in the stepped area STP2. The first stadium-shaped stepped structure and the second stadium-shaped stepped structure overlap in part each other in the Z direction. The terrace portions of the respective interconnect layers in the second stadium-shaped stepped structure are provided at positions not overlapping the first stadium-shaped stepped structure in the Z direction. For example, as illustrated in FIG. 43, in plan view, the first stadium-shaped stepped structure is provided so as to be sandwiched between terrace portions of the second stadium-shaped stepped structures in the X direction.

In the hookup area HA1, a middle stacked interconnect M and a lower stacked interconnect L include bridge portions BRG3 and BRG4, respectively. The bridge portions BRG3 and BRG4 extend in the X direction and couple a portion provided in a memory area MA1 and a portion provided in a memory area MA2 of each of interconnect layers 22, 23-1, and 23-2 included in the middle stacked interconnect M and the lower stacked interconnect L.

As illustrated in FIG. 45, in the hookup area HA2, a stepped area STP3 is provided in the middle stacked interconnect M, and a stepped area STP4 is provided in the lower stacked interconnect L. The middle stacked interconnect M includes a third stadium-shaped stepped structure in the stepped area STP3. The lower stacked interconnect L includes a fourth stadium-shaped stepped structure in the stepped area STP4. The third stadium-shaped stepped structure and the fourth stadium-shaped stepped structure overlap in part each other in the Z direction. The terrace portions of the respective interconnect layers in the fourth stadium-shaped stepped structure are provided at positions not overlapping the third stadium-shaped stepped structure in the Z direction. For example, as illustrated in FIG. 43, in plan view, the third stadium-shaped stepped structure is provided so as to be sandwiched between terrace portions of the fourth stadium-shaped stepped structures in the X direction.

In the hookup area HA2, the top stacked interconnect T and the upper stacked interconnect U include bridge portions BRG1 and BRG2, respectively. The bridge portions BRG1 and BRG2 extend in the X direction and couple a portion provided in the memory area MA1 and a portion provided in the memory area MA2 of each of the interconnect layers 24-1 and 24-2 included in the top stacked interconnect T and the upper stacked interconnect U.

### 4.2 Effects

According to the fourth embodiment, similarly to the first embodiment, the yield of the semiconductor memory device can be improved. In addition, similarly to the second embodiment, the chip area of the semiconductor memory device 3 can be reduced (expansion thereof can be suppressed).

### 4.3 Modifications

The semiconductor memory device 3 according to the fourth embodiment described above can be variously modified. For example, modifications corresponding to the first modification and the second modification in the first embodiment may be applied to the semiconductor memory device 3 according to the fourth embodiment. Furthermore, in the stepped areas STP1 to STP4, the second stadium-shaped stepped structure may be provided so as to be sandwiched between terrace portions of the first stadium-shaped stepped structures in the X direction in plan view, and the fourth stadium-shaped stepped structure may be provided so as to be sandwiched between terrace portions of the third stadium-shaped stepped structures in the X direction in plan view.

### 5. Fifth Embodiment

Next, a semiconductor memory device according to a fifth embodiment will be described. A semiconductor memory device 3 according to the fifth embodiment is different from the semiconductor memory device 3 according to the first embodiment in the shape of a stepped structure provided in each stacked structure. In the following description, description about configurations equivalent to those of the first embodiment will be omitted, and configurations different from those of the first embodiment will be mainly described.

### 5.1 Configurations

In the semiconductor memory device 3 according to the fifth embodiment, each NAND string NS includes, for example, 23 memory cell transistors MT0 to MT22 and select transistors ST1 and ST2. The control gates of the memory cell transistors MT0 to MT22 in the same block BLK are coupled to word lines WL0 to WL22, respectively.

A memory cell array 10 according to the fifth embodiment includes a lower stacked interconnect L, a middle stacked interconnect M, and an upper stacked interconnect U. The lower stacked interconnect L includes an interconnect layer 22 corresponding to a select gate line SGS and a plurality of interconnect layers 23-1 corresponding to the word lines WL0 to WL6. The middle stacked interconnect M includes a plurality of interconnect layers 23-2 corresponding to the word lines WL7 to WL14. The upper stacked interconnect U includes a plurality of interconnect layers 24 corresponding to the word lines WL15 to WL22 and an interconnect layer 25 corresponding to the select gate line SGD.

### 5.2 Structure of Memory Cell Array

### 5.2.1 Planar Layout

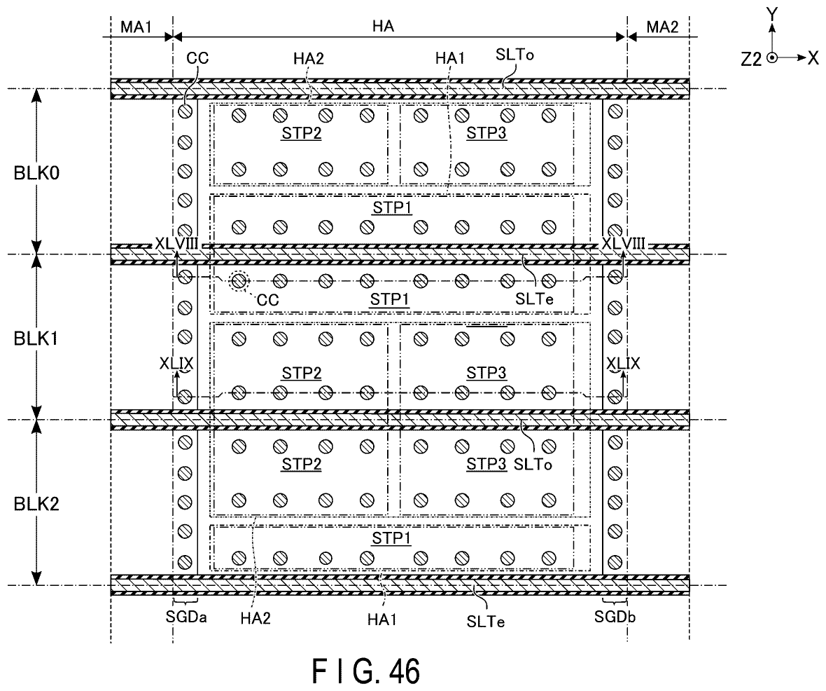

FIG. 46 is a plan view schematically illustrating an example of a planar layout in a hookup area of a memory cell array included in a semiconductor memory device according to the fifth embodiment. FIG. 46 illustrates areas corresponding to three blocks BLK0 to BLK2. Note that FIG. 46 omits the stepped structure and illustrates a stepped area where the stepped structure is provided in plan view. In FIG. 46, only the positions of a plurality of contacts CC are illustrated, and the structures thereof are omitted.

As illustrated in FIG. 46, the memory cell array 10 includes stepped areas STP1, STP2, and STP3 in a hookup area HA. The stepped area STP1 is provided so as to straddle a member SLTe in the Y direction. The stepped areas STP2 and STP3 are provided so as to straddle a member SLTo in the Y direction and are arranged in the X direction. The stepped area STP1 and the stepped areas STP2 and STP3 are provided side by side in the Y direction. In the stepped area STP1, for example, a first stadium-shaped stepped structure is provided. The terrace portions of the first stadium-shaped stepped structures are provided in a hookup area HA1. A plurality of contacts CC are provided corresponding to the respective terrace portions of the first stadium-shaped stepped structure.

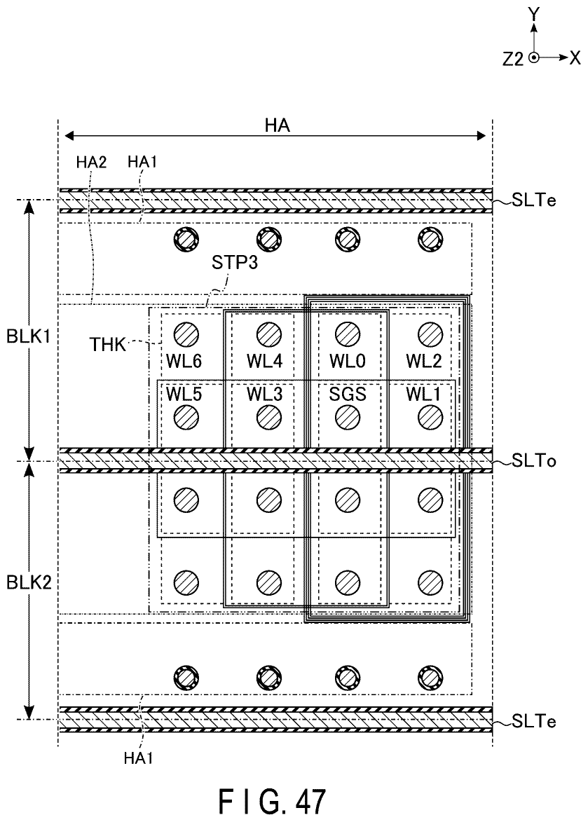

FIG. 47 is a plan view illustrating an example of a planar layout of a lower stacked interconnect in the hookup area of the memory cell array included in the semiconductor memory device according to the fifth embodiment. FIG. 47 illustrates areas corresponding to two blocks BLK1 and BLK2.

As illustrated in FIG. 47, in the area corresponding to a hookup area HA2 of the lower stacked interconnect L, the stepped area STP3 is provided. In the stepped area STP3, the interconnect layers 22 and 23-1 included in the lower stacked interconnect L include, for example, a second two-column stepped structure including one level difference in the Y direction and a pair of two level differences stepwise in the X direction. Although not illustrated, a stepped area STP2 is provided in an area corresponding to the hookup area HA2 of the middle stacked interconnect M. In the stepped area STP2, the interconnect layers 23-2 included in the middle stacked interconnect M include, for example, a first two-column stepped structure including one level difference in the Y direction and a pair of two level differences stepwise in the X direction. The terrace portions of the first and second two-column stepped structures are provided in the hookup area HA2. The plurality of contacts CC are provided corresponding to the respective terrace portions of the first and second two-column stepped structures.

As illustrated in FIG. 46, in the memory cell array 10 according to the fifth embodiment, the contacts CC are provided so as to be arranged in three columns in the Y direction in one block BLK. This structure is referred to as a “three-lane contact structure”.

A thick film portion THK in each of interconnect layers 22 and 23-1 included in the lower stacked interconnect L is spaced apart in the X direction from the side surface of the thick film portion THK of the interconnect layer 23-1 provided two layers above the interconnect layer 22 or 23-1. In addition, a thick film portion THK in each of the interconnect layers 22 and 23-1 is spaced apart in the Y direction from the side surface of the thick film portion THK of the interconnect layer 23-1 provided one layer above the interconnect layer 22 or 23-1. Although not illustrated, the thick film portion THK in each interconnect layer 23-2 included in the middle stacked interconnect M is spaced apart in the X direction from the side surface of the thick film portion THK of the interconnect layer 23-2 provided two layers above the interconnect layer 23-2. In addition, a thick film portion THK in each interconnect layer 23-2 is spaced apart in the Y direction from the side surface of the thick film portion THK of the interconnect layer 23-2 provided one layer above the interconnect layer 23-2.

### 5.2.2 Sectional Structure

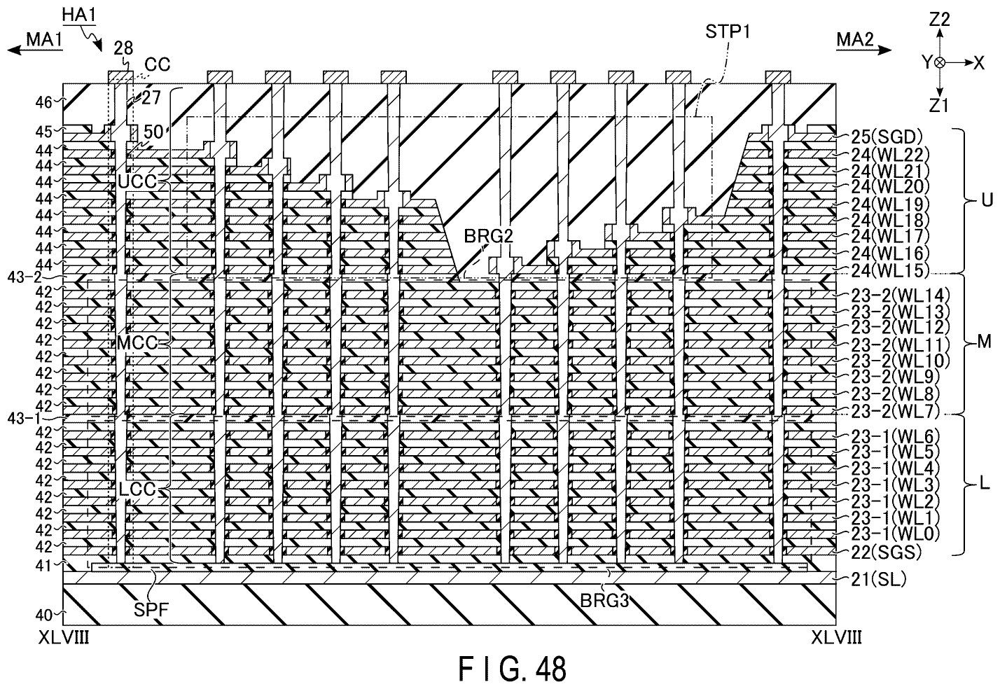

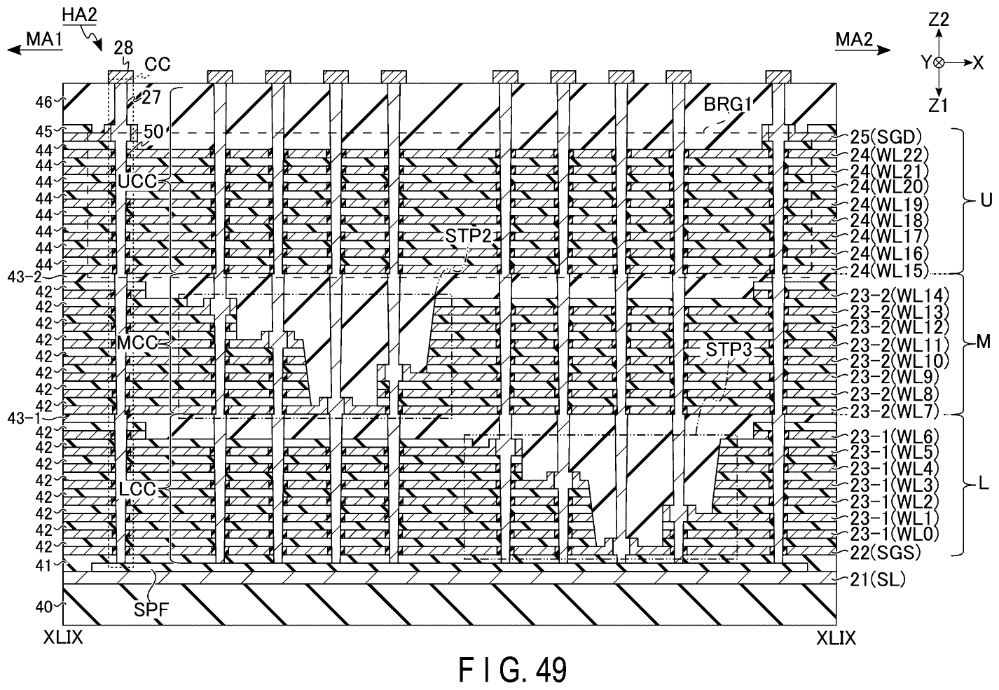

FIG. 48 is a sectional view taken along line XLVIII-XLVIII in FIG. 46 in the hookup area of the memory cell array included in the semiconductor memory device according to the fifth embodiment. FIG. 49 is a sectional view taken along line XLIX-XLIX in FIG. 46 in the hookup area of the memory cell array included in the semiconductor memory device according to the fifth embodiment. FIGS. 48 and 49 illustrate XZ sections of the hookup area HA and the contact CC in the block BLK1. FIGS. 48 and 49 correspond to the XZ sections of the hookup areas HA1 and HA2, respectively.

As illustrated in FIG. 48, in the hookup area HA1, the stepped area STP1 is provided in the upper stacked interconnect U. The upper stacked interconnect U includes a first stadium-shaped stepped structure in the stepped area STP1.

In the hookup area HA1, the middle stacked interconnect M and the lower stacked interconnect L include bridge portions BRG2 and BRG3, respectively. The bridge portions BRG2 and BRG3 extend in the X direction and couple a portion provided in a memory area MA1 and a portion provided in a memory area MA2 of each of the interconnect layers 22, 23-1, and 23-2 included in the middle stacked interconnect M and the lower stacked interconnect L.

As illustrated in FIG. 49, in the hookup area HA2, a stepped area STP2 is provided in the middle stacked interconnect M, and a stepped area STP3 is provided in the lower stacked interconnect L. The middle stacked interconnect M includes a first two-column stepped structure in the stepped area STP2. The lower stacked interconnect L includes a second two-column stepped structure in the stepped area STP3. The first two-column stepped structure and the second two-column stepped structure are provided at positions not overlapping each other in the Z direction.

In the hookup area HA2, the upper stacked interconnect U includes the bridge portion BRG1. The bridge portion BRG1 extends in the X direction and couples a portion provided in the memory area MA1 and a portion provided in the memory area MA2 of each interconnect layer 24 included in the upper stacked interconnect U.

The memory cell array 10 includes insulating layers 43-1 and 43-2. The insulating layer 43-1 is provided so as to fill the second two-column stepped structure between the lower stacked interconnect L and the middle stacked interconnect M. The insulating layer 43-2 is provided so as to fill the first two-column stepped structure between the middle stacked interconnect M and the upper stacked interconnect U.

The plurality of contacts CC are provided extending in the Z direction. Each contact CC is a through contact that extends through (passes through), in the Z direction, the corresponding interconnect layer and other layers above the stopper film SPF provided at the position where the contact CC is disposed in plan view.

Each contact CC includes an upper contact UCC, a middle contact MCC, and a lower contact LCC. The lower contact LCC extends through the lower stacked interconnect L, that is, at least a part of the interconnect layers 22 and 23-1, at least a part of the insulating layers 41 and 42, and the insulating layer 43-1. The middle contact MCC extends through the middle stacked interconnect M, that is, at least a part of the interconnect layers 23-2, at least a part of the insulating layers 42, and the insulating layer 43-2. The upper contact UCC extends through the upper stacked interconnect U, that is, at least a part of the interconnect layers 24 and 25, at least a part of the insulating layers 44 and 45, and an insulating layer 46. The upper end of the lower contact LCC and the lower end of the middle contact MCC are in contact with each other at the boundary surface between the insulating layer 43-1 and the lowermost interconnect layer 23-2. The upper end of the middle contact MCC and the lower end of the upper contact UCC are in contact with each other at the boundary surface between the insulating layer 43-2 and the lowermost interconnect layer 24.

Although not illustrated, a member SLT and a memory pillar MP may also have individual structures for each stacked interconnect. The structures of the members SLT and the memory pillars MP for each stacked interconnect are coupled continuously in the Z direction.

### 5.3 Effects

According to the fifth embodiment, similarly to the first embodiment, the incline of the stacked interconnect due to the bias of a stress can be reduced, and thus, the yield of the semiconductor memory device 3 can be improved. In addition, the memory cell array 10 according to the fifth embodiment includes a three-lane contact structure. This structure can further suppress an increase in the length of the memory cell array 10 in one direction (e.g., the X direction) due to the arrangement of the coupling portion of each interconnect layer 22, 23-1, 23-2, and 24 with the contact CC in the direction than the two-lane contact structure, and can reduce (suppress the expansion of) the chip area of the semiconductor memory device 3.

### 5.4 Modifications

The semiconductor memory device 3 according to the fifth embodiment described above can be variously modified. For example, modifications corresponding to the first modification and the second modification in the first embodiment may be applied to the semiconductor memory device 3 according to the fifth embodiment. Furthermore, instead of the middle stacked interconnect M and the lower stacked interconnect L, the upper stacked interconnect U and the middle stacked interconnect M may include respectively, in the hookup area HA1, terrace portions of first and second two-column stepped structures arranged in the X direction in plan view.

### 6. Sixth Embodiment

Next, a semiconductor memory device according to a sixth embodiment will be described. A semiconductor memory device 3 according to the sixth embodiment is different from the semiconductor memory device 3 according to the first embodiment in the shape of a stepped structure provided in each stacked structure. In the following description, description about configurations equivalent to those of the first embodiment will be omitted, and configurations different from those of the first embodiment will be mainly described.

### 6.1 Configurations

In the semiconductor memory device 3 according to the sixth embodiment, each NAND string NS includes, for example, 31 memory cell transistors MT0 to MT30 and select transistors ST1 and ST2. The control gates of the memory cell transistors MT0 to MT30 in the same block BLK are coupled to the word lines WL0 to WL30, respectively.

A memory cell array 10 according to the sixth embodiment includes a lower stacked interconnect L, a middle stacked interconnect M, an upper stacked interconnect U, and a top stacked interconnect T. The lower stacked interconnect L includes an interconnect layer 22 corresponding to a select gate line SGS and a plurality of interconnect layers 23-1 corresponding to the word lines WL0 to WL6. The middle stacked interconnect M includes a plurality of interconnect layers 23-2 corresponding to the word lines WL7 to WL14. The upper stacked interconnect U includes a plurality of interconnect layers 24-1 corresponding to the word lines WL15 to WL22. The top stacked interconnect T includes a plurality of interconnect layers 24-2 corresponding to the word lines WL23 to WL30 and an interconnect layer 25 corresponding to a select gate line SGD.

### 6.2 Structure of Memory Cell Array

### 6.2.1 Planar Layout

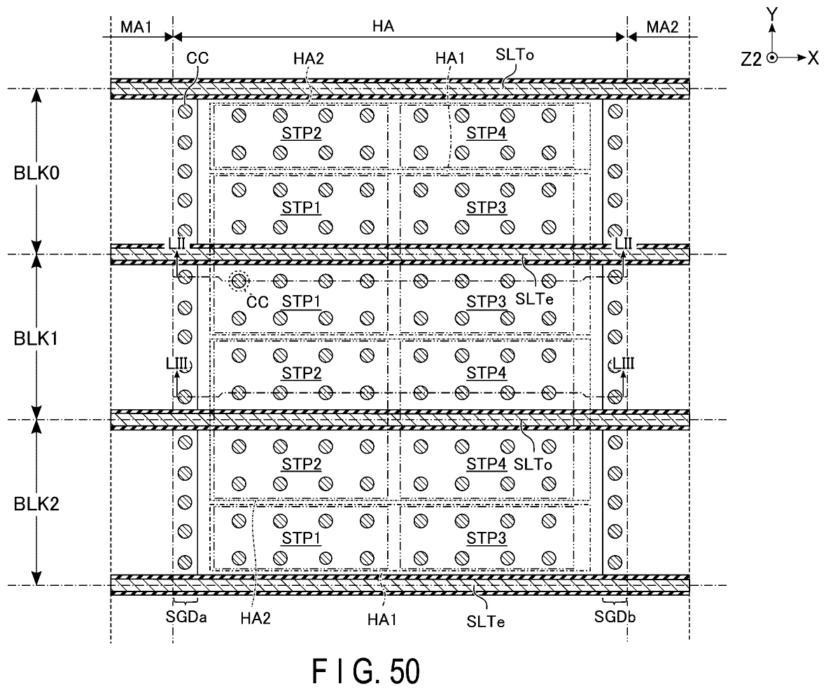

FIG. 50 is a plan view schematically illustrating an example of a planar layout in a hookup area of a memory cell array included in a semiconductor memory device according to the sixth embodiment. FIG. 50 illustrates areas corresponding to three blocks BLK0 to BLK2. Note that FIG. 50 omits the stepped structure and illustrates a stepped area where the stepped structure is provided in plan view. In addition, in FIG. 50, only the positions of a plurality of contacts CC are illustrated, and the structure is omitted.

As illustrated in FIG. 50, the memory cell array 10 includes stepped areas STP1, STP2, STP3, and STP4 in a hookup area HA. The stepped areas STP1 and STP3 are provided so as to straddle a member SLTe in the Y direction and are arranged in the X direction. The stepped areas STP2 and STP4 are provided so as to straddle a member SLTo in the Y direction and are arranged in the X direction. The stepped areas STP1 and STP2 are provided side by side in the Y direction. The stepped areas STP3 and STP4 are provided side by side in the Y direction.

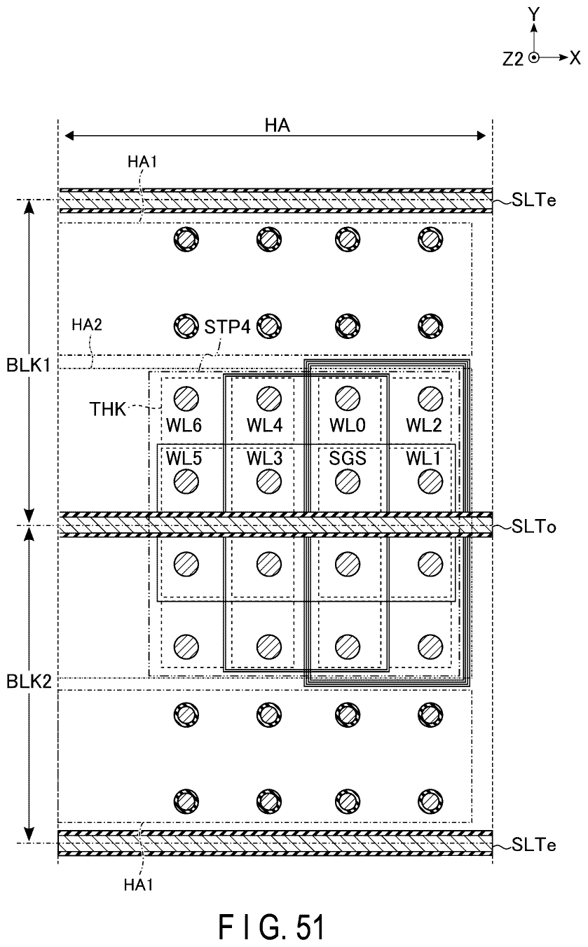

FIG. 51 is a plan view illustrating an example of a planar layout of a lower stacked interconnect in the hookup area of the memory cell array included in the semiconductor memory device according to the sixth embodiment. FIG. 51 illustrates areas corresponding to two blocks BLK1 and BLK2.

As illustrated in FIG. 51, in the area corresponding to a hookup area HA2 of the lower stacked interconnect L, the stepped area STP4 is provided. In the stepped area STP4, the interconnect layers 22 and 23-1 included in the lower stacked interconnect L include, for example, a fourth two-column stepped structure including one level difference in the Y direction and a pair of two level differences stepwise in the X direction. Although not illustrated, the stepped area STP1 is provided in an area corresponding to a hookup area HA1 of the top stacked interconnect T. In the stepped area STP1, the interconnect layers 24-2 included in the top stacked interconnect T include, for example, a first two-column stepped structure including one level difference in the Y direction and a pair of two level differences stepwise in the X direction. In the area corresponding to the hookup area HA2 of the upper stacked interconnect U, the stepped area STP2 is provided. In the stepped area STP2, the interconnect layers 24-1 included in the upper stacked interconnect U include, for example, a second two-column stepped structure including one level difference in the Y direction and a pair of two level differences stepwise in the X direction. In the area corresponding to the hookup area HA1 of the middle stacked interconnect M, the stepped area STP3 is provided. In the stepped area STP3, the interconnect layers 23-2 included in the middle stacked interconnect M include, for example, a third two-column stepped structure including one level difference in the Y direction and a pair of two level differences stepwise in the X direction. The terrace portions of the first and third two-column stepped structures are provided in the hookup area HA1. The terrace portions of the second and fourth two-column stepped structures are provided in the hookup area HA2. A plurality of contacts CC are provided corresponding to the respective terrace portions of the first to fourth two-column stepped structures.

As illustrated in FIG. 50, in the memory cell array 10 according to the sixth embodiment, the contacts CC are provided so as to be arranged in four columns in the Y direction in one block BLK. This structure is referred to as a “four-lane contact structure”.

A thick film portion THK in each of interconnect layers 22 and 23-1 included in the lower stacked interconnect L is spaced apart in the X direction from the side surface of the thick film portion THK of the interconnect layer 23-1 provided two layers above the interconnect layer 22 or 23-1. In addition, a thick film portion THK in each of the interconnect layers 22 and 23-1 is spaced apart in the Y direction from the side surface of the thick film portion THK of the interconnect layer 23-1 provided one layer above the interconnect layer 22 or 23-1. Although not illustrated, the thick film portion THK in each interconnect layer 23-2 included in the middle stacked interconnect M is spaced apart in the X direction from the side surface of the thick film portion THK of the interconnect layer 23-2 provided two layers above the interconnect layer 23-2. In addition, a thick film portion THK in each interconnect layer 23-2 is spaced apart in the Y direction from the side surface of the thick film portion THK of the interconnect layer 23-2 provided one layer above the interconnect layer 23-2. A thick film portion THK in each interconnect layer 24-1 included in the upper stacked interconnect U is spaced apart in the X direction from the side surface of the thick film portion THK of the interconnect layer 24-1 provided two layers above the interconnect layer 24-1. In addition, a thick film portion THK in each interconnect layer 24-1 is spaced apart in the Y direction from the side surface of the thick film portion THK of the interconnect layer 24-1 provided one layer above the interconnect layer 24-1. A thick film portion THK in each interconnect layer 24-2 included in the top stacked interconnect T is spaced apart in the X direction from the side surface of the thick film portion THK of the interconnect layer 24-2 provided two layers above the interconnect layer 24-2. In addition, a thick film portion THK in each interconnect layer 24-2 is spaced apart in the Y direction from the side surface of the thick film portion THK of the interconnect layer 24-2 provided one layer above the interconnect layer 24-2.

### 6.2.2 Sectional Structure

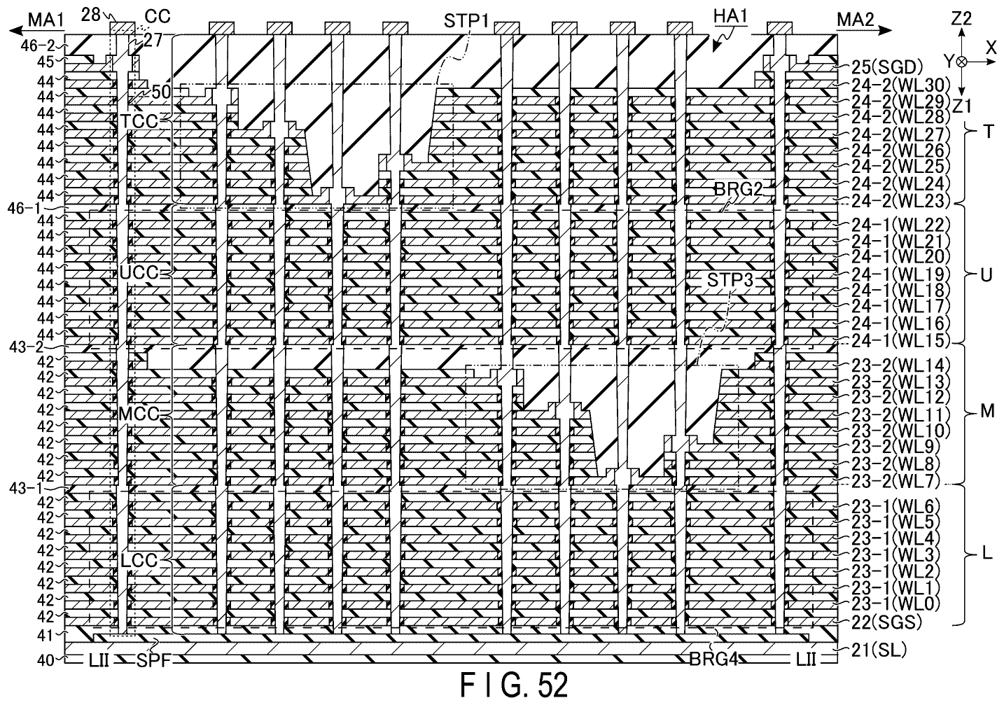

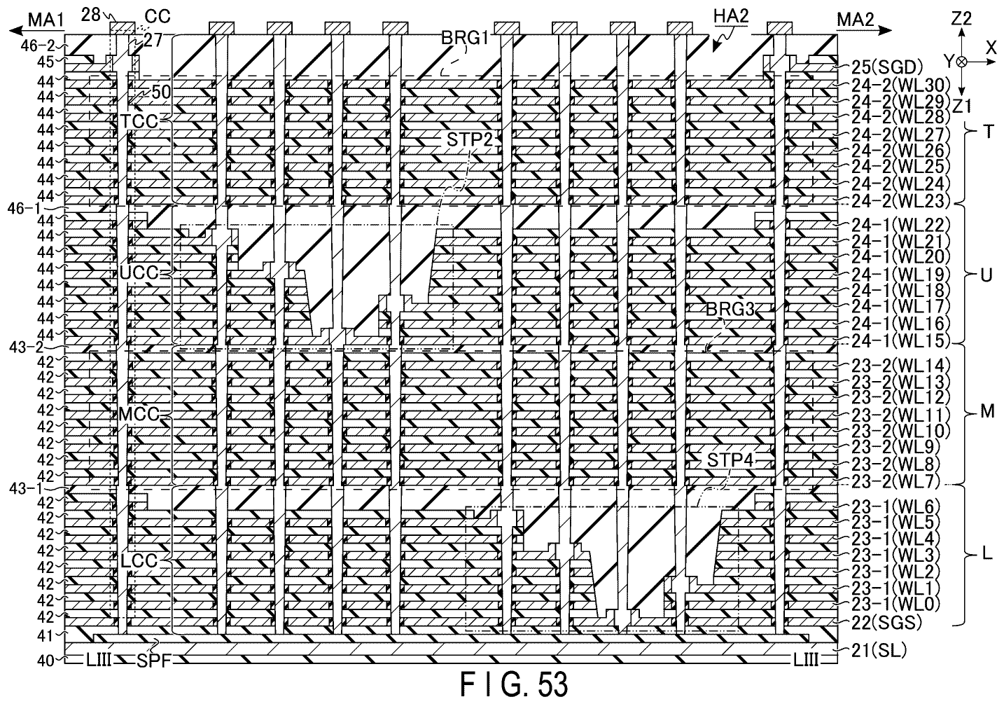

FIG. 52 is a sectional view taken along line LII-LII in FIG. 50 in the hookup area of the memory cell array included in the semiconductor memory device according to the sixth embodiment. FIG. 53 is a sectional view taken along line LIII-LIII in FIG. 50 in the hookup area of the memory cell array included in the semiconductor memory device according to the sixth embodiment. FIGS. 52 and 53 illustrate XZ sections of the hookup area HA and the contact CC in the block BLK1. FIGS. 52 and 53 correspond to the XZ sections of the hookup areas HA1 and HA2, respectively.

As illustrated in FIG. 52, in the hookup area HA1, a stepped area STP1 is provided in the top stacked interconnect T, and a stepped area STP3 is provided in the middle stacked interconnect M. The top stacked interconnect T includes a first two-column stepped structure in the stepped area STP1. The middle stacked interconnect M includes a third two-column stepped structure in the stepped area STP3. The first two-column stepped structure and the third two-column stepped structure are provided at positions not overlapping each other in the Z direction.

In the hookup area HA1, the upper stacked interconnect U and the lower stacked interconnect L include bridge portions BRG2 and BRG4, respectively. The bridge portions BRG2 and BRG4 extend in the X direction and couple a portion provided in a memory area MA1 and a portion provided in a memory area MA2 of each of the interconnect layers 22, 23-1, and 24-1 included in the upper stacked interconnect U and the lower stacked interconnect L.

As illustrated in FIG. 53, in the hookup area HA2, a stepped area STP2 is provided in the upper stacked interconnect U, and a stepped area STP4 is provided in the lower stacked interconnect L. The upper stacked interconnect U includes a second two-column stepped structure in the stepped area STP2. The lower stacked interconnect L includes a fourth two-column stepped structure in the stepped area STP4. The second two-column stepped structure and the fourth two-column stepped structure are provided at positions not overlapping each other in the Z direction.

In the hookup area HA2, the top stacked interconnect T and the middle stacked interconnect M include bridge portions BRG1 and BRG3, respectively. The bridge portions BRG1 and BRG3 extend in the X direction and couple a portion provided in the memory area MA1 and a portion provided in the memory area MA2 of each of the interconnect layers 23-2 and 24-2 included in the top stacked interconnect T and the middle stacked interconnect M.

The memory cell array 10 includes insulating layers 43-1, 43-2, 46-1, and 46-2. The insulating layer 43-1 is provided so as to fill the fourth two-column stepped structure between the lower stacked interconnect L and the middle stacked interconnect M. The insulating layer 43-2 is provided so as to fill the third two-column stepped structure between the middle stacked interconnect M and the upper stacked interconnect U. The insulating layer 46-1 is provided so as to fill the second two-column stepped structure between the upper stacked interconnect U and the top stacked interconnect T. The insulating layer 46-2 is provided so as to fill the first two-column stepped structure above the top stacked interconnect T.

The plurality of contacts CC are provided extending in the Z direction. Each contact CC is a through contact that extends through (passes through), in the Z direction, the corresponding interconnect layer and other layers above the stopper film SPF provided at the position where the contact CC is disposed in plan view.

Each contact CC includes a top contact TCC, an upper contact UCC, a middle contact MCC, and a lower contact LCC. The lower contact LCC extends through the lower stacked interconnect L, that is, at least a part of the interconnect layers 22 and 23-1, at least a part of the insulating layers 41 and 42, and the insulating layer 43-1. The middle contact MCC extends through the middle stacked interconnect M, that is, at least a part of the interconnect layers 23-2, at least a part of the insulating layers 42, and the insulating layer 43-2. The upper contact UCC extends through the upper stacked interconnect U, that is, at least a part of the interconnect layers 24-1, at least a part of the insulating layers 44, and the insulating layer 46-1. The top contact TCC extends through the top stacked interconnect T, that is, at least a part of the interconnect layers 24-2 and 25, at least a part of the insulating layers 44 and 45, and the insulating layer 46-2. The upper end of the lower contact LCC and the lower end of the middle contact MCC are in contact with each other at the boundary surface between the insulating layer 43-1 and the lowermost interconnect layer 23-2. The upper end of the middle contact MCC and the lower end of the upper contact UCC are in contact with each other at the boundary surface between the insulating layer 43-2 and the lowermost interconnect layer 24-1. The upper end of the upper contact UCC and the lower end of the top contact TCC are in contact with each other at the boundary surface between the insulating layer 46-1 and the lowermost interconnect layer 24-2.

Although not illustrated, a member SLT and a memory pillar MP may also have individual structures for each stacked interconnect. The structures of the members SLT and the memory pillars MP for each stacked interconnect are coupled continuously in the Z direction.

### 6.3 Effects

According to the sixth embodiment, similarly to the first embodiment, the incline of the stacked interconnect due to the bias of a stress can be reduced, and thus, the yield of the semiconductor memory device 3 can be improved. In addition, the memory cell array 10 according to the sixth embodiment includes a four-lane contact structure. This structure can further suppress an increase in the length of the memory cell array 10 in one direction (e.g., the X direction) due to the arrangement of the coupling portion of each interconnect layer 22, 23-1, 23-2, 24-1, and 24-2 with the contact CC in the direction than the two-lane contact structure and the three-lane contact structure, and can reduce (suppress the expansion of) the chip area of the semiconductor memory device 3.

### 6.4 Modifications

The semiconductor memory device 3 according to the sixth embodiment described above can be variously modified. For example, modifications corresponding to the first modification and the second modification in the first embodiment may be applied to the semiconductor memory device 3 according to the sixth embodiment.

### 7. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first interconnect layer;
a plurality of second interconnect layers that are provided above the first interconnect layer and apart from each other in a first direction, the second interconnect layers straddling, as viewed in the first direction, a first area and a second area that are arranged in a second direction intersecting the first direction, wherein the first area includes a third area and a fourth area that are arranged in a third direction intersecting the first direction and the second direction, and the second interconnect layers including a plurality of first terrace portions that are provided not overlapping respective upper layers of the second interconnect layers in the first direction in the third area, and a first bridge portion that extends in the second direction in the fourth area;
a plurality of third interconnect layers that are provided above the second interconnect layers and apart from each other in the first direction in the first area and the second area, the third interconnect layers including a plurality of second terrace portions that are provided not overlapping respective upper layers of the third interconnect layers in the first direction in the fourth area, and a second bridge portion that extends in the second direction in the third area;
a first insulating member and a second insulating member that extend in the first direction and the second direction and sandwich the first area and the second area in the third direction;
a first memory pillar that extends in the first direction in the second area, and in which a portion passing through the second interconnect layers and the third interconnect layers functions as a plurality of first memory cells;
a first contact that extends in the first direction above one of the first terrace portions in the third area and is electrically coupled to the one of the first terrace portions; and
a second contact that extends in the first direction above one of the second terrace portions in the fourth area and is electrically coupled to the one of the second terrace portions.

2. The semiconductor memory device according to claim 1, wherein
the first contact passes through the third interconnect layers in the first direction in the third area.

3. The semiconductor memory device according to claim 2, wherein
the first contact further passes through a second interconnect layer provided below the one of the first terrace portions among the second interconnect layers in the first direction in the third area.

4. The semiconductor memory device according to claim 3, wherein
the second contact passes through the second interconnect layers and a third interconnect layer provided below the one of the second terrace portions among the third interconnect layers in the first direction in the fourth area.

5. The semiconductor memory device according to claim 1, wherein
each of the first terrace portions is thicker in the first direction than another portion of the second interconnect layers, and
each of the second terrace portions is thicker in the first direction than another portion of the third interconnect layers.

6. The semiconductor memory device according to claim 1, wherein
the first terrace portions include a plurality of first sub-terrace portions that are provided in a step shape descending to one side in the second direction, and a plurality of second sub-terrace portions that are provided in a step shape ascending to the one side in the second direction,
the second terrace portions include a plurality of third sub-terrace portions that are provided in a step shape descending to the one side in the second direction, and a plurality of fourth sub-terrace portions that are provided in a step shape ascending to the one side in the second direction,
the first sub-terrace portions and the second sub-terrace portions are disposed side by side in the second direction in the third area, and
the third sub-terrace portions and the fourth sub-terrace portions are disposed side by side in the second direction in the fourth area.

7. The semiconductor memory device according to claim 6, wherein
in a portion sandwiched between the first sub-terrace portions and the second sub-terrace portions in the third area in the second direction, the second interconnect layers include a first level difference having a height corresponding to a plurality of layers among the second interconnect layers, and
in a portion sandwiched between the third sub-terrace portions and the fourth sub-terrace portions in the fourth area in the second direction, the third interconnect layers include a second level difference having a height corresponding to a plurality of layers among the third interconnect layers.

8. The semiconductor memory device according to claim 1, wherein
the first bridge portion of the second interconnect layers is in contact with the first insulating member in the third direction, and
the second bridge portion of the third interconnect layers is in contact with the second insulating member in the third direction.

9. The semiconductor memory device according to claim 8, wherein
the first terrace portions are in contact with the second insulating member in the third direction, and
the second terrace portions are in contact with the first insulating member in the third direction.

10. The semiconductor memory device according to claim 1, wherein
the first terrace portions and the second terrace portions are arranged in the third direction at substantially a same position in the second direction.

11. The semiconductor memory device according to claim 1, further comprising:
a plurality of fourth interconnect layers that are provided above the third interconnect layers and apart from each other in the first direction in the first area and the second area, the fourth interconnect layers including a plurality of third terrace portions that are provided not overlapping respective upper layers of the fourth interconnect layers in the first direction in the third area, and a third bridge portion that extends in the second direction in the fourth area;
a plurality of fifth interconnect layers that are provided above the fourth interconnect layers and apart from each other in the first direction in the first area and the second area, the fifth interconnect layers including a plurality of fourth terrace portions that are provided not overlapping respective upper layers of the fifth interconnect layers in the first direction in the fourth area, and a fourth bridge portion that extends in the second direction in the third area;
a third contact that extends in the first direction above one of the third terrace portions in the third area and is electrically coupled to the one of the third terrace portions; and
a fourth contact that extends in the first direction above one of the fourth terrace portions in the fourth area and is electrically coupled to the one of the fourth terrace portions.

12. The semiconductor memory device according to claim 11, wherein
the first terrace portions and the third terrace portions do not overlap each other in the first direction and are arranged in the second direction in the third area, and
the second terrace portions and the fourth terrace portions do not overlap each other in the first direction and are arranged in the second direction in the fourth area.

13. The semiconductor memory device according to claim 1, further comprising:
a plurality of fourth interconnect layers that are sandwiched between the second interconnect layers and the third interconnect layers in the first direction and apart from each other in the first direction in the first area and the second area, the fourth interconnect layers including a plurality of third terrace portions that are provided not overlapping respective upper layers of the fourth interconnect layers in the first direction in the third area, and a third bridge portion that extends in the second direction in the fourth area;
a plurality of fifth interconnect layers that are provided above the third interconnect layers and apart from each other in the first direction in the first area and the second area, the fifth interconnect layers including a plurality of fourth terrace portions that are provided not overlapping respective upper layers of the fifth interconnect layers in the first direction in the fourth area, and a fourth bridge portion that extends in the second direction in the third area;
a third contact that extends in the first direction above one of the third terrace portions in the third area and is electrically coupled to the one of the third terrace portions; and
a fourth contact that extends in the first direction above one of the fourth terrace portions in the fourth area and is electrically coupled to the one of the fourth terrace portions.

14. The semiconductor memory device according to claim 13, wherein
the first terrace portions and the third terrace portions do not overlap each other in the first direction and are arranged in the second direction in the third area, and
the second terrace portions and the fourth terrace portions do not overlap each other in the first direction and are arranged in the second direction in the fourth area.

15. The semiconductor memory device according to claim 13, wherein
one of the first terrace portions or the third terrace portions includes a plurality of first sub-terrace portions that are provided in a step shape descending to one side in the second direction, and a plurality of second sub-terrace portions that are provided in a step shape ascending to the one side in the second direction,
one of the second terrace portions or the fourth terrace portions includes a plurality of third sub-terrace portions that are provided in a step shape descending to the one side in the second direction, and a plurality of fourth sub-terrace portions that are provided in a step shape ascending to the one side in the second direction,
the first sub-terrace portions and the second sub-terrace portions are arranged in the second direction in the third area,
the third sub-terrace portions and the fourth sub-terrace portions are arranged in the second direction in the fourth area,
the other of the first terrace portions or the third terrace portions overlaps, in the first direction, a portion being sandwiched between the first sub-terrace portions and the second sub-terrace portions in the second direction in the third area, and
the other of the second terrace portions or the fourth terrace portions overlaps, in the first direction, a portion being sandwiched between the third sub-terrace portions and the fourth sub-terrace portions in the second direction in the fourth area.

16. The semiconductor memory device according to claim 1, wherein
the third area includes a fifth area and a sixth area arranged in the third direction,
the first terrace portions include a plurality of fifth sub-terrace portions in the fifth area, and a plurality of sixth sub-terrace portions in the sixth area, and
the fifth sub-terrace portions and the sixth sub-terrace portions are arranged in the third direction at substantially a same position in the second direction.

17. The semiconductor memory device according to claim 16, wherein
the fourth area includes a seventh area and an eighth area arranged in the third direction,
the second terrace portions include a plurality of seventh sub-terrace portions in the seventh area, and a plurality of eighth sub-terrace portions in the eighth area, and
the seventh sub-terrace portions and the eighth sub-terrace portions are arranged in the third direction at substantially a same position in the second direction.

18. The semiconductor memory device according to claim 1, wherein
each of the first contact and the second contact includes a lower contact and an upper contact, and has a shape in which a side surface of the lower contact and an extension of a side surface of the upper contact are displaced in a plane including the first direction.

19. The semiconductor memory device according to claim 18, wherein
an upper surface of the lower contact and a lower surface of the upper contact of each of the first contact and the second contact are in contact with each other between the second interconnect layers and the third interconnect layers in the first direction.

20. The semiconductor memory device according to claim 1, wherein
the second interconnect layers further straddle, as viewed in the first direction, a ninth area positioned opposite the second area with respect to the first area in the second direction, and
the second interconnect layers and the third interconnect layers extend in the second direction and reach the ninth area,
the device further comprising a second memory pillar that extends in the first direction in the ninth area and in which a portion passing through the second interconnect layers and the third interconnect layers functions as a plurality of second memory cells.
